(19) United States
(12) Patent Application Publication
(10) Pub. No.: US 2009/0042321 A1
(43) Pub. Date: Feb. 12, 2009

(54) APPARATUS AND METHOD FOR PLASMA DOPING

(75) Inventors: Yuichiro Sasaki, Osaka (JP); Tomohiro Okumura, Osaka (JP); Hiroyuki Ito, Chiba (JP); Keiichi Nakamoto, Osaka (JP); Katsumi Okashita, Osaka (JP); Bunji Mizuno, Nara (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD., Osaka (JP)

(21) Appl. No.: 12/183,775

(22) Filed: Jul. 31, 2008

Related U.S. Application Data
(63) Continuation of application No. PCT/JP2008/056002, filed on Mar. 21, 2008.

(30) Foreign Application Priority Data
Mar. 23, 2007 (JP) 2007-077113

(51) Int. Cl. H01L 21/66; C23C 16/513

(52) U.S. Cl. 438/10; 118/723 R; 257/E21.531

(57) ABSTRACT

Gas supplied to gas flow passages of a top plate from a gas supply device by gas supply lines forms flow along a vertical direction along a central axis of a substrate, so that the gas blown from gas blow holes can be made to be uniform, and a sheet resistance distribution is rotationally symmetric around a substrate center.

### CROSS REFERENCE TO RELATED APPLICATIONS

This is a continuation of International Application No. PCT/JP2008/056002, filed on Mar. 21, 2008, which in turn claims the benefit of Japanese Patent Application No. 2007-077113, filed on Mar. 21, 2007, the disclosures of which Applications are incorporated by reference herein.

### TECHNICAL FIELD

The present invention relates to a semiconductor device and a manufacturing method of the same, and particularly relates to an apparatus and a method for plasma doping, for introducing impurities to a surface of a solid sample such as a semiconductor substrate.

### BACKGROUND ART

A plasma doping method for ionizing the impurities and introducing the impurities into a solid object with low energy is known as a technique of introducing the impurities to the surface of the solid sample (for example, see U.S. Pat. No. 4,912,065).

FIG. 20 shows an outline structure of a plasma processing apparatus used for the plasma doping method as a conventional impurity introduction method described in U.S. Pat. No. 4,912,065. In FIG. 20, a sample electrode 202 for placing a sample 201 made of a silicon substrate is provided in a vacuum vessel 200. A gas supply device 203 for supplying doping source gas containing a desired element such as B₂H₆, and a pump 204 for reducing a pressure inside of the vacuum vessel 200 are provided in the vacuum vessel 200, so that the pressure inside of the vacuum vessel 200 can be maintained to a prescribed pressure. Microwaves are transmitted into the vacuum vessel 200 from a microwave waveguide 205, via a quartz plate 206 as a dielectric window. By an interaction of the microwaves and a D.C. magnetic field formed from an electromagnet 207, magnetic field microwave plasma (electron cyclotron resonance plasma) 208 is formed in the vacuum vessel 200. A high frequency power supply 210 is connected to the sample electrode 202 via a capacitor 209, so that a potential of the sample electrode 202 can be controlled. In addition, the gas supplied from the gas supply device 203 is introduced into the vacuum vessel 200 from a gas blowing hole 211, and is exhausted to the pump 204 from an exhaust port 212 disposed in opposition to the gas supply device 203.

In the plasma processing apparatus thus constituted, the doping source gas introduced from the gas blowing hole 211 such as B₂H₆ is turned into plasma by a plasma generating means made of the microwave waveguide 205 and the electromagnet 207, and boron ion in the plasma 208 is introduced to the surface of the sample 201 by the high frequency power supply 210.

After a metal wiring layer is formed on the sample 201 to which the impurities are thus introduced, a thin oxide film is formed on a metal wiring layer in a prescribed oxide atmosphere, and thereafter a gate electrode is formed on the sample 201 by a CVD apparatus, etc. to obtain an MOS transistor or the like.

Meanwhile, in a field of a general plasma processing apparatus, an induction coupled type plasma processing apparatus having a plurality of gas blowing holes in opposition to the sample has been developed (for example, see Japanese Unexamined Patent Publication No. 2001-15493). FIG. 21 shows the outline structure of a conventional dry etching device described in Japanese Unexamined Patent Publication No. 2001-15493. In FIG. 21, an upper wall of the vacuum vessel 221 is constituted of upper-side and lower-side first and second top plates 222 and 223 formed of dielectric bodies, and multiple coils 224 are arranged on the first top plate 222 and are connected to the high frequency power supply 225. In addition, process gas is supplied toward the first top plate 222 from a gas flow passage 226. On the first top plate 222, a gas main passage 227 formed of one or a plurality of cavities, with one point inside set as a passing point is formed so as to communicate with the gas flow passage 226, and a gas blowing hole 228 is formed so as to reach the gas main passage 227 from a bottom face of the top plate 222. On the second top plate 223, a through hole 229 for blowing out gas is formed at the same position as the gas blowing hole 228. The vacuum vessel 221 is constituted so as to be exhausted by an exhaust port 230 provided on a side wall of the vacuum vessel 221, and a sample electrode 231 is disposed at a lower part in the vacuum vessel 221, so that a sample 232, being a processing object, is held thereon.

In addition, structures as shown in FIG. 22A and FIG. 22B are given as another conventional dry etching device, which is a device for dry etching for removing a film (for example, see Japanese Unexamined Patent Publication No. 2005-507159 which is the translation of PCT International Application). This apparatus supplies process gas to an inside of the vacuum vessel 250 through gas flow passages 240 and 241. The gas flow passage 240 is connected to a mass flow controller 242b, and the gas flow passage 241 is connected to a mass flow controller 242a, respectively, thus controlling gas flow rates independently respectively. Gas is supplied to a substrate center part from the gas flow passage 240, and the gas is supplied to a substrate peripheral part from the gas flow passage 241. Since the gas flow rates supplied to the substrate center part and the substrate peripheral part can be separately independently controlled, this structure is significantly effective for correcting an etching rate of dry etching, which is distributed rotationally symmetric around a substrate center, so as distribute uniformly over an entire surface of the substrate.

In a field of plasma doping also, there is a demand for independently controlling the gas flow rates supplied to the substrate center part and the substrate peripheral part, and uniformly correcting a process distribution which is distributed rotationally symmetric around the substrate center. In a case of the plasma doping, there is not a demand for correcting not an etching rate distribution but a dose amount distribution of implanted boron. In order to respond to such a demand, a plasma doping apparatus as shown in FIG. 23 is proposed (see International Publication WO 2006/106872A1). In this apparatus, the process gas is supplied to the inside of the vacuum vessel 255 through gas flow passages 251 and 252. The gas flow passage 251 is connected to a mass flow controller 253 through a line 251a, and the gas flow passage 252 is connected to a mass flow controller 254 through a line 252a, respectively, thus controlling the gas flow rates independently respectively. The gas is supplied to the center part of a substrate 256 from the gas flow passage 251, and the gas is supplied to the peripheral part of the substrate 256 from the gas flow passage 252. With such a structure, dose amount of impurities distributed rotationally symmetric around the substrate center is corrected so as to be uniformly distributed over the entire surface of the substrate.

### DISCLOSURE OF INVENTION

### Subject to be Solved by the Invention

However, according to the conventional plasma processing apparatus disclosed in the aforementioned patent documents from U.S. Pat. No. 4,912,065, Japanese Unexamined Patent Publication No. 2001-15493, Japanese Unexamined Patent Publication No. 2005-507159, and International Publication WO 2006/106872A1, there is an issue that it is difficult to make the dose amount of impurities in the plasma doping uniform over a substrate main surface.

That is, in a case of applying the conventional apparatus to other process such as the dry etching, variation in a process result over the substrate main surface is small enough not to cause problem in practical use, and the process result can be uniformized with high precision. However, when such an apparatus is applied to the plasma doping, the dose amount of impurities is hardly uniformized over the substrate main surface.

The reason therefore will be explained, with a difference between the dry etching and the plasma doping taken as an example. A large difference in process between the dry etching and the plasma doping is the number of particles (ion, radical, and neutral gas) that have an influence on the process result. The plasma doping is a process of implanting impurity particles such as boron, arsenic, and phosphorus which are electrically active in a semiconductor into the substrate, by the number of a range of from 1×10¹⁴ cm⁻² to 5×10¹⁶ cm⁻². Meanwhile, the number of particles (ion, radical, and neutral gas, being an etchant) that have an influence on the etching rate in the dry etching, radiated on 1 cm⁻² of the substrate main surface is extraordinarily large compared to the plasma doping (such as the number of three digits (about thousandhold). An object of the dry etching is to change a shape of a processing object such as silicon, while an object of the plasma doping is to implant a required amount of impurities, with a shape not changed as much as possible. In a case of the plasma doping that implant the required amount of impurities without changing the shape of the processing object, the process result is determined with dramatically less particles than the particles for dry etching whereby the shape of the processing object is changed. That is, although the plasma doping and the dry etching have the same point that the substrate is processed in a state of being exposed to plasma, the number of particles directly affecting on the process result in plasma doping is extremely smaller than that in the dry etching. Therefore, variation in the number of particles directly affecting on the process result has an extraordinarily larger influence on the variation of the process result, in a case of the plasma doping compared to a case of the dry etching.

As described above, the dry etching is taken as an example for explanation. However, in a process using other plasma such as a CVD, the substrate is directly exposed to plasma, thus obtaining from the plasma a plurality of particles required in the process. Therefore, a difference from the plasma doping is the same in a case of the dry etching.

This causes an issue that while the process result can be uniformized over the substrate main surface with high precision when the conventional apparatus is used in other process such as dry etching, the dose amount of impurities is hardly uniformized over the substrate main surface when such conventional apparatuses are applied to plasma doping.

Further, in a case of the plasma doping, even if an apparatus structure and condition are established to obtain high precision uniformity by one process condition, there is an issue that it is difficult to satisfy a request that the high precision uniformity is obtained based on a plurality of process conditions. This is because since the plasma distribution is changed with a change of the process condition, even if the apparatus has a structure capable of obtaining the high precision uniformity based on other process condition, an excellent uniformity can not be necessarily obtained based on other process condition. From a universal principle that the plasma distribution is changed with the change of the process condition, it is a normal case that an excellent uniformity can not be obtained based on other process condition.

In view of the aforementioned conventional issues, the present invention is provided, and an object of the present invention is to provide an apparatus and a method for plasma doping and a manufacturing method of a semiconductor device which are capable of obtaining a high precision uniformity in plasma doping.

In order to achieve the aforementioned object, the inventors of the present invention obtain the following knowledge, as a result of studying on a reason for not obtaining the high precision uniformity of the plasma doping when a conventional plasma apparatus is applied to plasma doping.

In addition, as an application of the plasma doping, the inventors of the present invention study on the high precision uniformity of the plasma doping in a manufacturing step of forming a source/drain extension region of a silicon device, particularly in which region, the uniformity is hardly secured. Thus, an issue difficult to be apparent conventionally is easily recognized.

FIG. 24A to FIG. 24H are partially sectional views showing the step of forming the source/drain extension region of a planar device by using the plasma doping.

First, as shown in FIG. 24A, an SOI substrate is prepared, which is formed by stacking an n-type silicon layer 263 on a surface of a silicon substrate 261 via an oxide silicon film 262, and an oxide silicon film 264 is formed on the surface as a gate oxide film.

Then, as shown in FIG. 24B, a polycrystal silicon layer 265A is formed, for forming a gate electrode 265.

Next, as shown in FIG. 24C, a mask R is formed by using photolithography.

Thereafter, as shown in FIG. 24D, the polycrystal silicon layer 265A and the oxide silicon film 264 are patterned by using the mask R, to form the gate electrode 265.

Further, as shown in FIG. 24E, boron is introduced by plasma doping, with the gate electrode 265 being as a mask, to form a layer of a shallow p-type impurity region 266 in a dose amount of about 1E15 cm⁻².

Thereafter, as shown in FIG. 24F, according to an LPCVD method (a Low Pressure CVD method) an oxide silicon film 267 is formed on a surface of a layer of the p-type impurity region 266, on an upper surface and a side surface of the gate electrode 265, and on the side surface of the oxide silicon film 264, and then by anisotropic etching, the oxide silicon film 267 is etched, to make the oxide silicon film 267 remain only on a side wall of the gate electrode 265, as shown in FIG. 24G.

As shown in FIG. 24H, boron is implanted by implantation of ion, with the oxide silicon film 267 and the gate electrode 265 being as masks, to form the source/drain region formed of the layer of the p-type impurity region 268, which is then subjected to heat treatment so as to activate boron ion.

Thus, an MOSFET is formed, with a shallow layer of the p-type impurity region 266 formed inside of the source/drain region formed of the layer of the p-type impurity region 268.

At this time, in the step of forming the layer of the shallow p-type impurity region 266, plasma doping is applied by the plasma apparatus to any one of the substrates in the patent documents of U.S. Pat. No. 4,912,065, Japanese Unexamined Patent Publication No. 2001-15493, Japanese Unexamined Patent Publication No. 2005-507159, and International Publication WO 2006/106872A1, shown in FIGS. 20 to 23.

FIG. 25 shows an intra-substrate surface distribution of a sheet resistance of the layer of the source/drain region, when the layer of the source/drain region is formed by the apparatus shown in FIG. 20 disclosed in U.S. Pat. No. 4,912,065. In the apparatus of FIG. 20, the gas flow passage is disposed only on one side viewed from the substrate. Accordingly, a part of the intra-substrate surface close to the gas flow passage (upper-side part of FIG. 25) is processed in a large dose amount, thus lowering the sheet resistance. Meanwhile, a part of the intra-substrate surface far from the gas flow passage (lower-side part of FIG. 25) is processed in a small dose amount, thus increasing the sheet resistance (dose amount and sheet resistance are in an opposite relation to each other, and therefore the relation will be described with only the sheet resistance hereafter). Thus, in the apparatus disposed on only the one side viewed from the substrate, there is an issue that the part where the intra-substrate surface distribution of the sheet resistance is low appears biased on one side.

Next, FIG. 26 shows the intra-substrate surface distribution of the sheet resistance of the layer of the source/drain extension region, when using the apparatus as shown in FIG. 22A and FIG. 22B disclosed in Japanese Unexamined Patent Publication No. 2005-507159. In the apparatus of FIG. 22A and FIG. 22B, the gas flow passage is disposed only in the center part viewed from the substrate. Accordingly, the substrate center part close to the gas flow passage has a low sheet resistance. Meanwhile, the substrate peripheral part far from the gas flow passage has a high sheet resistance. Even if the gas flow rate and gas concentration of the gas flow passage 243 are increased, for the purpose of reducing the sheet resistance of the substrate peripheral part, it can be hardly realized, because it is difficult to supply the gas as far as the substrate peripheral part. Thus, in the apparatus in which the gas flow passage is disposed only on the center part viewed from the substrate, there is an issue that the part of the intra-substrate surface, where the sheet resistance is low, appears biased on the substrate center part.

Next, FIG. 27 shows the intra-substrate surface distribution of the sheet resistance of the layer of the source/drain extension region, when using the apparatus as shown in FIG. 21 disclosed in Japanese Unexamined Patent Publication No. 2001-15493. In the apparatus of FIG. 21, the gas flow passage is disposed on an entire surface viewed from the substrate. Accordingly, the intra-substrate surface distribution of the sheet resistance is more uniform than the distribution shown in FIG. 26. However, depending on the process condition, a difference remains between a sheet resistance SR1 of the substrate center part and a sheet resistance SR2 of the substrate peripheral part, which may possibly cause an issue in practical use. That is, for example, in the aforementioned apparatus of FIG. 21, a gas introducing direction of a gas introduction passage is directed to the right side with respect to the substrate as shown by an arrow in FIG. 27, thus generating the difference due to a deviation of the center of a region of the substrate center part having the sheet resistance SR1 to the right side of FIG. 27 with respect to the center of the substrate. In this case, in the apparatus structure of FIG. 21, the sheet resistances of the substrate center part and the substrate peripheral part can not be controlled separately, thus making it difficult to further uniformize the distribution shown in FIG. 27. Thus, in the apparatus in which one gas flow passage is provided and gas holes are disposed on an entire surface of the substrate, there is an issue that depending on the process condition, the difference in the sheet resistances of the substrate center part and the substrate peripheral part appears, thereby possibly causing an issue in practical use.

Next, FIG. 28 shows the intra-substrate surface distribution of the sheet resistance of the layer of the source/drain extension region, when using the apparatus shown in FIG. 23 disclosed in International Publication WO 2006/106872A1. In the apparatus of FIG. 23, the gas flow passages are disposed on an entire surface viewed from the substrate, and further the gas flow rate and the gas concentration can be controlled independently by the gas flow passages 251 and 252. Thus, in accordance with the process condition, the gas flow rates and the gas concentrations supplied to the substrate center part and the substrate peripheral part can be made variable. Accordingly, the apparatus of FIG. 23 has a more excellent responsiveness to a plurality of process conditions than the apparatus of FIG. 21, similarly, the high precision uniformity expressed by standard deviations under the plurality of process conditions can be provided. However, in the apparatus of FIG. 23, the regions having levels of four kinds of sheet resistances as shown in FIG. 28 appear easily in a complicated distribution. It becomes apparent that this is caused by an arrangement of the gas flow passages. The gas flow passage 251 carries the gas onto the substrate center part from the left side of the substrate as shown in FIG. 28 by the line 251a, and thereafter blows the gas from gas blowing holes on the substrate center part. However, it appears that a movement vector formed when the gas is blown from the gas blowing holes is not vertical to the substrate main surface, but is a direction of a composite of the vector directed toward the right side from the left side of the substrate and the vector vertical to the substrate main surface. As a result, the sheet resistance distribution caused by the gas blown to the substrate center part through the gas flow passage 251 is not completely transferred to the substrate center but is distributed so as to slightly deviate from the substrate center. Similarly, the gas flow passage 252 carries the gas onto the substrate center from the right lower side of the substrate as shown in FIG. 28, and thereafter blows the gas form the gas blowing holes on the substrate peripheral part. However, it appears that the movement vector formed when the gas is blown from the gas blowing holes is not vertical to the substrate main surface but is a direction of the composite of the vector directed toward the left upper side from the right lower side of the substrate and the vector vertical to the substrate main surface. As a result, the sheet resistance distribution caused by the gas blown to the substrate peripheral part via the gas flow passage 252 is not completely transferred in symmetry to the substrate center but is distributed so as to slightly deviate to an upper left side from the substrate center. As a result of the composite of the distributions formed by deviation of the sheet resistance distributions due to the gas flow passages 251 and 252 from the substrate center, a distribution as shown in FIG. 28 would appear. Thus, in the apparatus in which two gas flow passages are provided, the gas holes are disposed on the entire surface of the substrate, and gas flow passages are connected to the gas holes of the substrate center part and the gas holes of the substrate peripheral part separately, the sheet resistance distribution not rotationally symmetric around the substrate center appears and this distribution is complicated, thus involving an issue that this distribution can not be easily corrected, depending on the process condition.

Here, explanation will be given to a different point between a combination of Japanese Unexamined Patent Publication No. 2005-507159 and International Publication WO 2006/106872A1 considered to be particularly close to the present invention out of the aforementioned patent documents, and the present invention.

A largest reason for making it difficult to combine Japanese Unexamined Patent Publication No. 2005-507159 and International Publication WO 2006/106872A1 is that an advantage of the present invention (the advantage that the sheet resistance distribution on the entire surface of the substrate can be corrected so as to obtain the high precision uniformity) can not be easily achieved even by a person skilled in the art. Regarding the apparatus structure of the present invention (for example, the apparatus of FIG. 1 as one embodiment of the present invention), the number of components is increased, compared to each apparatus of Japanese Unexamined Patent Publication No. 2005-507159 and International Publication WO 2006/106872A1, thus complicating the structure, which is not desirable for the person skilled in the art of an apparatus manufacturer.

Meanwhile, the inventors of the present invention found an advantage specific to the apparatus and the method of the present invention. This is the advantage that by using the apparatus and the method of the present invention, the sheet resistance distribution is made approximately completely rotationally symmetric around the center of the substrate, thus making it possible to supply plasma doping gas as far as an end portion of the substrate having a large diameter such as 300 mm, so that the sheet resistance distribution rotationally symmetric around the center of the substrate can be corrected to be uniform.

Such an advantage will be more understandably explained by using the figures.

FIG. 1B is a view showing an example of a gas flow containing impurities by using the apparatus and the method for plasma doping according to a first embodiment of the present invention. The gas flowing through the gas flow passage from an upper side in a lower direction of a top plate (an upper-side vertical gas flow passage) is laterally flown into the gas flow passage inside of the top plate (inside and outside lateral gas flow passages), and thereafter flows to an inside of the vacuum vessel downward from the gas blowing holes via the gas flow passages (lower-side vertical gas flow passages). That is, the gas flows from a start point F1 of an upper end along a central axis of the substrate downward up to a point F2 along the gas flow passage (upper-side vertical gas flow passage), and flows from the point F2 in a lateral direction to a point F3 along the gas flow passage (inside and outside laterally gas flow passage) and thereafter flows downward to a substrate surface from the point F3 along the gas flow passages (lower-side vertical gas flow passages) and the gas blowing holes. Thus, the sheet resistance distribution is made rotationally symmetric around the center of a substrate 9, thus making it possible to supply the plasma doping gas as far as the end portion of the substrate having a large diameter such as 300 mm, and the sheet resistance distribution can be corrected over the entire surface of the substrate, so as to obtain the high precision uniformity of the sheet resistance distribution.

Meanwhile, FIG. 1C shows the gas flow of Japanese Unexamined Patent Publication No. 2005-507159. In Japanese Unexamined Patent Publication No. 2005-507159, the gas flows from a start point F11 of an upper end, partially branched obliquely downward through a point F12, and thereafter flows downward up to the substrate surface. This makes the sheet resistance distribution rotationally symmetric around a central axis of the substrate 9. However, the plasma doping gas can be supplied only to the central part of the substrate, and the plasma doping gas can not be supplied as far as the end portion of the substrate having a large diameter such as 300 mm. Accordingly, the sheet resistance distribution can not be uniformly corrected over the entire surface of the substrate.

FIG. 1D shows the gas flow of International Publication WO 2006/106872A1. In International Publication WO 2006/106872A1, the gas flows from a start point F21 of a left end in a lateral direction (in a right direction) laterally up to a point F22, and flows downward from the point F22 to a point F23, flows laterally from the point F23 to a point F24, and thereafter flows downward from the point F24 to the substrate surface. Thus, a second lateral flow distance is extremely short. Therefore, the sheet resistance distribution can not be rotationally symmetric around the substrate central axis. Accordingly, the sheet resistance distribution can not be uniformly corrected over the entire surface of the substrate.

This reveals that the present invention is not easily anticipated.

As described above, the present invention is not easily anticipated. However, explanation will be given next to a reason for not easily realizing the present invention by the person skilled in the art, by simply combining Japanese Unexamined Patent Publication No. 2005-507159, and International Publication WO 2006/106872A1, even if the above-described matter is anticipated.

First, explanation will be given to the gas flow, with reference to FIG. 22A and FIG. 22B. When the gas flow in the apparatus of Japanese Unexamined Patent Publication No. 2005-507159 is made to flow “from a start point at an upper end downward along the central axis of the substrate, laterally and thereafter downward” as described in the present invention, a failure occurs as described below. In the apparatus of Japanese Unexamined Patent Publication No. 2005-507159, the top plate and a nozzle function separately, and a gas inflow path is formed only in the nozzle, and is not formed at all in the top plate, and a position of a rotating direction of the nozzle with respect to the top plate is not particularly defined. Therefore, even if the top plate is the top plate having a plurality of gas flow passages like that of International Publication WO 2006/106872A1, the gas flow passage in the nozzle and the gas flow passage in the top plate can not be connected to each other in a state of the top plate as it is.

Next, the gas flow passage will be explained with reference to FIG. 23. When the gas flow in the apparatus of International Publication WO 2006/106872A1 is made to flow “from a start position at an upper end downward along the central axis of the substrate, then laterally, and thereafter downward”, the failure occurs. The apparatus of International Publication WO 2006/106872A1 has a coil above the central part of the top plate, and the gas flow passage such as a metallic pipe and a quartz pipe can not be provided above the center of the top plate. If the gas flow passage is forcibly provided, an arrangement of the coil is changed and a magnetic field is distorted, thus involving an issue that the uniformity of the plasma is not rotationally symmetric around the central axis of the substrate, resulting in being non-uniform.

Based on the aforementioned knowledge, the inventors of the present invention achieves the invention of the apparatus and the method for plasma doping and the manufacturing method of the semiconductor device, capable of tremendously improving the uniformity of the sheet resistance distribution over the entire surface of the substrate.

In order to achieve the above-described object, the present invention takes several aspects as follows.

According to a first aspect of the present invention, there is provided a plasma doping apparatus comprising:

a vacuum vessel having a top plate;

an electrode disposed in the vacuum vessel, for placing a substrate thereon;

a high frequency power supply for applying a high frequency power to the electrode;

an exhaust device for exhausting an inside of the vacuum vessel; and

a plurality of gas supply devices for supplying gas into the vacuum vessel; and

a gas-nozzle member having a plurality of upper-side vertical gas flow passages extending along a longitudinal direction of the gas-nozzle member with the longitudinal direction of the gas-nozzle member being perpendicular to a surface of the electrode,

the top plate having a plurality of gas blow holes on a vacuum vessel inner surface of the top plate in opposition to the electrode, the upper-side vertical gas flow passages of the gas-nozzle member being respectively connected to the plurality of gas supply devices.

In a modification of the first aspect, there might be provided the plasma doping apparatus according to the first aspect, wherein the top plate has gas flow passages comprising the upper-side vertical gas flow passages extending downward in a vertical direction along a central axis of the electrode from a central part of a surface of the top plate on an opposite side to the vacuum vessel inner surface in opposition to the electrode, a plurality of lateral gas flow passages branched independently respectively in a lateral direction intersecting with the vertical direction and communicated with the upper-side vertical gas flow passages, and lower-side vertical gas flow passages extending vertically downward from the lateral gas flow passages and communicated with the gas blow holes respectively,

the plasma doping apparatus further comprising:

gas supply lines, with one ends communicated with the gas supply devices, and other ends vertically connected with the central part of the surface of the top plate on the opposite side to the vacuum vessel inner surface in opposition to the electrode, thereby forming flows along the vertical direction by the gas supplied from the gas supply devices.

According to a second aspect of the present invention, there is provided the plasma doping apparatus according to the first aspect,

wherein the top plate comprises a recess portion at a central part of an outer surface of the top plate on an opposite side to the electrode, the gas-nozzle member is fitted into the recess portion of the top plate, the top plate has gas flow passages comprising the upper-side vertical gas flow passage of the gas-nozzle member, a plurality of lateral gas flow passages branched independently respectively in a lateral direction intersecting with the longitudinal direction of the gas-nozzle member and communicated with the upper-side vertical gas flow passage, and a lower-side vertical gas flow passage extending downward along the longitudinal direction from the lateral gas flow passage and communicated with the gas blow holes respectively.

According to a third aspect of the present invention, there is provided the plasma doping apparatus according to the first or second aspect, further comprising:

a plurality of gas supply lines, with respective one ends communicated with the gas supply devices, and respective other ends vertically connected with the upper-side vertical gas flow passage of the gas-nozzle member, thereby forming flows along the vertical direction by the gas supplied from the gas supply devices;

wherein the top plate is constituted by laminating a plurality of plate-like members;

the gas supply devices are a first gas supply device and a second gas supply device; and the gas supply lines and the gas flow passages are separately and independently provided to each of the first gas supply device and the second gas supply device.

According to a fourth aspect of the present invention, there is provided the plasma doping apparatus according to the second aspect, further comprising:

a plurality of gas supply lines, with respective one ends communicated with the gas supply devices, and respective other ends vertically connected with the upper-side vertical gas flow passage of the gas-nozzle member, thereby forming flows along the vertical direction by the gas supplied from the gas supply devices;

wherein the lower-side vertical gas flow passages and the lateral gas flow passages in the top plate are:

a first lower-side vertical gas flow passage that communicates with a first gas blow hole out of the plurality of gas blow holes;

a first lateral gas flow passage that communicates with the first lower-side vertical gas flow passage;

a second lower-side vertical gas flow passage that communicates with a second gas blow hole out of the plurality of gas blow holes and independent of the first lower-side vertical gas flow passage; and

a second lateral gas flow passage that communicates with the second lower-side vertical gas flow passage and independent of the first lateral gas flow passage; and

the gas-nozzle member comprises a disc part having a communication-switching gas flow passage rotatable with respect to the gas-nozzle member, capable of communicating with the upper-side vertical gas flow passage and capable of selectively communicating with the first lateral gas flow passage and the second lateral gas flow passage in accordance with rotational positions,

wherein by changing the rotational position of the disc part of the gas-nozzle member, either one of the first lateral gas flow passage and the second lateral gas flow passage, and the communication-switching gas flow passage are selectively communicated to each other, so that the gas is blown from a gas blow hole that communicates with the lateral gas flow passage that is selectively communicated, through either one of the first lateral gas flow passage and the second lateral gas flow passage that is selectively communicated, via the gas supply line and the upper-side vertical gas flow passage of the gas-nozzle member and the communication-switching gas flow passage from the gas supply device.

According to an aspect of the present invention, there is provided the plasma doping apparatus according to any one of the first to fourth aspects, wherein the gas supply device is a device for supplying gas containing boron and diluted with rare gas or hydrogen.

According to an aspect of the present invention, there is provided the plasma doping apparatus according to any one of the first to fourth aspects, wherein the gas supply device is a device for supplying gas containing boron and diluted with hydrogen or helium.

According to a fifth aspect of the present invention, there is provided the plasma doping apparatus according to any one of the first to fourth aspects, wherein the gas supply device is a device for supplying gas containing B₂H₆.

According to a sixth aspect of the present invention, there is provided the plasma doping apparatus according to any one of the first to fourth aspects, wherein the gas supply device is a device for supplying gas containing impurities and diluted with rare gas or hydrogen, with a concentration of the gas containing the impurities set at not less than 0.05 wet % and not more than 5.0 wet %.

According to a seventh aspect of the present invention, there is provided the plasma doping apparatus according to any one of the first to fourth aspects, wherein the gas supply device is a device for supplying gas containing impurities and diluted with rare gas or hydrogen, with a concentration of the gas containing the impurities set at not less than 0.2 wet % and not more than 2.0 wet %.

According to an eighth aspect of the present invention, there is provided the plasma doping apparatus according to any one of the first to ninth aspects, wherein a bias voltage of the high frequency power applied from the high frequency power supply is not less than 30 V and not more than 600 V.

According to a ninth aspect of the present invention, there is provided the plasma doping apparatus according to any one of the first to ninth aspects, wherein the exhaust device is communicated with an exhaust opening disposed on a bottom surface of the vacuum vessel on an opposite side of the electrode to the top plate, regarding the electrode.

According to a 10th aspect of the present invention, there is provided a plasma doping method of performing plasma doping by using a plasma doping apparatus comprising:
a vacuum vessel having a top plate;
an electrode disposed in the vacuum vessel, for placing a substrate thereon;
a high frequency power supply for applying high frequency power to the electrode;
an exhaust device for exhausting an inside of the vacuum vessel;
a plurality of gas supply devices for supplying gas into the vacuum vessel;
a gas-nozzle member having a plurality of upper-side vertical gas flow passages extending along a longitudinal direction of the gas-nozzle member with the longitudinal direction of the gas-nozzle member being perpendicular to a surface of the electrode; and
a plurality of gas blow holes disposed on a vacuum vessel inner surface of the top plate in opposition to the electrode, the upper-side vertical gas flow passages of the gas-nozzle member being respectively connected to the plurality of gas supply devices,

the plasma doping method comprising:
supplying the gas from the gas supply devices into gas flow passages of the top plate by gas supply lines, with one ends of the gas supply lines communicated with the gas supply devices and other ends of the gas supply lines connected along a vertical direction along a central axis of the electrode to a central part of a surface of the top plate on an opposite side to the vacuum vessel inner surface of the top plate in opposition to the electrode, while forming flows along the vertical direction toward the gas flow passages of the top plate; and
flowing the gas in the gas flow passages of the top plate, sequentially through upper-side vertical gas flow passages extending downward in the vertical direction from the central part of the surface of the top plate on the opposite side to the vacuum vessel inner surface of the top plate in opposition to the electrode, a plurality of lateral gas flow passages that communicate with the upper-side vertical gas flow passages and which are independently branched in a lateral direction intersecting with the vertical direction, and a lower-side vertical gas flow passages extending downward in the vertical direction from the lateral gas flow passages and which communicate with the plurality of gas blow holes respectively, and supplying the gas into the vacuum vessel by blowing out the gas from the plurality of gas blow holes; and
implanting impurities into a source/drain extension region of the substrate at a time of the plasma doping by using gas containing the impurities and diluted with rare gas or hydrogen is used as the gas, with a concentration of the gas containing the impurities set at not less than 0.05 wet % and not more than 5.0 wet %, and bias voltage of the high frequency power applied by the high frequency power supply set at not less than 30 V and not more than 600 V.

According to an 11th aspect of the present invention, there is provided the plasma doping method according to the 10th aspect, comprising:

firstly performing the plasma doping to a first dummy substrate before performing to the substrate to implant the impurities into the first dummy substrate;

subsequently electrically activating the impurities of the first dummy substrate by annealing;

subsequently comparing with a threshold value, information regarding a uniformity of a distribution obtained by measuring an in-surface sheet resistance distribution of the first dummy substrate, and then determining the uniformity of the in-surface sheet resistance distribution of the first dummy substrate;

when a sheet resistance of a substrate central part of the first dummy substrate is determined to be excellent, replacing the first dummy substrate with the substrate and then performing the plasma doping to the substrate to implant the impurities into the substrate;

meanwhile, when the sheet resistance of the substrate central part of the first dummy substrate is determined not to be excellent and the sheet resistance of the substrate central part of the first dummy substrate is determined to be smaller than that of a substrate peripheral part of the first dummy substrate, replacing the first dummy substrate with a second dummy substrate, blowing the gas from the blow hole of the gas in opposition to a substrate central part of the second dummy substrate in a state of stopping blow of the gas from the blow hole of the gas in opposition to a substrate peripheral part of the second dummy substrate, and performing the plasma doping to the second dummy substrate to implant the impurities into the second dummy substrate; and

when the sheet resistance of the substrate central part is determined not to be excellent and the sheet resistance of the substrate central part of the first dummy substrate is determined to be larger than that of the substrate peripheral part of the first dummy substrate, replacing the first dummy substrate with a second dummy substrate, blowing the gas from the blow hole of the gas in opposition to the substrate peripheral part of the second dummy substrate in a state of stopping the blow of the gas from the blow hole of the gas in opposition to the substrate central part of the second dummy substrate, and performing the plasma doping to the second dummy substrate to implant the impurities into the second dummy substrate; then

after performing the plasma doping to the second dummy substrate, comparing with a threshold value, information regarding a uniformity of a distribution obtained by measuring an in-surface sheet resistance distribution of the second dummy substrate, and determining the uniformity of the in-surface sheet resistance distribution of the second dummy substrate, and adjusting gas blow amounts from the gas blow hole in opposition to the substrate central part of the second dummy substrate and the gas blow hole in opposition to the substrate peripheral part of the second dummy substrate to correct a uniformity of an in-surface sheet resistance distribution of the substrate, thereafter replacing the second dummy substrate with the substrate, thereby performing the plasma doping to the substrate to implant the impurities into the substrate.

According to a 12th aspect of the present invention, there is provided the plasma doping method according to the 10th aspect, comprising:

firstly performing the plasma doping to a first dummy substrate before performing to the substrate to implant the impurities into the first dummy substrate;

subsequently electrically activating the impurities of the first dummy substrate by annealing;

subsequently comparing with the threshold value, information regarding a uniformity of a distribution obtained by measuring an in-surface sheet resistance distribution of the first dummy substrate, and then determining the uniformity of the in-surface sheet resistance distribution of the first dummy substrate; and

when a sheet resistance of a substrate central part of the first dummy substrate is determined to be excellent, replacing the first dummy substrate with the substrate and then performing the plasma doping to the substrate to implant the impurities into the substrate;

meanwhile, when the sheet resistance of the substrate central part of the first dummy substrate is determined not to be excellent, and the sheet resistance of the substrate central part of the first dummy substrate is determined to be smaller than that of a substrate peripheral part of the first dummy substrate, decreasing a concentration of the impurities of the gas blown from the blow hole of the gas in opposition to a substrate peripheral part of the second dummy substrate, and increasing a concentration of the impurities of the gas blown from the blow hole of the gas in opposition to a substrate central part of the second dummy substrate, and then performing the plasma doping to the second dummy substrate to implant the impurities into the second dummy substrate; and

when the sheet resistance of the substrate central part of the first dummy substrate is determined not to be excellent and the sheet resistance of the substrate central part of the first dummy substrate is determined to be large than that of the substrate peripheral part of the first dummy substrate, replacing the first dummy substrate with a second dummy substrate, decreasing a concentration of the impurities of the gas blown from the blow hole of the gas in opposition to a substrate central part of the second dummy substrate, increasing a concentration of the impurities of the gas blown from the blow hole of the gas in opposition to the blow hole of the gas in opposition to a substrate peripheral part of the second dummy substrate, and the performing the plasma doping to the second dummy substrate to implant the impurities into the second dummy substrate; then

after performing the plasma doping to the second dummy substrate, comparing with the threshold value, information regarding a uniformity of a distribution obtained by measuring an in-surface sheet resistance distribution of the second dummy substrate, determining the uniformity of the in-surface sheet resistance distribution of the second dummy substrate, and adjusting concentrations of the impurities of the gas from the blow hole of the gas in opposition to the substrate central part of the second dummy substrate and the blow hole of the gas in opposition to the substrate peripheral part of the second dummy substrate to correct a uniformity of an in-surface sheet resistance distribution of the substrate, thereafter replacing the second dummy substrate with the substrate, thereby performing the plasma doping to the substrate to implant the impurities into the substrate.

According to a 13th aspect of the present invention, there is provided the plasma doping method according to any one of the 10th to 12th aspects, wherein the concentration of the impurities of the gas is not less than 0.2 wet % and not more than 2.0 wet %.

According to a 14th aspect of the present invention, there is provided the plasma doping method according to any one of the 10th to 13th aspects, wherein thereby the gas is supplied in independent two lines of a first gas supply device and a second gas supply device which the gas supply device comprises, and to which the gas supply lines and the gas flow passages are separately and independently provided respectively.

According to an aspect of the present invention, there is provided the plasma doping method according to any one of the 10th to 14th aspects, wherein the gas containing boron is supplied from the gas supply device.

According to an aspect of the present invention, there is provided the plasma doping method using the plasma doping apparatus according to any one of the 10th to 14th aspects, wherein the gas containing B₂H₆ is supplied from the gas supply device.

According to an aspect of the present invention, there is provided the plasma doping method according to any one of the 10th to 14th aspects, wherein rare gas in the gas supplied from the gas supply device is helium.

According to an aspect of the present invention, there is provided the plasma doping method according to any one of the 10th to the previous aspects, wherein the impurities are implanted into a channel region under a gate, instead of the source/drain extension region.

According to an aspect of the present invention, there is provided the plasma doping method according to the previous aspect, wherein phosphorus is selected instead of the boron.

According to an aspect of the present invention, there is provided the plasma doping method according to the previous aspect, wherein arsenic is selected instead of the boron.

According to a 15th aspect of the present invention, there is provided a manufacturing method of a semiconductor device for manufacturing a semiconductor device, by performing plasma doping using a plasma doping apparatus comprising:
a vacuum vessel having a top plate;
an electrode disposed in the vacuum vessel, for placing a substrate thereon;
a high frequency power supply for applying high frequency power to the electrode;
an exhaust device for exhausting an inside of the vacuum vessel;
a plurality of gas supply devices for supplying gas into the vacuum vessel;
a gas-nozzle member having a plurality of upper-side vertical gas flow passages extending along a longitudinal direction of the gas-nozzle member with the longitudinal direction of the gas-nozzle member being perpendicular to a surface of the electrode; and
a plurality of gas blow holes disposed on a vacuum vessel inner surface of the top plate in opposition to the electrode, the upper-side vertical gas flow passages of the gas-nozzle member being respectively connected to the plurality of gas supply devices,

the method comprising:
supplying the gas from the gas supply devices into gas flow passages of the top plate while forming flows in a vertical direction along a central axis of the electrode toward gas flow passages of the top plate, by gas supply lines, with one ends of the gas supply lines communicated with the gas supply devices and other ends of the gas supply lines connected along the vertical direction to a central part of a surface of the top plate on an opposite side to a vacuum vessel inner surface of the top plate in opposition to the electrode;
flowing the gas in the gas flow passages of the top plate, sequentially through upper-side vertical gas flow passages extending downward in the vertical direction from the central part of the surface of the top plate on the opposite side to the vacuum vessel inner surface in opposition to the electrode, a plurality of lateral gas flow passages that communicate with the upper-side vertical gas flow passages and which are independently branched in a lateral direction intersecting with the vertical direction, and lower-side vertical gas flow passages extending downward in the vertical direction from the lateral gas flow passages and which communicate with the plurality of gas blow holes respectively, and supplying the gas into the vacuum vessel by blowing the gas from the plurality of gas blow holes; and
implanting impurities into a source/drain extension region of the substrate at a time of the plasma doping by using gas containing the impurities and diluted with rare gas or hydrogen which is used as the gas, with a concentration of the impurities of the gas set at not less than 0.05 wet % and not more than 5.0 wet %, and bias voltage of the high frequency power applied by the high frequency power supply set at not less than 30 V and not more than 600 V.

According to the present invention, the gas supplied to the gas flow passage of the top plate from the gas supply device by the gas supply line can form the flow along the vertical direction along the central axis of the substrate. Therefore, the gas blown from the gas blowing holes can be made uniform and the sheet resistance distribution is made to be rotationally symmetrical to the substrate center, thus making it possible to provide the apparatus and the method for plasma doping capable of obtaining the high-precision uniformity of the sheet resistance distribution in plasma doping.

### BRIEF DESCRIPTION OF DRAWINGS

These and other aspects and features of the present invention will become clear from the following description taken in conjunction with the preferred embodiments thereof with reference to the accompanying drawings, in which:

FIG. 1A is a partially sectional view of a plasma doping apparatus according to a first embodiment of the present invention;

FIG. 1B is an explanatory view for explaining an example of a flow of plasma doping gas containing impurities by the apparatus and a method for plasma doping according to the first embodiment of the present invention;

FIG. 1C is an explanatory view for explaining the flow of the gas of Japanese Unexamined Patent Publication No. 2005-507159;

FIG. 1D is an explanatory view for explaining the flow of the gas of International Publication WO 2006/106872A1;

FIG. 1E is a specifically explanatory view for explaining an example of the flow of the plasma doping gas containing the impurities by the apparatus and the method for plasma doping according to the first embodiment of the present invention with a state where molecules of the gas flow in lines schematically shown by arrows, in a similar way to FIG. 1B;

FIG. 1F is a specifically explanatory view for explaining the flow of the gas of the International Publication WO 2006/106872A1 with a state where molecules of the gas flow in lines schematically shown by arrows, in a similar way to FIG. 1D;

FIG. 2A is a partially sectional view of a gas flow passage forming member (gas-nozzle member), in a state that the gas flow passage forming member of the plasma doping apparatus according to the first embodiment of the present invention is attached to a central part of a top plate and the central part of the top plate;

FIG. 2B is an enlarged partially sectional view of the gas flow passage forming member, in a state that the gas flow passage forming member of the plasma doping apparatus according to the first embodiment of the present invention is attached to the central part of the top plate and the central part of the top plate;

FIG. 2C is a plan view of the top plate before the gas flow passage forming member of the plasma doping apparatus according to the first embodiment of the present invention is attached to the central part of the top plate;

FIG. 2D is a partially sectional view of the gas flow passage forming member and the central part of the top plate in a state that the gas flow passage forming member of the plasma doping apparatus according to the first embodiment of the present invention is detached from the central part of the top plate or in a state just before attached thereto;

FIG. 3A is a plan view of a plate-like member of a first layer of the top plate of the plasma doping apparatus according to the first embodiment of the present invention in a case where the top plate is divided for each laminated portion;

FIG. 3B is a plan view of the plate-like member of a second layer of the top plate of a plasma doping apparatus according to the first embodiment of the present invention in a case where the top plate is divided for each laminated portion;

FIG. 3C is a plan view of a plate-like member of a third layer of the top plate of the plasma doping apparatus according to the first embodiment of the present invention in a case where the top plate is divided for each laminated portion;

FIG. 3D is a view showing a sheet resistance distribution of a substrate with a diameter of 300 mm after 20 seconds from plasma doping start, which shows a result of simulation carried out by using the apparatus of FIGS. 22A and 22B in order to obtain a ratio of a radius of an inner circle and a radius of an outer circle in FIG. 3A regarding gas supply control of substrate central part gas blowing holes and substrate peripheral part gas blowing holes of the top plate of the plasma doping apparatus according to the first embodiment of the present invention;

FIG. 3E is a view showing a sheet resistance distribution of the substrate with the diameter of 300 mm after 40 seconds from the plasma doping start, which shows a result of the simulation of FIG. 3D;

FIG. 3F is a view showing a sheet resistance distribution of the substrate with the diameter of 300 mm after 60 seconds from the plasma doping start, which shows a result of the simulation of FIG. 3D;

FIG. 3G is a view showing a sheet resistance distribution of the substrate with the diameter of 300 mm after 120 seconds from the plasma doping start, which shows a result of the simulation of FIG. 3D;

FIG. 3H is a view showing a sheet resistance distribution of the substrate with the diameter of 300 mm after 200 seconds from the plasma doping start, which shows a result of the simulation of FIG. 3D;

FIG. 4A is a partially sectional view of a first gas supply line and a second gas supply line and the central part of the top plate in a state that the first gas supply line and the second gas supply line from a gas supply device of a plasma doping apparatus according to a first modification of the first embodiment of the present invention are directly attached to the central part of the top plate;

FIG. 4B is an enlarged partially sectional view of the first gas supply line and the second gas supply line in a state of the aforementioned attachment state of FIG. 4A, and the central part of the top plate;

FIG. 4C is a plan view of the top plate before the first gas supply line and the second gas supply line of the plasma doping apparatus according to the first modification of the first embodiment of the present invention are attached to the central part of the top plate;

FIG. 5A is a plan view of a plate-like member of a first layer of the top plate of the plasma doping apparatus according to the first modification of the first embodiment of the present invention in a case where the top plate is divided for each laminated portion;

FIG. 5B is a plan view of a plate-like member of a second layer of the top plate of the plasma doping apparatus according to the first modification of the first embodiment of the present invention in a case where the top plate is divided for each laminated portion;

FIG. 5C is a plan view of a plate-like member of a third layer of the top plate of the plasma doping apparatus according to the first modification of the first embodiment of the present invention in a case where the top plate is divided for each laminated portion;

FIG. 6A is a sectional view of a gas flow passage forming member of a plasma doping apparatus according to a second modification of the first embodiment of the present invention;

FIG. 6B is a sectional view of the top plate of the plasma doping apparatus according to the second modification of the first embodiment of the present invention;

FIG. 6C is an enlarged partially sectional view of the gas flow passage forming member and the central part of the top plate in a state just before the gas flow passage forming member of the plasma doping apparatus according to the second modification of the first embodiment of the present invention is attached to the top plate;

FIG. 6D is a plan view of the top plate before the gas flow passage forming member of the plasma doping apparatus according to the second modification of the first embodiment of the present invention is attached to the central part of the top plate;

FIG. 7A is a plan view of a plate-like member of a first layer of the top plate of a plasma doping apparatus according to the second modification of the first embodiment of the present invention in a case where the top plate is divided for each laminated portion;

FIG. 7B is a plan view of a plate-like member of a second layer of the top plate of the plasma doping apparatus according to the second modification of the first embodiment of the present invention in a case where the top plate is divided for each laminated portion;

FIG. 7C is a plan view of a plate-like member of a third layer of the top plate of the plasma doping apparatus according to the second modification of the first embodiment of the present invention in a case where the top plate is divided for each laminated portion;

FIG. 8A is a sectional view of a gas flow passage forming member of a plasma doping apparatus according to a third modification of the first embodiment of the present invention;

FIG. 8B is a sectional view of the top plate of the plasma doping apparatus according to the third modification of the first embodiment of the present invention;

FIG. 8C is an enlarged partially sectional view of the gas flow passage forming member and the central part of the top plate in a state just before the gas flow passage forming member of the plasma doping apparatus according to the third modification of the first embodiment of the present invention is attached to the central part of the top plate;

FIG. 8D is a plan view of the top plate before the gas flow passage forming member of the plasma doping apparatus according to the third modification of the first embodiment of the present invention is attached to the central part of the top plate;

FIG. 9A is a plan view of a plate-like member of a first layer of the top plate of the plasma doping apparatus according to the third modification of the first embodiment of the present invention in a case where the top plate is divided for each laminated portion;

FIG. 9B is a plan view of a plate-like member of a second layer of the top plate of the plasma doping apparatus according to the third modification of the first embodiment of the present invention in a case where the top plate is divided for each laminated portion;

FIG. 9C is a plan view of a plate-like member of a third layer of the top plate of the plasma doping apparatus according to the third modification of the first embodiment of the present invention in a case where the top plate is divided for each laminated portion;

FIG. 10 is a partially sectional view of the plasma doping apparatus according to the second embodiment of the present invention, with the view showing a case that a rotational angle of a disc part of a tip end of the gas flow passage forming member is 0°;

FIG. 11 is a partially sectional view of the plasma doping apparatus according to the second embodiment of the present invention, with the view showing a case that the rotational angle of the disc part of the tip end of the gas flow passage forming member is 45°;

FIG. 12A is a sectional view of the gas flow passage forming member of the plasma doping apparatus according to the second embodiment of the present invention;

FIG. 12B is a sectional view of FIG. 12A taken along the A-A line;

FIG. 12C is a sectional view of FIG. 12A taken along the B-B line;

FIG. 12D is a sectional view of the top plate of the plasma doping apparatus according to the second embodiment of the present invention;

FIG. 12E is an enlarged partially sectional view of the gas flow passage forming member and the central part of the top plate in a state just before the gas flow passage forming member of the plasma doping apparatus according to the second embodiment of the present invention is attached to the central part of the top plate;

FIG. 12F is an enlarged partially sectional view of a lower part of the gas flow passage forming member of the plasma doping apparatus according to the second embodiment of the present invention;

FIG. 12G is an explanatory view of a rotation mechanism of the plasma doping apparatus according to the second embodiment of the present invention;

FIG. 13A is a plan view of a plate-like member of a first layer of the top plate of the plasma doping apparatus according to the second embodiment of the present invention in a case where the top plate is divided for each laminated portion;

FIG. 13B is a plan view of a plate-like member of a second layer of the top plate of the plasma doping apparatus according to the second embodiment of the present invention in a case where the top plate is divided for each laminated portion;

FIG. 13C is a plan view of a plate-like member of a third layer of the top plate of the plasma doping apparatus according to the second embodiment of the present invention in a case where the top plate is divided for each laminated portion;

FIG. 14A is a sectional view of FIG. 12A taken along the line A-A when a rotational angle of a disc part of a tip end of the gas flow passage forming member is 0°, in the plasma doping apparatus according to the second embodiment of the present invention;

FIG. 14B is a sectional view of FIG. 12A taken along the line B-B when the rotational angle of the disc part of the tip end of the gas flow passage forming member is 0°, in the plasma doping apparatus according to the second embodiment of the present invention;

FIG. 14C is a plan view of a plate-like member of a first layer of the top plate, showing a gas flow passage and gas blowing holes through which the gas flows when the rotational angle of the disc part of the tip end of the gas flow passage forming member is 0°, in the plasma doping apparatus according to the second embodiment of the present invention;

FIG. 14D is a plan view of the plate-like member of a second layer of the top plate, showing the gas flow passage and the gas blowing holes through which the gas flows when the rotational angle of the disc part of the tip end of the gas flow passage forming member is 0°, in the plasma doping apparatus according to the second embodiment of the present invention;

FIG. 14E is a plan view of the plate-like member of a third layer of the top plate, showing the gas flow passage and the gas blowing hole through which the gas flows when the rotational angle of the disc part of the tip end of the gas flow passage forming member is 0°, in the plasma doping apparatus according to the second embodiment of the present invention;

FIG. 15A is a sectional view of FIG. 12A taken along the line A-A when the rotational angle of the disc part of the tip end of the gas flow passage forming member is 45°, in the plasma doping apparatus according to the second embodiment of the present invention;

FIG. 15B is a sectional view of FIG. 12A taken along the line B-B when the rotational angle of the disc part of the tip end of the gas flow passage forming member is 45°, in the plasma doping apparatus according to the second embodiment of the present invention;

FIG. 15C is a plan view of the plate-like member of the first layer of the top plate, showing the gas flow passage and the gas blowing holes through which the gas flows when the rotational angle of the disc part of the tip end of the gas flow passage forming member is 45°, in the plasma doping apparatus according to the second embodiment of the present invention;

FIG. 15D is a plan view of a plate-like member of a second layer of the top plate, showing the gas flow passage and the gas blowing hole through which the gas flows when the rotational angle of the disc part of the tip end of the gas flow passage forming member is 45°, in the plasma doping apparatus according to the second embodiment of the present invention;

FIG. 15E is a plan view of a plate-like member of a third layer of the top plate, showing the gas flow passage and the gas blowing hole through which the gas flows when the rotational angle of the disc part of the tip end of the gas flow passage forming member is 45°, in the plasma doping apparatus according to the second embodiment of the present invention;

FIG. 16 is a flowchart showing a method of correcting the uniformity of a sheet resistance distribution by adjusting a gas total flow rate, as a modification of a third embodiment of the present invention;

FIG. 17 is a flowchart showing the method of correcting the uniformity of the sheet resistance distribution by adjusting a gas concentration, as a modification of the third embodiment of the present invention;

FIG. 18 is an explanatory view explaining the sheet resistance of a substrate before and after correction with (b) showing an explanatory view of a case that the uniformity of the sheet resistance distribution is not more excellent than a desired precision, and the sheet resistance of a substrate central part is smaller than that of a substrate peripheral part, and (a) showing an explanatory view of a case that the uniformity of the sheet resistance distribution is more excellent than the desired precision;

FIG. 19 is an explanatory view explaining the sheet resistance of the substrate before and after correction, with (c) showing an explanatory view of a case that the uniformity of the sheet resistance distribution is not more excellent than the desired precision and the sheet resistance of the substrate central part is larger than that of the substrate peripheral part, and (a) showing an explanatory view of a case that the uniformity of the sheet resistance distribution is more excellent than the desired precision;

FIG. 20 is a partially sectional view of a conventional plasma doping apparatus in U.S. Pat. No. 4,912,065;

FIG. 21 is a partially sectional view of a conventional dry etching device in Japanese Unexamined Patent Publication No. 2001-15493;

FIG. 22A is a partially sectional view of a conventional dry etching device in Japanese Unexamined Patent Publication No. 2005-507159;

FIG. 22B is an enlarged sectional view of the dry etching device in Japanese Unexamined Patent Publication No. 2005-507159;

FIG. 23 is a partially sectional view (of FIG. 28 taken along the XIII-XIII line) of the plasma doping apparatus in International Publication WO 2006/106872A1;

FIG. 24A is a view showing a manufacturing step of an MOSFET using the plasma doping method of the present invention;

FIG. 24B is a view showing the manufacturing step of the MOSFET using the plasma doping method of the present invention following FIG. 24A;

FIG. 24C is a view showing the manufacturing step of the MOSFET using the plasma doping method of the present invention following FIG. 24B;

FIG. 24D is a view showing the manufacturing step of the MOSFET using the plasma doping method of the present invention following FIG. 24C;

FIG. 24E is a view showing the manufacturing step of the MOSFET using the plasma doping method of the present invention following FIG. 24D;

FIG. 24F is a view showing the manufacturing step of the MOSFET using the plasma doping method of the present invention following FIG. 24E;

FIG. 24G is a view showing the manufacturing step of the MOSFET using the plasma doping method of the present invention following FIG. 24F;

FIG. 24H is a view showing the manufacturing step of the MOSFET using the plasma doping method of the present invention following FIG. 24G;

FIG. 25 is an explanatory view showing an intra-substrate surface distribution of the sheet resistance when a layer of a source/drain extension region is formed by a conventional plasma doping apparatus as described in FIG. 20;

FIG. 26 is an explanatory view showing the intra-substrate surface distribution of the sheet resistance when gas containing impurities is supplied to a conventional dry etching device as described in FIG. 22 and then the layer of the source/drain extension region is formed;

FIG. 27 is an explanatory view showing the intra-substrate surface distribution of the sheet resistance when the gas containing the impurities is supplied to the conventional dry etching device as described in FIG. 21 and then the layer of the source-drain extension region is formed; and

FIG. 28 is an explanatory view showing the intra-substrate surface distribution of the sheet resistance when the layer of the source/drain extension region is formed by the conventional plasma doping apparatus as described in FIG. 23.

### BEST MODE FOR CARRYING OUT THE INVENTION

Before the description of the present invention proceeds, it is to be noted that like parts are designated by like reference numerals throughout the accompanying drawings.

First, before explaining the embodiments according to the present invention, detailed explanation will be given to the apparatus and the method for plasma doping of the present invention for achieving the aforementioned object.

Specifically, a plasma doping apparatus according to one aspect of the present invention includes a gas flow passage forming member (gas-nozzle member) having a plurality of gas passages vertically along a central axis of a substrate placement region of a sample electrode or the substrate, with respect to a substrate main surface (surface of the substrate to be subjected to plasma doping processing), so that the plurality of gas flow passages can independently control gas flow rates and gas concentrations respectively; the gas flow passage forming member is connected to a top plate having the plurality of gas flow passages; the top plate has a plurality of gas blowing holes; the gas blowing holes are connected to the plurality of gas flow passages so as to correspond to each other; and a group of gas blowing holes corresponding to a certain one gas flow passage is disposed rotationally symmetric around the central axis of the substrate placement region of the sample electrode or the substrate. That is, gas is carried to a central part of the top plate from an upper part of the top plate through two or more gas flow passages, and further the gas is supplied to an inside of a vacuum vessel from the gas blowing hole disposed rotationally symmetric around the center of the top plate from the central part of the top plate through two or more gas flow passages. By carrying the gas to the central part of the top plate from the upper part of the top plate through the gas flow passage, the substrate main surface can be vertically irradiated with the gas from the gas blowing holes.

Thus, even in a case of the apparatus having two or more gas flow passages, the sheet resistance distribution is a simple distribution rotationally symmetric around the substrate center, thus making it easy to correct the distribution. By supplying the gas to the inside of the vacuum vessel from the gas blowing holes disposed rotationally symmetric around the center of the top plate from the central part of the top plate through two or more gas flow passages, the sheet resistance distribution can be corrected so that a high precision uniformity is realized by distributing the gas flow rates and gas concentrations of optimal ratios to two more gas flow passages for the concentrations of the sheet resistance that appears with a different ratio in the substrate central part and the substrate peripheral part according to a plurality of processing conditions. As described above, according to this structure, even in a case of the apparatus having two or more of the gas flow passages, the sheet resistance distribution is a simple distribution rotationally symmetric around the substrate center, and by distributing the gas flow rates or the gas concentrations of optimal ratio to two or more gas flow passages, for the concentrations of the sheet resistance that appears with a different ratio in the substrate central part and the substrate peripheral part according to a plurality of processing conditions, it is possible to obtain a tremendous advantage that the sheet resistance distribution can be corrected so that the high precision uniformity is realized.

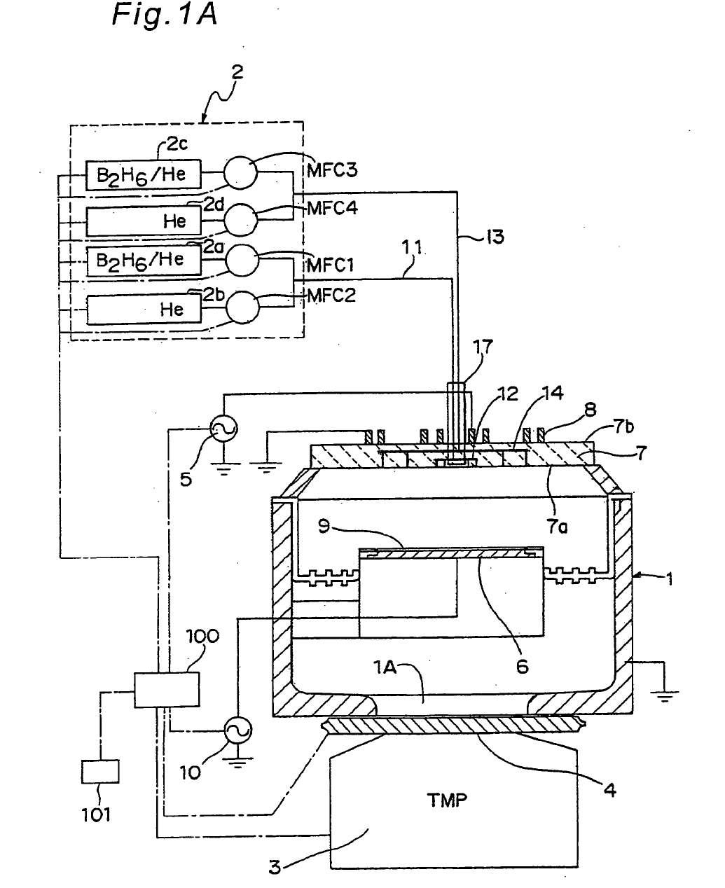

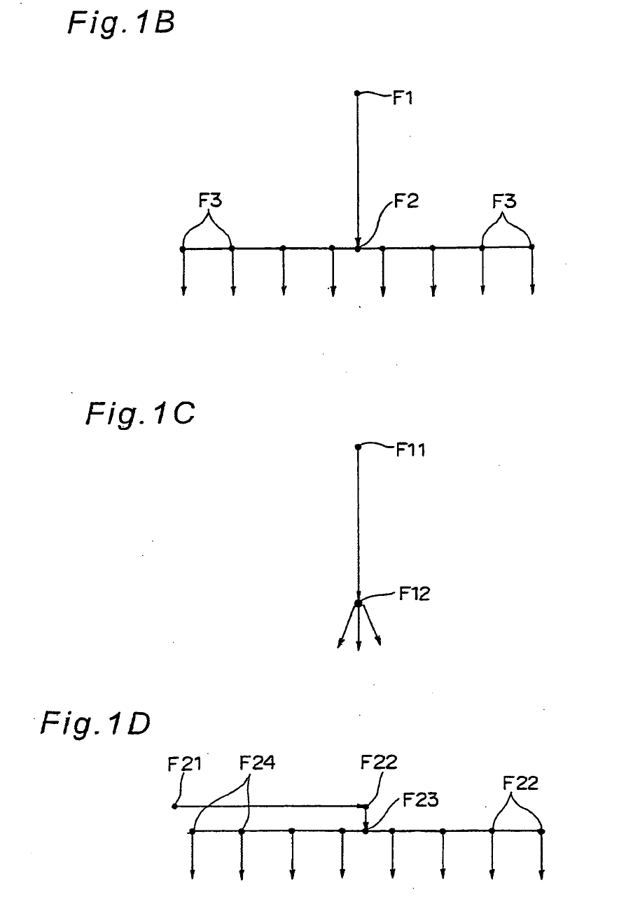

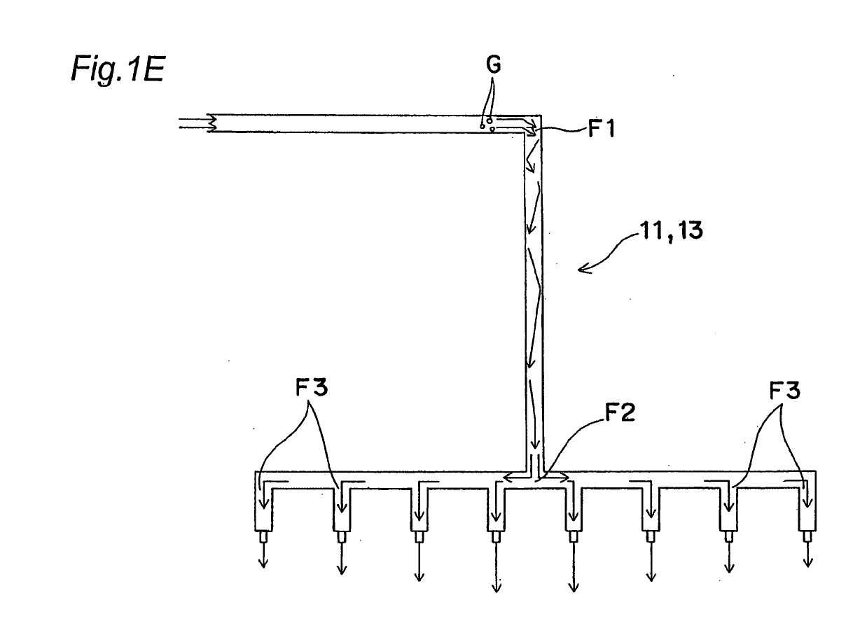

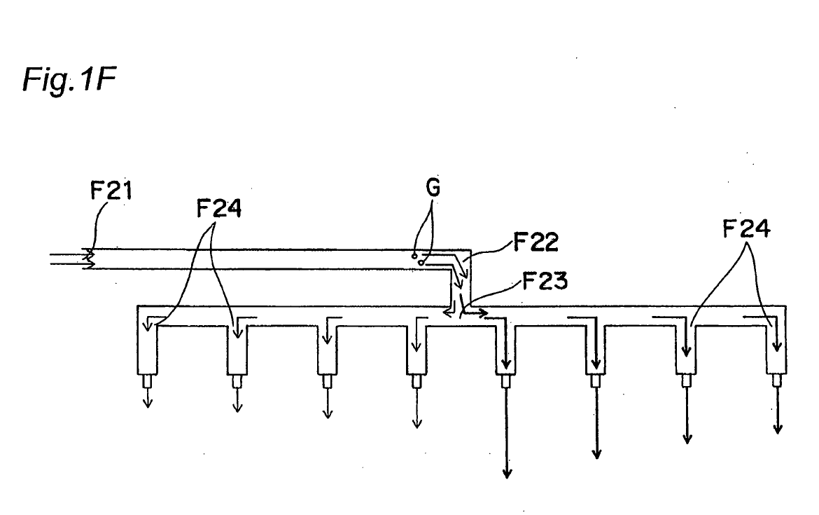

Note that in the plasma doping, when the process condition is different, there is a specific issue that a difference in dose amount between the central part and the peripheral part of the substrate may become extremely large. Meanwhile, in such a case, according to the present invention, arrangement of gas blowing holes 12 and 14 and a position of a wall of a vacuum vessel 1 are adjusted, and further a plasma parameter is adjusted, to thereby secure an in-surface uniformity of the dose amount. As one devised example of arrangement of the gas blowing holes 12, 14 in one working example, as shown in FIG. 1A, it is preferable to provide gas supply in two systems, arrangement of gas lines from upper to lower sides, evacuation through the exhaust port 1A at the bottom part of the vacuum vessel 1, gas supply control for each of the central part and the peripheral part of the top plate 7 independently, and a ratio of (radius of inner circle 31):(radius of outer circle 33) being set at a range of (radius of outer circle 33)/(radius of inner circle 31)=1.66 through 4.5. The reason is that dose amount distribution at the substrate central part and the substrate peripheral part can be formed ideally concentrically, and it is easy to independently control the dose amounts of the substrate central part and the substrate peripheral part, thus easily realizing extremely higher precision in-surface uniformity.

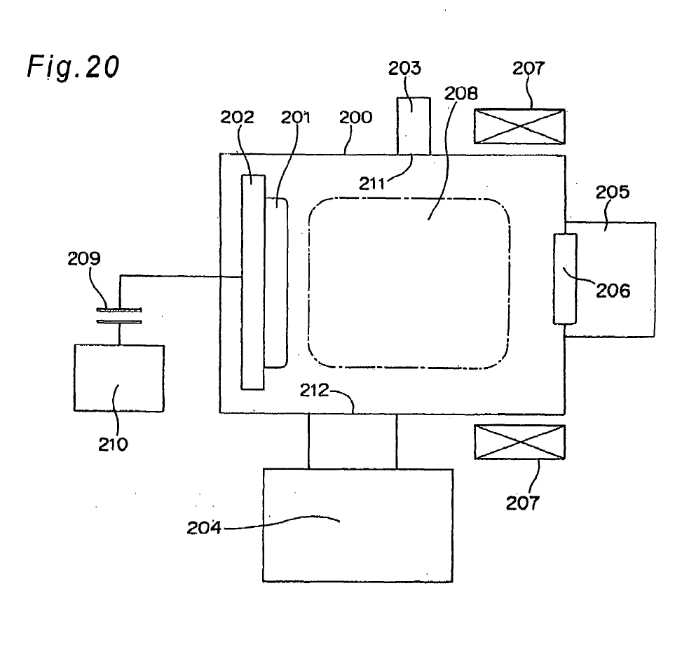

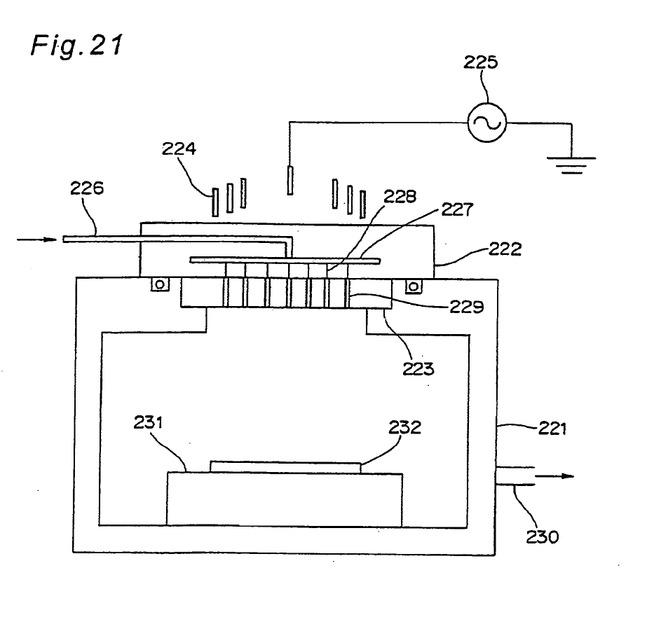

However, as is shown in FIG. 20 of U.S. Pat. No. 4,912,065 and FIG. 21 of Japanese Unexamined Patent Publication No. 2001-15493, with respect to a single vacuum vessel, in the apparatus having only one gas flow passage (in FIG. 21, although a plurality of through holes 229 for blowing gas are provided, there is only one gas flow passage itself capable of controlling the gas flow rate), even if the in-surface uniformity of the dose amount is secured by optimally adjusting an apparatus structure such as an arrangement of the gas blow openings and a position of a wall of the vacuum vessel and a process condition, in order to correspond to a change of the process condition based on a request for changing a device design, it is difficult to change the apparatus structure in accordance with the process condition, and in addition, it is difficult to secure the in-surface uniformity of the dose amount because limitation is imposed on the process condition from the device design. That is, there is an issue that it is difficult to obtain the high precision uniformity so as to correspond to a plurality of process conditions.

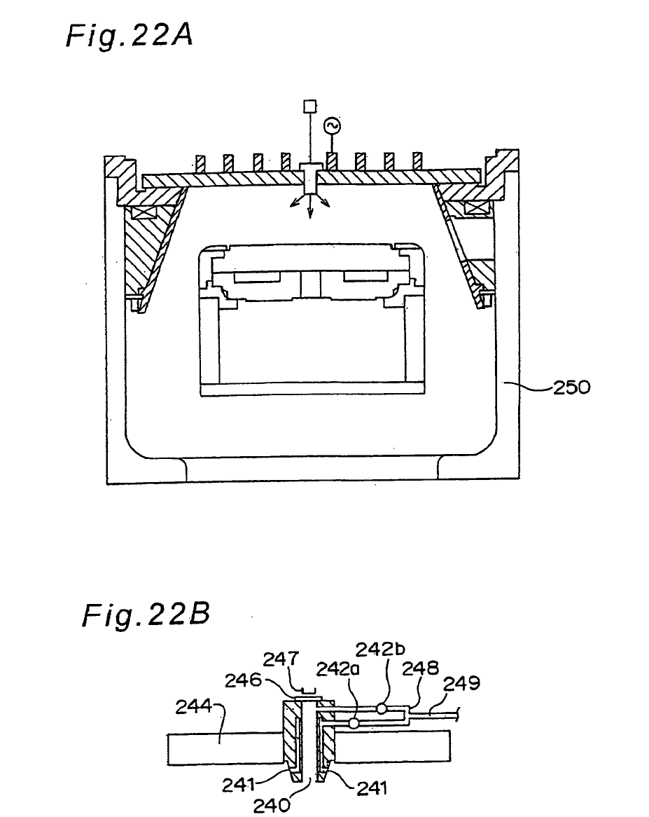

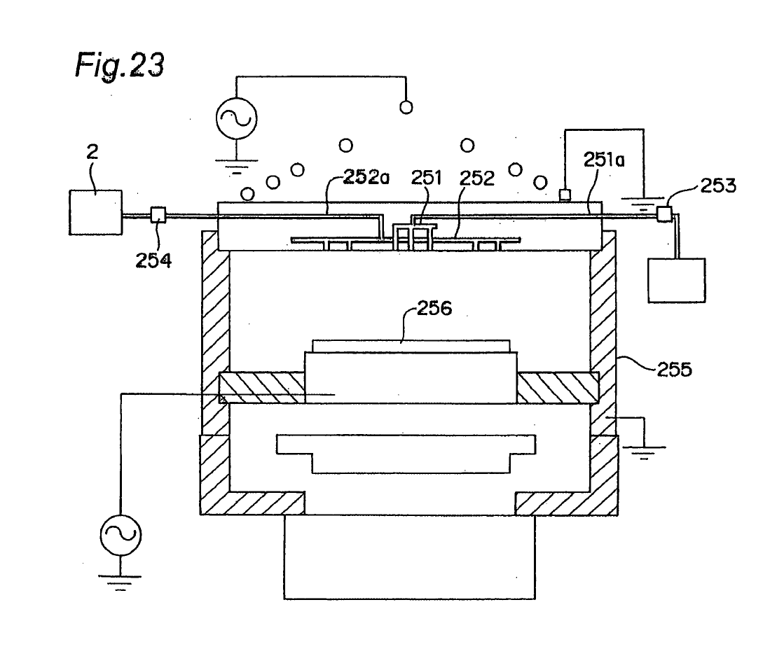

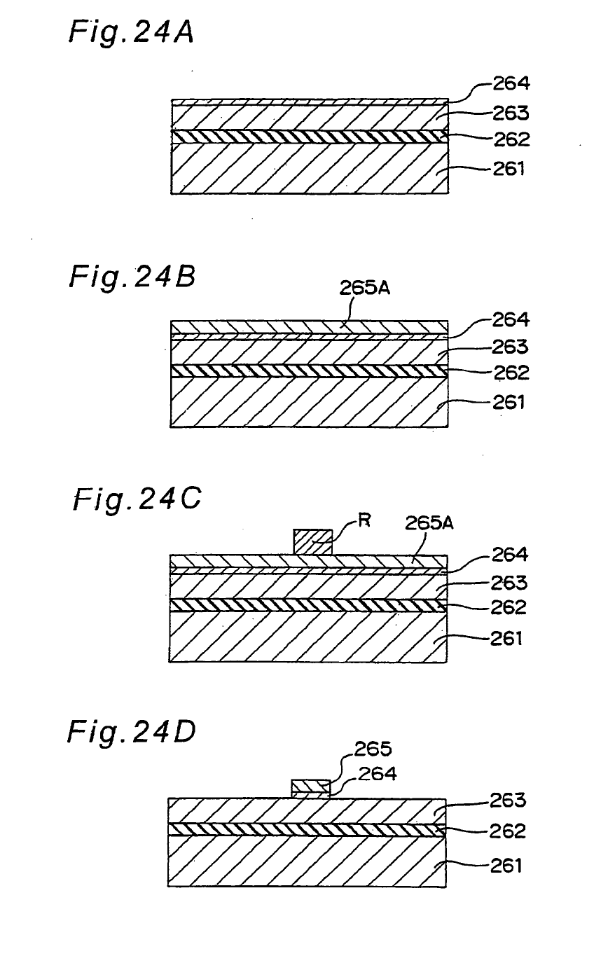

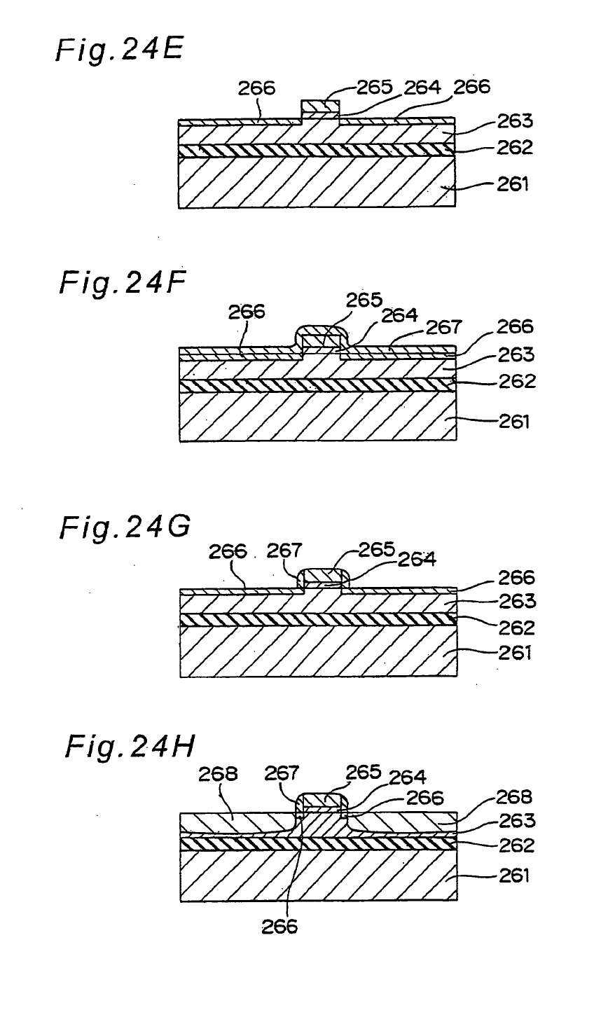

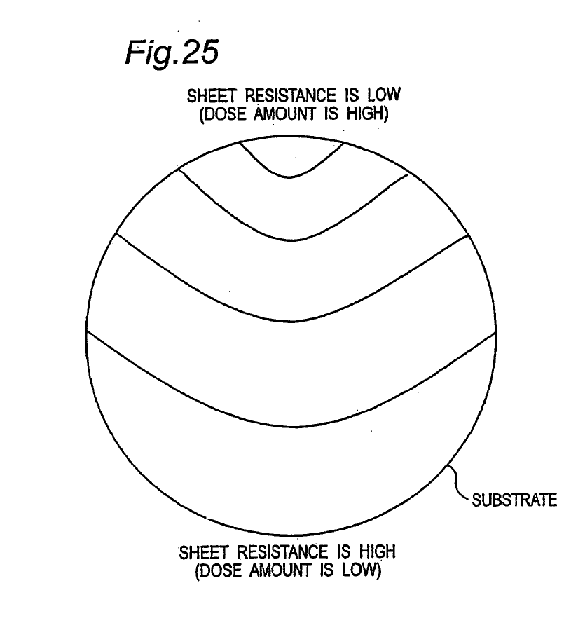

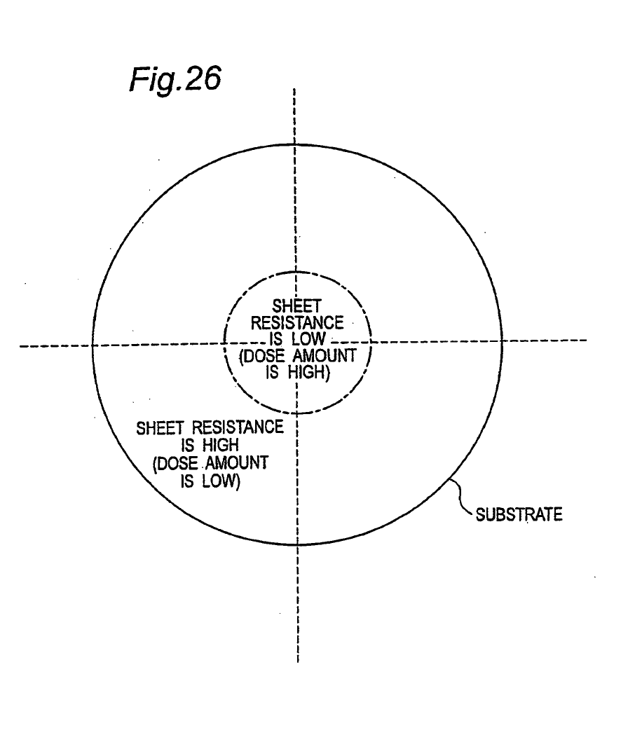

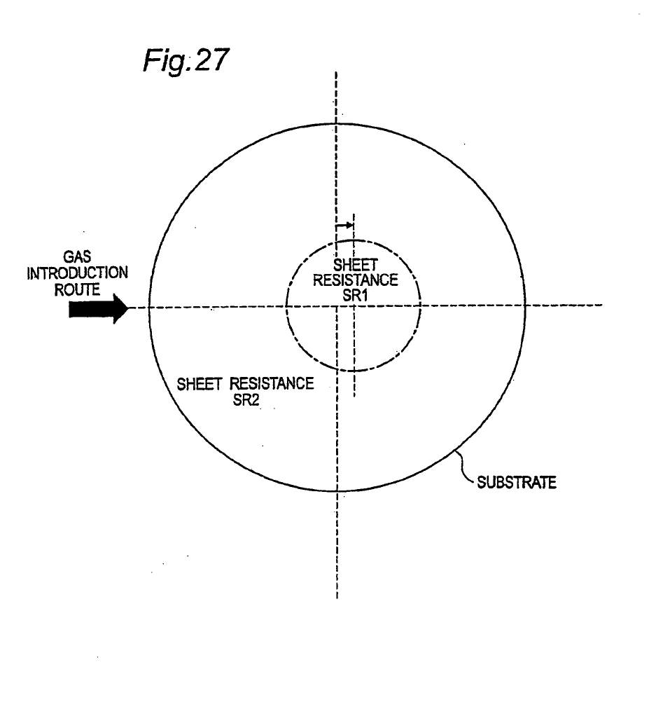

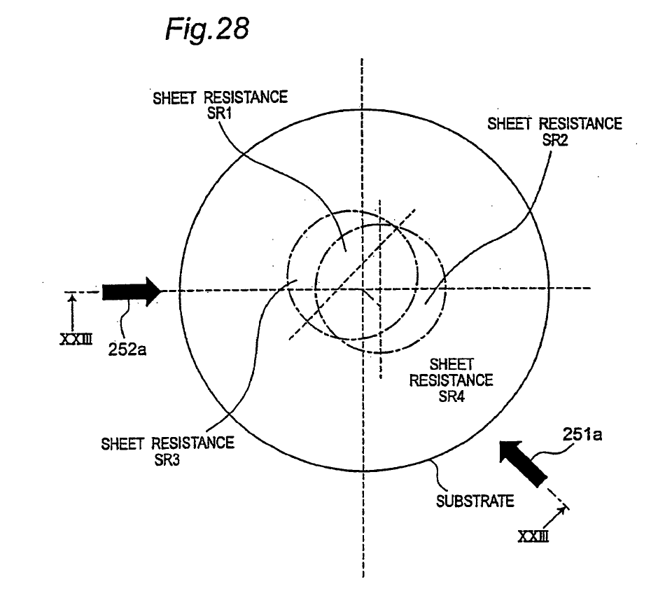

Meanwhile, as is shown in the apparatus of this embodiment, FIG. 22 of Japanese Unexamined Patent Publication No. 2005-507159 and FIG. 23 of International Publication WO 2006/106872A1, in the apparatus having two or more gas flow passages for one vacuum vessel, the ratio of the gas flow rate or gas concentration of the gas that flows through each gas flow passage can be made variable so as to be adjusted to the process condition demanded from the device design, which corresponds to pseudo changing the arrangement of the gas blowing holes, and there is an advantage that the in-surface uniformity of the dose amount can be easily secured so as to correspond to a plurality of process conditions. However, the apparatuses of FIG. 22 of Japanese Unexamined Patent Publication No. 2005-507159 and FIG. 23 of International Publication WO 2006/106872A1 have another issue (issue that a sheet resistance distribution rotationally symmetric around the center of the substrate can not be made uniform.) as already described above. The apparatus according to the present invention can be provided as the apparatus capable of solving such an issue entirely.

Next, the apparatus having further higher advantage will be explained.

A further preferable plasma doping apparatus has the top plate having a plurality of gas flow passages, and the gas flow passage forming member having a connection path corresponding to each gas flow passage. In this plasma doping apparatus, by changing the position of at least a part of the gas flow passage forming member, thereby changing the gas flow passage connected to the connection path, the gas is supplied into the vacuum vessel from the gas flow passage corresponding to the position of at least a part of the gas flow passage forming member. That is, this is the plasma doping apparatus having a mechanism of carrying the gas to the central part of the top plate from the upper part of the top plate through two or more gas flow passages, and the gas flow passage forming member having a connection hole corresponding to each gas flow passage, wherein by changing the position of the gas flow passage forming member to change the gas flow passage connected to the connection hole, the gas is supplied into the vacuum vessel from the gas flow passage corresponding to the position of the gas flow passage forming member.

More specifically, by providing a plurality of gas flow passages and the gas blowing holes on the top plate, disposing the gas flow passage forming member in the central part of the top plate, and the gas flow passage forming member is rotated and connected to corresponding different gas flow passage and gas blowing holes according to a rotational angle, an appropriate gas blowing hole can be corresponded in a state of maintaining a vacuum state according to a plurality of process conditions. With this structure, the gas blowing holes are uniformly arranged over an entire body of the substrate main surface, and the arrangement of the gas blowing holes can be made variable corresponding to the process condition, with the vacuum vessel maintained in a vacuum state without being opened. Thus, it is possible to provide the plasma doping apparatus capable of realizing a move excellent uniformity of the dose amount, so as to correspond to a plurality of process conditions, without opening the vacuum vessel.

Each embodiment of the present invention will be explained hereunder, with reference to the drawings.

### FIRST EMBODIMENT

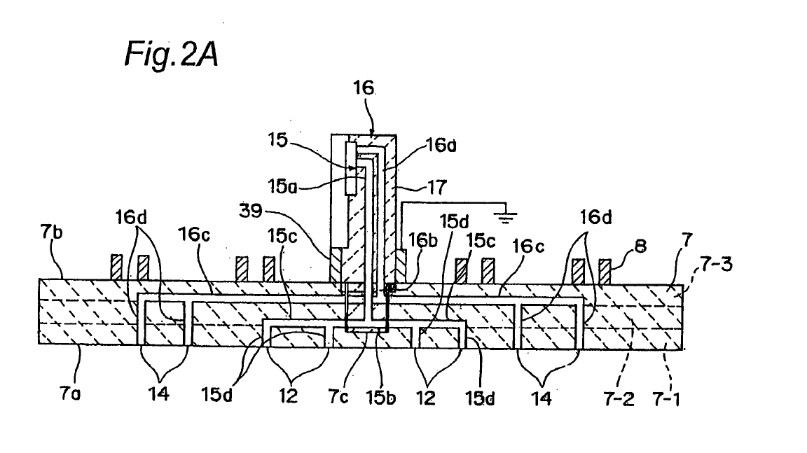

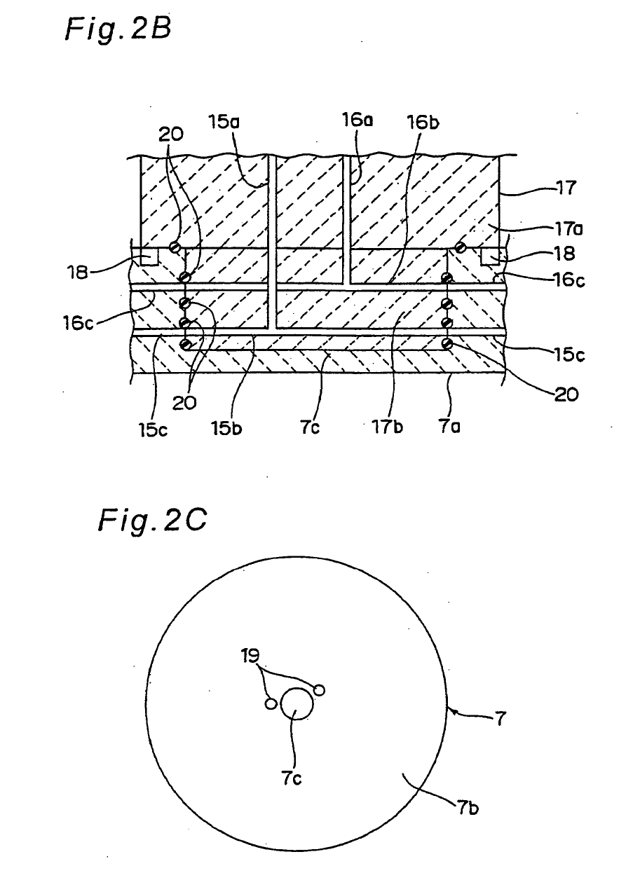

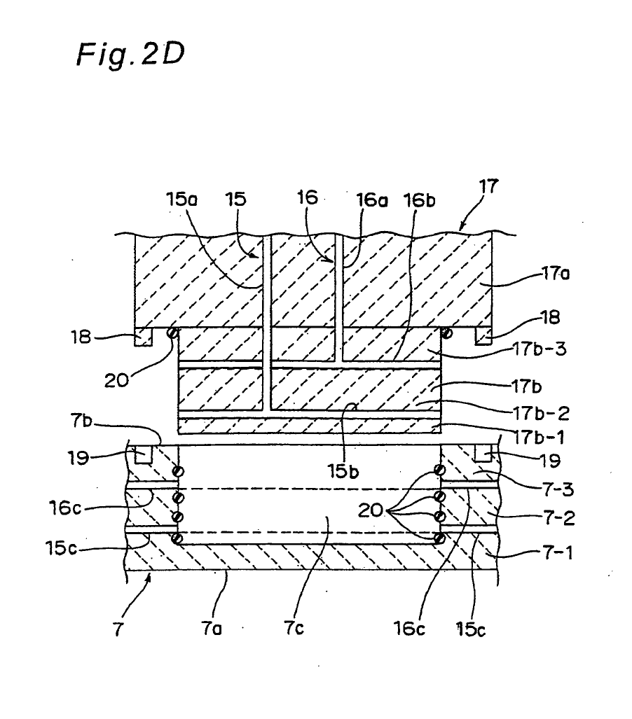

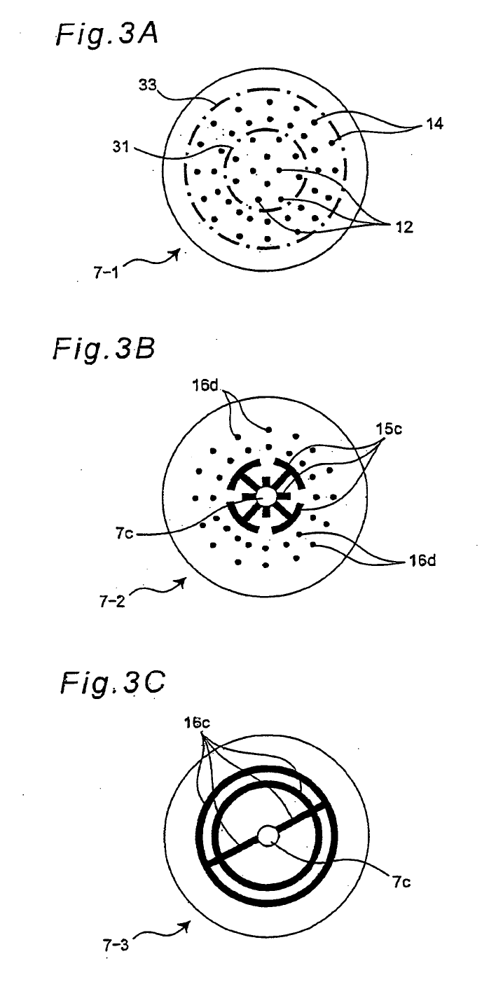

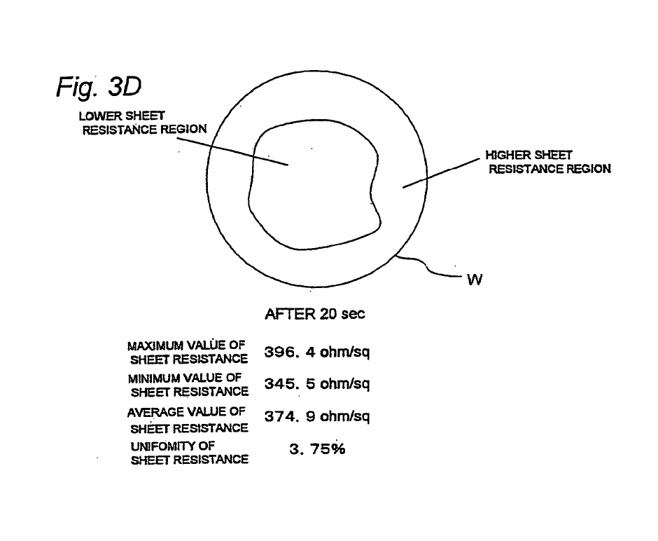

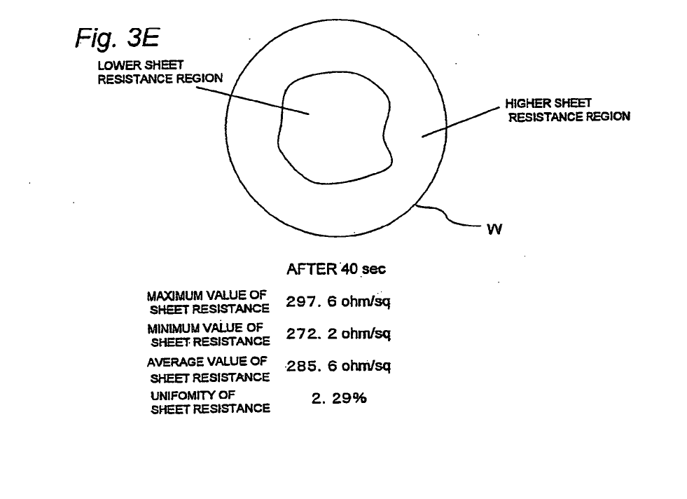

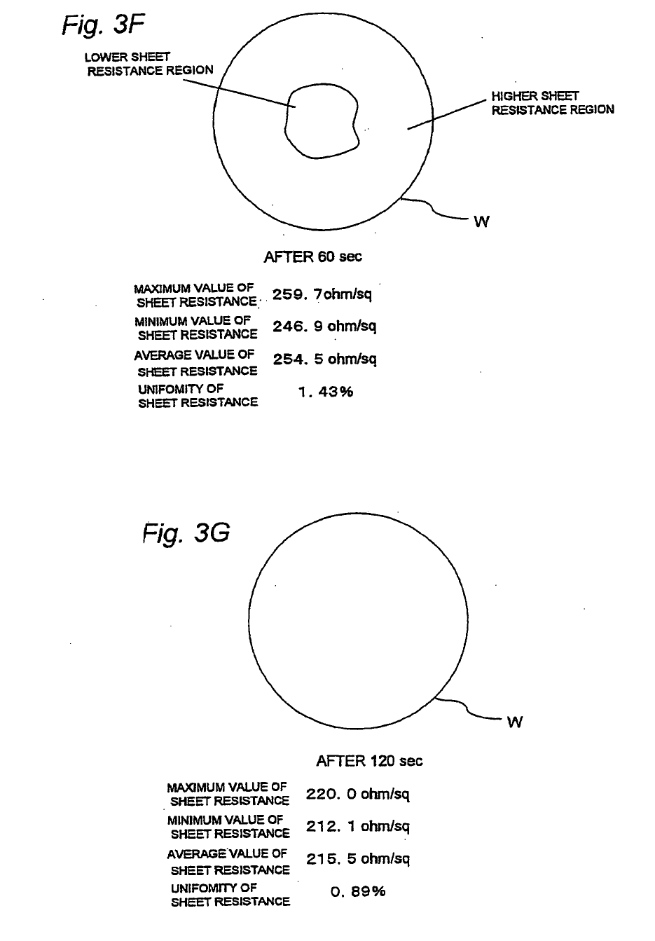

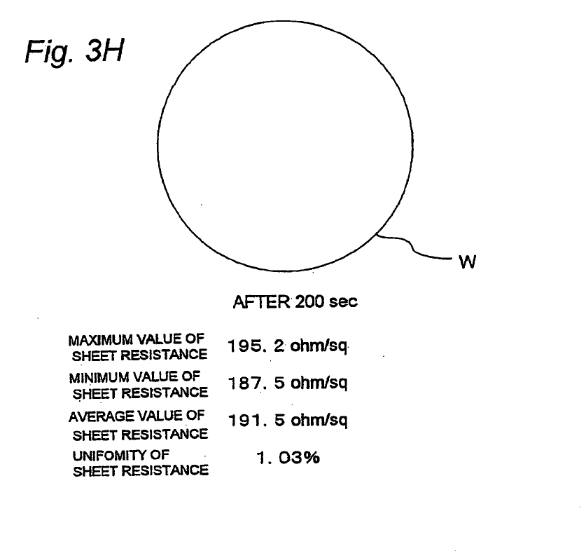

The apparatus and the method for plasma doping according to a first embodiment of the present invention will be explained hereunder, with reference to FIG. 1A, FIG. 2A, and FIG. 3C.

FIG. 1A shows a partially sectional view of the plasma doping apparatus used in the first embodiment of the present invention. In FIG. 1A, the vacuum vessel 1 is exhausted by a turbo molecular pump 3 as an example of an exhaust device, while introducing a prescribed gas into the vacuum vessel 1 constituting a vacuum chamber from a gas supply device 2, and the inside of the vacuum vessel 1 can be set in a prescribed pressure by a pressure control valve 4. By supplying a high-frequency power of 13.56 MHz to a coil 8 provided in the vicinity of a top plate 7 opposite to a sample electrode 6 from a high-frequency power supply 5, plasma can be generated in the vacuum vessel 1. A silicon substrate 9 is placed on the sample electrode 6, as an example of a sample. In addition, a high-frequency power supply 10 is provided in the sample electrode 6, for supplying high-frequency power, and this high-frequency power supply 10 functions as a voltage supply for controlling a potential of the sample electrode 6, so that the substrate 9 as an example of the sample has a negative potential against the plasma. A control device 100 is connected to the gas supply device 2 (an impurity source gas supply device 2a, a helium supply device 2b, an impurity source gas supply device 2c, a helium supply device 2d, first to fourth mass flow controllers MFC1 to MFC4), the turbo molecular pump 3, the pressure control valve 4, the high-frequency power supply 5, and the high-frequency power supply 10, so that each operation is controlled. With this structure, ion in the plasma is accelerated toward the surface of the substrate 9 as an example of the sample and is made to collide with the surface, to thereby introduce the impurities to the surface of the substrate 9. Note that the gas supplied from the gas supply device 2 is exhausted to the pump 3 from an exhaust port 1A. The turbo molecular pump 3 and the exhaust port 1A are disposed just under the sample electrode 6. The sample electrode 6 is an approximately round pedestal for placing the substrate 9 thereon.

In this way, the vacuum vessel 1 has the exhaust port 1A just under the sample electrode 6, namely, the electrode 6 for placing the substrate 9 thereon, the top plate 7, wherein the top plate 7 is positioned so as to be opposite to the electrode 6, and the exhaust port 1A is provided on a bottom surface of the vacuum vessel 1 opposite to the top plate 7, thereby realizing isotropic exhaust. That is, by providing the exhaust port 1A on the electrode side (actually on the bottom surface of the vacuum vessel 1 positioned below the electrode 6), not on the side wall of the vacuum vessel 1 viewed from the top plate 7, the isotropic exhaust viewed from the substrate 9 is realized. Thus as a result of the isotropic exhaust, the gas flow supplied from the gas blowing holes 12 and 14 of the top plate 7 as will be describe later toward the exhaust port 1A of the vacuum vessel 1 via the substrate 9 can be made uniform.

Note that from the viewpoint of further uniformizing supplied gas flow, it is preferable to dispose the top plate 7, the substrate 9, the electrode 6, and the exhaust port 1A, with each central axis approximately arranged on one straight line.

The structure of supplying gas into the vacuum 1 from the gas supply device 2 can be given as one characteristic of the present invention.

The gas is supplied from the gas supply device 2 to a gas flow passage forming member 17, being an example of the gas flow passage forming member (gas-nozzle member) (which may be constructed as a part of the top plate 7) erected approximately in the central part of the surface (outer surface) 7b of the opposite side to the vacuum vessel inner surface 7a which is opposite to the sample electrode 6 of the top plate 7, through at least two lines such as a first gas supply line 11 and a second gas supply line 13. Further, the gas is respectively supplied from the gas flow passage forming member 17 and then the top plate 7 to the inside of the vacuum vessel 1 from the gas blowing holes 12 for the substrate central part and the gas blowing holes 14 for the substrate peripheral part disposed rotationally symmetric around the center of the top plate 7 (in other words, the central axis of the substrate 9 (the substrate placement region of the sample electrode 6)) respectively, via at least two gas flow passages, a first gas flow passage 15 and a second gas flow passage 16. This structure will be specifically explained hereunder. Note that reference numeral 20 indicates an O-ring.

The gas is supplied, as described below, to the upper end part of the gas flow passage forming member 17 erected in the central part of the outer surface 7b of the top plate 7, by using from the gas supply device 2 to the first gas supply line 11. At this time, the flow rate and the concentration of plasma doping processing gas containing impurity source gas are controlled to prescribed values by the mass flow controllers MFC1 and MFC2 provided in the gas supply device 2. Generally, the gas obtained by diluting the impurity source gas with helium, such as the gas obtained by diluting diborane (B₂H₆), being an example of the impurity source gas, with helium (He) to 5 wet %, is used as the plasma doping processing gas. Therefore, the flow rate control of the impurity source gas supplied from the impurity source gas supply device 2a is performed by the first mass flow controller MFC1, and the flow rate control of helium (He) supplied from the helium supply device 2b is performed by the second mass flow controller MFC2, and the plasma doping processing gas, with the flow rates controlled by the first and second mass flow controllers MFC1 and MFC2, is mixed in the gas supply device 2. Thereafter, the mixed gas thus obtained is supplied to the upper end of the first gas flow passage 15 of the upper end part of the gas flow passage forming member 17, via the first gas supply line 11. The mixed gas supplied to the upper end of the first gas flow passage 15 is blown into the vacuum vessel 1 by a plurality of substrate central part gas blowing holes 12 formed in a region opposite to the substrate central part of the vacuum vessel inner surface 7a which is opposite to the substrate 9 of the top plate 7, through the first gas flow passage 15 connected to the first gas supply line 11 and formed in the gas flow passage forming member 17 and the top plate 7. The mixed gas blown from the plurality of substrate central part gas blowing holes 12 is blown toward the central part of the substrate 9.

Similarly, by using the second gas supply line 13, the gas is supplied from the gas supply device 2, as described below, to the upper end part of the gas flow passage forming member 17 erected in the central part of the outer surface 7b of the top plate 7. At this time, the flow rates and concentrations of the plasma doping processing gas containing the impurity source gas are controlled to prescribed values, by the mass flow controllers MFC3 and MFC4 provided in the gas supply device 2. Generally, the gas obtained by diluting the impurity source gas with helium, such as the gas obtained by diluting diborane (B₂H₆), being an example of the impurity source gas, with helium (He) to 5 wet %, is used as the plasma doping processing gas. Therefore, the flow rate control of the impurity source gas supplied from the impurity source gas supply device 2c is performed by the third mass flow controller MFC3 and the flow rate control of helium supplied from the helium supply device 2d is performed by the fourth mass flow controller MFC4, and the plasma doping processing gas, with the flow rates controlled by the third and fourth mass flow controllers MFC3 and MFC4 is mixed in the gas supply device 2. Thereafter, the mixed gas thus obtained is supplied to the upper end of the second gas flow passage 16 of the upper end part of the gas flow passage forming member 17, via the second gas introduction passage 13. The mixed gas supplied to the upper end of the second gas flow passage 16 is blown into the vacuum vessel 1 from a plurality of substrate peripheral part gas blowing holes 14 formed in a region opposite to the substrate peripheral part of the vacuum vessel inner surface 7a of the top plate 7 which is opposite to the substrate 9, through the second gas flow passage 16 connected to the second gas introduction passage 13 and formed in the gas flow passage forming member 17 and the top plate 7. The mixed gas blown from the plurality of substrate peripheral part gas blowing holes 14 is blown toward the peripheral part of the substrate 9.

FIG. 2A to FIG. 2D are a partially sectional view and an enlarged partially sectional view of the gas flow passage forming member 17 and the central part of the top plate 7 in a state that the gas flow passage forming member 17 for connecting the first gas supply line 11, the second gas supply line 13, and the first gas flow passage 15 and the second gas flow passage 16 of the top plate 7 is attached to the central part of the top plate 7, a plan view of the top plate 7 before the gas flow passage forming member 17 is attached to the central part of the top plate 7, and a partially sectional view of the gas flow passage forming member 17 and the central part of the top plate 7 in a state that the gas flow passage forming member 17 is detached from the central part of the top plate 7.

The gas flow passage forming member 17 is a columnar member such as quartz forming each part of two gas flow passages, namely, the first gas flow passage 15 and the second gas flow passage 16 in a longitudinal direction (vertical direction in FIG. 2A and FIG. 2B and FIG. 2D etc.). The gas flow passage forming member 17 includes integrally therewith a columnar main body part 17a and a columnar engagement part 17b disposed in a lower end of the columnar main body part 17a, with a smaller diameter than the diameter of the columnar main body part 17a. In a range from the main body part 17a to a part of the engagement part 17b, an upper-side vertical gas flow passage 15a and an upper-side vertical gas flow passage 16a constituting a part of the first gas flow passage 15 and a part of the second gas flow passage 16 respectively are formed in its inside along the longitudinal direction of the gas flow passage forming member 17. An inside lateral gas flow passage 15b, with the lower end of the upper-side vertical gas flow passage 15a communicated therewith and laterally penetrated therethrough, is formed on the substrate side (lower end side in FIG. 2A, FIG. 2B, and FIG. 2D) of the inside of the engagement part 17b. An inside lateral gas flow passage 16b, with the lower end of the upper-side vertical gas flow passage 16a communicated therewith and laterally penetrated therethrough, is formed on the opposite side (upper end side in FIG. 2A, FIG. 2B, and FIG. 2D) to the substrate 9 of the inside of the engagement part 17b. Note that in FIG. 2A, FIG. 2B, and FIG. 2D, the upper-side vertical gas flow passage 15a intersects with the inside lateral gas flow passage 16b. However, they are simplified and shown in these figures, and therefore they are shown as if intersecting with each other, and in an actual apparatus, the upper-side vertical gas flow passage 15a and the inside lateral gas flow passage 16b are not communicated with each other. That is, the first gas flow passage 15 and the second gas flow passage 16 form flow passages mutually independently, and there is not part where both of them communicate with each other.

It is desirable to set the radii R of two gas flow passages provided in the top plate 7 and the gas flow passage forming member 17 (one of them is the first gas flow passage 15 through which the gas is supplied from the upper-side vertical gas flow passage 15a to the substrate central part gas blowing holes, and the other of them is the second gas flow passage 16 through which the gas is supplied from the upper-side vertical gas flow passage 16a to the substrate peripheral part gas blowing holes 14), to the same radius in the inside of the top plate 7 and the gas flow passage forming member 17. The reason is that since passage resistances of the first gas passage 15 and the second gas passage 16 become the same, by using the mass flow controllers MFC1-MFC4 disposed before the first gas passage 15 and the second gas passage 16, it is easy to control the gas flow rates of the gas blown through the substrate central part gas blowing holes 12. The reason is that since passage resistances of the first gas flow passage 15 and the second gas flow passage 16 become the same, by using the mass flow controllers MFC1 to MFC4 disposed on the upstream sides of the first gas flow passage 15 and the second gas flow passage 16, it is easy to control the gas flow rates of the gas blown through the substrate central part gas blowing holes 12 and the substrate peripheral part gas blowing holes 14, and thus it is possible to obtain the high precision uniformity of the gas flow rates. However, this is not only the case, and as an allowable range of the radius R, it is desirable to set the radius at (⅕) Rₒ<R<5Rₒ, with the radius Rₒ of the substrate central part gas blowing holes 12 set as a reference. When the radius R is set within this range, it is presumed that the flow rate of the gas blown to the inside of the vacuum vessel 1 from the substrate central part gas blowing holes 12 and the flow rate of the gas blown to the inside of the vacuum vessel 1 from the substrate peripheral part gas blowing holes 14 are easily controlled by the mass flow controllers MFC1 and MFC2 in the former gas flow rate, and by the mass flow controllers MFC3 and MFC4 in the latter gas flow rate. Therefore, it is possible to obtain an advantage that in-surface uniformity with an excellent dosing amount in the plasma doping can be realized. Meanwhile, when each radius R of the two gas flow passages 15 and 16 provided in the top plate 7 and the gas flow passage forming member 17 is outside of the aforementioned range, gas reservoir is easily formed, for example, in a spiral shape in the inside of the top plate 7 and the gas flow passage forming member 17, thus making it difficult to control a gas supply direction for blowing the gas toward the inside of the vacuum vessel. Here, “gas reservoir is easily formed” means that when the gas flows through the smaller passage, the larger passage, the smaller passage in order, it is easy to form gas reservoir at the larger passage. When the gas reservoir is formed, the gas supply direction for blowing the gas toward the inside of the vacuum vessel is different depending on large/small of the gas flow rates designated by the mass flow controllers MFC1 and MFC2, and the mass flow controllers MFC3 and MFC4, and thus the sizes of the gas flow rates affect on the structure of the gas flow designed by an arrangement of the two gas flow passages 15 and 16 provided in the top plate 7 and the gas flow passage forming member 17. Accordingly, there is a possibility of making it difficult to obtain the in-surface uniformity with excellent dosing amount based on a plurality of plasma doping conditions. Therefore, there is a possibility that the advantage of the apparatus of this embodiment having the gas flow passages 15 and 16 which are formed into two systems, namely, the advantage that the sheet resistance distribution can be made uniform with high precision, can not be surely obtained. Accordingly, as described above, it is preferable to set the radius R within the aforementioned range.

In addition, two positioning projections 18, 18 are disposed on the lower end surface of the main body part 17a and in the circumference of the engagement part 17b, so as to be engaged with two positioning holes 19 and 19 formed in the circumference of a recess portion 7c as will be described later, thereby making it possible to position the engagement part 17b, namely, the gas flow passage forming member 17 and the top plate 7, and dispose an O-ring 20 at a corner section between the outer surface 7b of the top plate 7 and the lower end surface of the main body part 17a of the engagement part 17b, and thus, sealing is achieved between the engagement part 17b and the outer surface 7b of the top plate 7.

In addition, although the engagement part 17b may be integrally formed, it may be formed of a plurality of layers (plate-like members). For example, three-layer lamination structure may be formed, such as a first layer 17b-1, a second layer 17b-2, and a third layer 17b-3 sequentially from the substrate side toward the opposite side to the substrate 9. In this case, the upper-side vertical gas flow passages 15a and 16a that respectively communicate with the upper-side vertical gas flow passages 15a and 16a of the main body part 17a of the gas flow passage forming member 17 are formed on the third layer 17b-3 of the engagement part 17b so as to penetrate therethrough, and the inside lateral gas flow passage 16b that communicates with the upper-side vertical gas flow passage 16a is formed on a joint surface between the third layer 17b-3 and the second layer 17b-2. The upper-side vertical gas flow passage 15a that communicates with the upper-side vertical gas flow passage 15a of the third layer 17b-3 is formed on the second layer 17b-2 of the engagement part 17b so as to penetrate therethrough, and the inside lateral gas flow passage 15b that communicates with the upper-side vertical gas flow passage 15a is formed on the joint surface between the second layer 17b-2 and the first layer 17b-1. Nothing in particular may be formed on the first layer 17b-1.

Meanwhile, the top plate 7 formed of quartz, for example, may be integrally formed. As an example, three-layer lamination structure is formed and each remaining part of the first gas flow passage 15 and the second gas flow passage 16 is independently formed inside. The recess portion 7c is formed in the central part of the surface 7b of the opposite side to the substrate 9 in the top plate 7 without penetrating therethrough in a thickness direction, so that the engagement part 17b of the gas flow passage forming member 17 can be engaged with the recess portion 7c for connection.

Here, if a gas supplying nozzle is disposed so as to penetrate the dielectric top plate 7 as shown in FIG. 22A, instead of the gas flow passage forming member 17, the gas is easily supplied from the gas supplying nozzle to the central part of the substrate 6. However, the gas is hardly supplied from the gas supplying nozzle to the peripheral part of the substrate 6. In order to supply the gas to the peripheral part of the substrate 6 from the gas supplying nozzle, the gas is required to be supplied from the gas supplying nozzle disposed above the central part of the substrate 6, obliquely downward toward the peripheral part of the substrate 6, or the diameter of the gas supplying nozzle is required to be made larger up to about the diameter of the substrate 6.

A result of the former case is shown as the apparatus of FIG. 22A. Although this is an excellent result, there is an issue that plasma doping time of 60 seconds or more is required for achieving 1.5% or less. The result of the plasma doping time of 20 seconds or 40 seconds reveals that there is such an issue that in a method of the former case, the gas is insufficiently supplied to the peripheral part of the substrate 6, because the sheet resistance is high (dose amount is low) in the peripheral part of the substrate 6 in this case.

Meanwhile, in the latter case, the gas can be sufficiently supplied to the peripheral part of the substrate 6, but in order to turn the gas in the vacuum vessel 1 into plasma, an antenna for charging energy must be disposed in an upper part of the gas supplying nozzle. In this case, the energy from the antenna is absorbed into the gas supplying nozzle, thus making it difficult to excite plasma.

Meanwhile, in the structure of this embodiment wherein the gas supplying nozzle is not disposed on the dielectric top plate 7 so as to penetrate therethrough, and as described above in this embodiment, the recess portion 7c is formed on the outer surface 7b of the dielectric top plate 7, with the vacuum vessel inner surface 7a of the dielectric top plate 7 formed in a flat surface as it is, and the gas flow passage forming member 17 is inserted into the recess portion 7c, the advantage can be exhibited, such as sufficiently supplying the gas to the peripheral part of the substrate 6 and simultaneously transferring the energy from the antenna (coil 8) to the gas in the vacuum vessel 1 efficiently with almost no deterioration allowed to occur.

Furthermore, if, in FIG. 23, the gas flow passage forming member 17 is disposed at the central part of the coil of the apparatus in International publication WO 2006/106872A1 so as to flow gas in the apparatus in International publication WO 2006/106872A1 like the embodiment of the present invention, that is, so as to start flowing the gas downward from the upper end position along the central axis of the sample electrode or the substrate, and flow laterally and thereafter downward, resulting in occurrence of the following defects. In the apparatus of the International publication WO 2006/106872A1, a three-dimensional coil 259 is disposed above the top plate. When the gas flow passage forming member 17 is disposed at the center of such a three-dimensional coil 259, it is very easy to make the gas supplied into the gas flow passage forming member 17 in plasma in the inside of the gas flow passage forming member 17 by magnetic fields formed by the coil 259, which is one issue. It is unintended that plasma is generated in the inside of the gas flow passage forming member 17, and thus it is very undesirable to have bad influences on plasma doping processing. Contrarily, in the embodiment of the present invention, as compared with the three-dimensional coil 259 of the International publication WO 2006/106872A1, the height of the coil 8 can be extremely reduced, and thus, it is hard to generate plasma in the inside of the gas flow passage forming member 17 than the coil 259 of the International publication WO 2006/106872A1. In addition, a metal shield 39 having the height higher than the height of the coil 8 from the upper surface of the top plate 7 and earthed may be disposed on the upper surface of the top plate 7 so as to surround the periphery of the gas flow passage forming member 17. The shield 39 can prevent the gas in the inside of the gas flow passage forming member 17 from being made in plasma.

The three-layer lamination structure of the top plate 7 is formed by a first layer 7-1, a second layer 7-2, and a third layer 7-3 sequentially from the substrate side toward the opposite side to the substrate 9.

A part of the recess portion 7c is formed on the third layer 7-3 of the top plate 7 so as to penetrate therethrough, and the outside lateral gas flow passage 16c that laterally extends and communicates with the inside lateral gas flow passage 16b of the engagement part 17b of the gas flow passage forming member 17 is formed on the joint surface between the third layer 7-3 and the second layer 7-2.

A part of the recess portion 7c is formed on the second layer 7-2 of the top plate 7 so as to penetrate therethrough, and a plurality of lower-side vertical gas flow passages 16d are also formed thereon, with each upper end thereof communicated with the outside lateral gas flow passage 16c of the third layer 7-3, so as to penetrate the second layer 7-2 in the thickness direction as shown in FIG. 2A, FIG. 2B, and FIG. 2D. Further, on the second layer 7-2 of the top plate 7, an outside lateral gas flow passage 15c is formed on the joint surface between the second layer 7-2 and the first layer 7-1, so as to be laterally extended and respectively connected to the inside lateral gas flow passage 15b of the engagement part 17b of the gas flow passage forming member 17.

A plurality of low side vertical gas flow passage 15d, with each upper end thereof communicated with the outside lateral gas flow passage 15c, is formed on the first layer 7-1 of the top plate 7 so as to penetrate through the first layer 7-1 in the thickness direction as shown in FIG. 2A, FIG. 2B, and FIG. 2D. Further, a plurality of lower-side vertical gas flow passages 16d that respectively communicate with the plurality of lower-side vertical gas flow passages 16d of the second layer 7-2 are formed on the first layer 7-1 of the top plate 7 so as to penetrate therethrough. The lower end opening of each lower-side vertical gas flow passage 15d of the first layer 7-1 is the gas blowing hole 12 for the substrate central part, and the lower end opening of each lower-side vertical gas flow passage 16d is the gas blowing hole 14 for the substrate peripheral part.

Note that it is preferable to form the gas flow passage forming member 17 integrally with a top plate 7. When the gas flow passage forming member 17 and the top plate 7 are separate components, there is a possibility that a vacuum leaks at a connection part between the gas flow passage forming member 17 and the top plate 7. In order to prevent such a leak as much as possible, the O-rings 20 are disposed between both members to seal this connection part. Meanwhile, when the both members are integrally formed, there is no connection part between the gas flow passage forming member 17 and the top plate 7, the vacuum does not leak from this part.

Note that when only the upper-side vertical gas flow passages 15a and 16a are provided on the gas flow passage forming member 17, there is an issue that the apparatus results in having extremely low reliability in maintaining the vacuum, because while the top plate 7 and the gas flow passage forming member 17 are connected to each other in the vertical direction, the vacuum also must be maintained in the vertical direction.

Meanwhile, according to this embodiment, not only the upper-side vertical gas flow passages 15a and 16a, but also the inside lateral gas flow passages 15b and 16b are provided in the gas flow passage forming member 17. Therefore, while the top plate 7 and the gas flow passage forming member 17 are connected to each other in the vertical direction, the vacuum can be maintained in a lateral direction (in other words, the O-rings 20 are disposed on a side surface of the engagement part 17b). Accordingly, there is an advantage of high reliability in maintaining vacuum between the top plate 7 and the gas flow passage forming member 17.

FIG. 3A to FIG. 3C are plan views of the first layer 7-1, the second layer 7-2, and the third layer 7-3 of the top plate 7 in FIG. 1A viewed from the lower side (substrate side). As is known from these figures, the gas blowing holes 12 and 14 are provided almost symmetric to the central axis (in other words, the central axis of the substrate 9) of the top plate 7, so that it is so constructed that the gas is almost isotropically blown toward the substrate 9. That is, a plurality of gas blowing holes 12 and 14 are almost isotropically disposed. In addition, as one example, “the central part of the substrate 9 (sample electrode 6)” is defined as “a part including the center of the substrate 9 (sample electrode 6) and having an area of ½ of the area of the substrate 9 (sample electrode 6)”, and “the peripheral part of the substrate 9 (sample electrode 6)” is defined as “a remaining part not including the center of the substrate 9 (sample electrode 6)”. Then, the substrate central part gas blowing holes 12 provided opposite to the central part of the substrate 9 (sample electrode 6) can be considered to be the substrate central part gas blowing holes 12 (12 pieces) disposed inside of an inner circle 31 (circle having the diameter of ½ of the diameter of the substrate 9). In addition, the substrate peripheral part gas blowing holes 14 provided opposite to the peripheral part of the substrate 9 (sample electrode 6) can be considered to be the substrate peripheral part gas blowing holes 14 (32 pieces) disposed inside of an outer circle 33 (circle having the same diameter with the diameter of the substrate 9) and outside of the inner circle 31. The gas is supplied to the first gas blowing holes (for substrate central part) 12 and the second gas blowing holes (for substrate peripheral part) 14, respectively through two gas flow passages such as the first gas flow passage 15 and the second gas flow passage 16 provided in the gas flow passage forming member 17 and the top plate 7 respectively. At this time, the first gas flow passage 15 supplies the gas to the substrate central part gas blowing holes 12 (12 pieces) disposed inside of the inner circle 31. The second gas flow passage 16 supplies the gas to the substrate peripheral part gas blowing holes 14 (32 pieces) disposed outside of the inner circle 31.

Note that the outside lateral gas flow passage 15c is disposed on the second layer 7-2 of the top plate 7 in FIG. 3B radially rotationally symmetric around the center of the substrate 9, so as to communicate with all substrate central part gas blowing holes 12 of the first layer 7-1 of the top plate 7. Similarly, the outside lateral gas flow passage 16c is disposed on the third layer 7-3 of the top plate 7 of FIG. 3C rotationally symmetric around the center of the substrate 9, so as to communicate with all substrate peripheral part gas blowing holes 14 of the first layer 7-1 and the second layer 7-2 of the top plate 7.

Note that the ratio of (radius of inner circle 31):(radius of outer circle 33) in FIG. 3A is not limited to the above value, but the ratio can be set as follows.

FIGS. 3D to 3H show the results in a case where simulation is carried out by using the apparatus of FIGS. 22A and 22B. Here, it is supposed that the gas flow passages 240 and 241 of FIG. 22B serving as a nozzle for blowing gas correspond to the substrate central part gas blowing holes 12 and the substrate peripheral part gas blowing holes 14 disposed at the top plate 7 of the embodiment, respectively. That is, it is supposed that the gas flow passage 240 for blowing the gas just under in FIG. 22B corresponds to the substrate central part gas blowing hole 12. it is supposed that the gas flow passage 241 for blowing the gas obliquely downward in FIG. 22B corresponds to the substrate peripheral part gas blowing hole 14. Under such supposition, the ratio of (radius of inner circle 31):(radius of outer circle 33) with which it is easy to obtain more excellent in-surface uniformity at plasma doping than that of the apparatus of FIGS. 22A and 22B is estimated based on FIGS. 3D to 3F showing the results after 20 sec, 40 sec, 60 sec, 120 sec, and 200 sec from the plasma doping start. After 120 sec and 200 sec, it is found that in-surface uniformity can be obtained in the almost entire surface of the substrate W.

FIG. 3D shows a sheet resistance distribution of the substrate W with a diameter of 300 mm after 20 sec from the plasma doping start in a case of using the apparatus disclosed in FIGS. 22A and 22B. A range of 3 mm from the peripheral edge of the substrate W is excluded from measuring objects of the sheet resistance while the sheet resistances at 121 points in the measuring object range of a diameter 294 mm (=300 mm−3 mm×2) are measured. The substrate central part of a range of a radius of about 90 mm or less in the substrate W is shown as a “lower sheet resistance region”, that is, a higher dose amount region. Meanwhile, the substrate peripheral part of a range of a radius of about 90 mm to about 150 mm in the substrate W is shown as a “higher sheet resistance region”, that is, a lower dose amount region. In such a manner (as shown in FIGS. 22A and 22B), when the gas nozzle is disposed at only the substrate central part and the gas blows from the nozzle only just under and obliquely downward to be designed to obtain in-surface uniformity at plasma doping, an average value of the sheet resistance is appeared in the vicinity of a radius of about 90 mm.

From the result of FIG. 3D, in the plasma doping apparatus of the embodiment, the substrate W is divided into two regions: the region of the radius of 90 mm or less (substrate central part region) and the region of the radius of more than 90 mm (substrate peripheral part region) so as to be capable of controlling the gas supply amounts of the gas blowing against the respective regions of the substrate W, and thus, it can be supposed to obtain more excellent in-surface uniformity.

As a result, a plurality of gas blowing holes (the substrate central part gas blowing holes 12) are provided at the central part region of the top plate 7 which corresponds to a place just above the region (substrate central part region) of the radius of 90 mm or less from the center of the substrate W (the center of the substrate placement region of the sample electrode). The mixing ratios and flow rates of the gas blowing through the substrate central part gas blowing holes 12 is controlled by the mass flow controllers MFC1 and MFC2. Next, a plurality of gas blowing holes (the substrate peripheral part gas blowing holes 14) are provided at the peripheral part region of the top plate 7 which corresponds to a place just above the region (substrate peripheral part region) of the radius of more than 90 mm from the center of the substrate W (the center of the substrate placement region of the sample electrode). The mixing ratios and flow rates of the gas blowing through the substrate peripheral part gas blowing holes 14 is controlled by the mass flow controllers MFC3 and MFC4. It is preferable to arrange the substrate peripheral part gas blowing holes 14 at the region of the radius of at least 90 mm to 150 mm of the substrate W. If the substrate peripheral part gas blowing holes 14 are arranged at the region of the top plate which corresponds to the region of the radius of less than 90 mm, it is difficult to supply the gas to the outermost peripheral edge part of the substrate W, resulting in difficulty in obtaining the high precision uniformity. More preferably, the substrate peripheral part gas blowing holes 14 are arranged at the region where its radius in the substrate W being 90 mm or more as large as possible. That is, regarding the gas supply from the top plate, it is preferable to arrange gas supply holes at the top plate as larger as possible. According to such a arrangement, it is easy to uniformly supply the gas to even the outermost peripheral part of the substrate W as well as the region of the radius of 90 mm in the substrate W. Note that when the top plat has too large to increase the whole size of the apparatus, resulting in impairing cost efficiency. Therefore, it is preferable to arrange the substrate peripheral part gas blowing holes 14 at the region of the radius of 90 mm to 270 mm in the substrate W. In such a range, as viewed from the outermost peripheral part of the substrate W, the gas is supplied from the top plate having sufficiently large without the cost efficiency.

Thus, regarding the result of FIG. 3D, from the result at 20 seconds of the plasma doping time, the radius of the inner circle 31 and the radius of the outer circle 33 in FIG. 3A may be set in such a range that (the radius of the inner circle 31):(the radius of the outer circle 33)=90:150=3:5, (the radius of the outer circle 33)/(the radius of the inner circle 31)=1.66 to (the radius of the inner circle 31):(the radius of the outer circle 33)=3:9, and (the radius of the outer circle 33)/(the radius of the inner circle 31)=3.

As a result of a similar analysis, regarding the result of FIG. 3F, from the result at 60 seconds of the plasma doping time, the radius of the inner circle 31 and the radius of the outer circle 33 in FIG. 3A may be set in such a range that (the radius of the inner circle 31):(the radius of the outer circle 33)=2:5, (the radius of the outer circle 33)/(the radius of the inner circle 31)=2.5 to (the radius of the inner circle 31):(the radius of the outer circle 33)=2:9, and (the radius of the outer circle 33)/(the radius of the inner circle 31)=4.5.

As summarized, the ratio of the radius of the inner circle 31 and the radius of the outer circle 33 in FIG. 3A may be preferably set in such a range that (the radius of the outer circle 33)/(the radius of the inner circle 31)=1.66 to 4.5. In such a range, it is found that specifically excellent in-surface uniformity of the dose amount can be obtained based on the above presumption results.

FIG. 1E is a specifically explanatory view for explaining an example of the flow of the plasma doping gas containing the impurities by the apparatus and the method for plasma doping according to the first embodiment of the present invention with a state where gas molecules G flow in lines schematically shown by arrows, in a similar way to FIG. 1B. The line is made of quarts with an inner diameter of 3 mm. The length of the gas flow passage for flowing the gas from the start point F1 at the upper end along the central axis of the substrate downward up to the point F2 (upper-side vertical gas flow passage) is not less than a value of ten times as longer as the inner diameter of 3 mm, preferably. The reason is that when gas molecules G laterally flow from the mass flow controllers MFC1 to MFC4 to the upper end point F1 along the central axis of the substrate in the first gas supply line 11 or the second gas supply line 13, the gas molecules G are surely brought into contact with the inner wall of the line of the downward gas flow passage of from the point F1 to the point F2 (upper-side vertical gas flow passage) to reduce lateral motion components of the gas molecules G as much as possible. Thus, according to such an arrangement, at the point F2, the lateral motion components of the gas molecules G become almost zero. In such a state, the gas molecules flow from the point F2 to the point F3 laterally in the gas flow passage (inside and outside lateral gas flow passage), and thus, the sheet resistance distribution is made almost rotationally symmetric around the center of a substrate.

Meanwhile, FIG. 1F is a specifically explanatory view for explaining the flow of the gas of the International publication WO 2006/106872A1 with a state where the gas molecules G flow in lines schematically shown by arrows, in a similar way to FIG. 1D. In this case, the lines are made of fluorine with an inner diameter of 3 mm. The length of the gas flow passage for flowing the gas from the upper end point F22 along the central axis of the substrate downward up to the point F23 is 5 to 10 mm, which is about 1.7 to 3.3 times as longer as the inner diameter of 3 mm. Thus, some of the gas molecules G flow from the point F22 to the point F23 obliquely downward while the gas molecules G are hardly brought into contact with the inner wall of the line of the gas flow passage, that is, merely pass through the line obliquely downward. In other words, the gas molecules G flown from the point F21 to the point F22 have lateral motion components, and while the gas molecules G have such lateral motion components, the gas molecules G flow from the point F22 to the point F23. Then, when the gas molecules G flow from the point F23 to the point F24, it is easy to flow the gas molecules G in the right direction inevitably. Then, as pointed out as the issues of the conventional technique, it seems that the sheet resistance distribution might not be made rotationally symmetric around the center of a substrate.

Contrarily, as described above, in the embodiments of the present invention, the length of the gas flow passage for flowing the gas from the start point F1 at the upper end along the central axis of the substrate downward up to the point F2 (upper-side vertical gas flow passage) is not less than a value of ten times as longer as the inner diameter of 3 mm, preferably. The gas molecules G can be surely brought into contact with the inner wall of the line of the downward gas flow passage (upper-side vertical gas flow passage) to reduce lateral motion components of the gas molecules G as much as possible. Thus, the sheet resistance distribution can be uniformly corrected at the whole surface of the substrate.

Preferably, as one working example, the upper-side vertical gas flow passage 15a and the upper-side vertical gas flow passage 16a are disposed in the center of the top plate 7, and a length of the upper-side vertical gas flow passage 15a is set five times or more of the length of the lower-side vertical gas flow passage 15d, and the length of the upper-side vertical gas flow passage 16a is set five times or more of the length of the lower-side vertical gas flow passage 16d. With such a structure, the gas of the same flow rate is easily supplied to the vacuum vessel 1 from the holes with the same distance (radius) from the center of the top plate 7, out of the substrate central part gas blowing holes 12 and the substrate peripheral part gas blowing holes 14. Therefore, there is an advantage that the in-surface uniformity with excellent dose amount can be obtained in plasma doping.

As plasma doping conditions for executing plasma doping in the plasma doping apparatus according to the aforementioned structure, for example, the source gas flown to the first gas flow passage 15 is B₂H₆ obtained by diluting this source gas with He, and the concentration of B₂H₆ in the source gas is in a range of from 0.05 wet % to 5.0 wet %. The source gas flown to the second gas flow passage 16 is also B₂H₆ obtained by diluting this source gas with He, and the concentration of B₂H₆ in the source gas is in a range of from 0.05 wet % to 5.0 wet %. Then, in accordance with the condition of the dose amount, namely, in accordance with the condition of plasma, the concentration of B₂H₆ of the first gas flow passage 15 is set higher or lower than the concentration of B₂H₆ of the second gas flow passage 16, to thereby be able to excellently adjust the dose amount of in-surface uniformity of the substrate 9. Note that as an example, a pressure in the vacuum vessel (vacuum chamber) is set to about 1.0 Pa, a source power (plasma generating high frequency power) is set to about 1000 W, a total flow rate of the source gas is set to about 100 cm³/min (standard state) in the first gas flow passage 15 and the second gas flow passage 16 respectively, a substrate temperature is set to 30° C., and the plasma doping time is set to about 60 seconds. The substrate is a large diameter substrate with a diameter of 300 mm, as an example.

Particularly, as an example, a bias voltage of the high frequency power applied from the high frequency power supply 10 is preferably adjusted in a range of from 30 V to 600 V. With such a structure, an implantation depth of boron implanted into silicon of the substrate 9 can be adjusted to an extremely shallow region such as a range of from about 5 nm to 20 nm. When the bias voltage is smaller than 30V, the implantation depth is shallower than 5 nm, with hardly functioning as an extension electrode. Meanwhile, when the bias voltage is larger than 600 V, the implantation depth is deeper than 20 nm, and therefore an extremely shallow extension electrode as required in the present silicon device can not be formed. Therefore, by adjusting the bias voltage in a range of from 30 V to 600 V, the extension electrode with an optimal depth can be formed, and this further preferable. Note that the implantation depth of boron is defined as the depth of achieving 5E18 cm⁻³ of boron concentration in silicon, and normally an SIMS (Secondary Ion Mass Spectrometry), etc, using oxygen ion, with primary ion energy set at about 250 eV, is used for inspection.

Next, preferably, the concentrations of B₂H₆ in the source gas flown to the first gas flow passage 15 and the second gas flow passage 16 are adjusted in a range of from 0.05 wet % to 5.0 wet %. With such a structure, the dose amount of boron implanted into silicon can be adjusted in a range of from 5E13 cm⁻² to 5E16 cm⁻². When the concentration of B₂H₆ is lower than 0.05 wet %, there is an issue that boron is hardly implanted. When the concentration of B₂H₆ is higher than 5.0 wet %, there is an issue that boron is easily deposited on the surface of silicon. Therefore, if the concentration of B₂H₆ is adjusted in a range of from 0.05 wet % to 5.0 wet %, boron is easily implanted and this is preferable. Further, the concentration of B₂H₆ is preferably adjusted in a range of from 0.2 wet % to 2.0 wet %. By thus adjusted, the dose amount of boron implanted into silicon can be adjusted in a range of from 5E14 cm⁻² to 5E15 cm⁻², and a most optimal dose amount can be obtained in a source/drain extension region.

It is preferable that the source gas contains boron and is diluted with rare gas. By diluting the source gas with the rare gas, there is an advantage that only dilution exhibits the advantage and a side effect hardly occurs, because the rare gas has a significantly low reactivity with a semiconductor material such as silicon.

In addition, it is also preferable to dilute the gas with hydrogen. The hydrogen is an atom having a smallest atomic weight, and therefore when the hydrogen collides with silicon, the energy given to the silicon atom is smallest. In the apparatus and the method for plasma doping of the present invention, there is a larger ratio of dilution gas than impurity gas. Therefore, a percentage of a collision of ionized dilution gas in plasma with a silicon crystal is significantly larger than a percentage of a collision of an impurity ion with the silicon crystal. Accordingly, it is important to reduce an influence of the collision of the ionized dilution gas with a substrate material such as silicon. Meanwhile, when hydrogen is used for the dilution gas, a collision energy that occurs when the dilution gas is ionized in plasma and collides with the silicon crystal can be made smallest, and this is preferable.

In addition, more preferably helium is used as the dilution gas. Helium has a smallest atomic weight in the rare gas, and has the second small atomic weight following hydrogen in all atoms. Accordingly, helium is only one atom with a characteristic of having extremely low reactivity with the semiconductor material, which the rare gas has, and a characteristic of having a smaller energy given to a silicon atom when collided with silicon, which hydrogen has.

As described above, according to the plasma doping apparatus of the first embodiment, a gas flow along the vertical direction along the central axis of the substrate 9 can be formed by the gas supplied to the gas flow passage of the top plate 7 from the gas supply device 2 by the gas supply lines 11, 13. Therefore, the gas blown from the gas blowing holes 12 and 14 can be made uniform, and the sheet resistance distribution is made rotationally symmetric around the substrate center. Accordingly, in plasma doping, the high precision uniformity can be obtained, corresponding to a plurality of process conditions. Further, by using this plasma doping apparatus under a limited condition, a tremendous high precision intra-substrate surface distribution of the sheet resistance of the layer of the source/drain extension region can be realized, although such a high precision uniformity can not be realized by a global development achieved by conventional devices for about the past ten years.

Needless to say, even when the present invention is applied to forming the layer of the source/drain extension region of a device having a three-dimensional structure such as a FinFET, similarly to the planar device, the advantage of realizing an excellent uniformity can be obtained.

In addition, instead of the source/drain extension region, even when the impurities are implanted into a layer of a channel region under a gate, it is possible to obtain a tremendous advantage that the uniformity with excellent dose amount which has been impossible conventionally because of a shallow implantation depth can be realized by the present invention, and the semiconductor device, to which the implantation of impurities is applied, can be manufactured.

In addition, arsenic may be used instead of boron as an impurity. By using arsenic, an N-type doping layer can be formed, while by using boron, a P-type doping layer can be obtained.

In addition, phosphorus may be used instead of boron as an impurity. By using phosphorus, the N-type doping layer can be formed similarly to the case of using arsenic. Further, the rate for sputtering the semiconductor substrate is smaller in plasma using phosphorus than in plasma using arsenic, thus making it easy to perform plasma doping processing without changing a shape of the substrate, and this is preferable.

In addition, according to the first embodiment, the gas flow passage forming member 17 is formed of quartz, and although the gas flow passage forming member 17 may be formed of a metal such as stainless steel (SUS), quartz is more preferably used. This is because the quartz allows the magnetic field to transmit without substantially absorbing the magnetic field, with almost no influence on the plasma distribution. In addition, when the quartz is used in the gas flow passage forming member 17, the gas flow passage forming member 17 is preferably protruded to an upper side of an upper end portion of the coil 8. This is because by forming the gas flow passage forming member 17 of quartz so as to extend to the upper side of the upper end portion of the coil 8 from the connection part with the top plate 7, the magnetic filed is hardly intercepted and the plasma is easily uniformly created.

In addition, the gas flow passage forming member 17 is not limited to the aforementioned structure, and can be executed by other various modes.

### (First Modification)

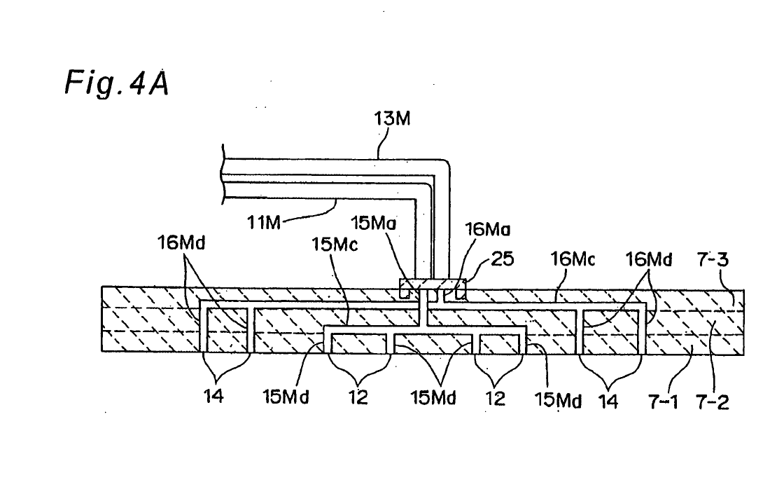

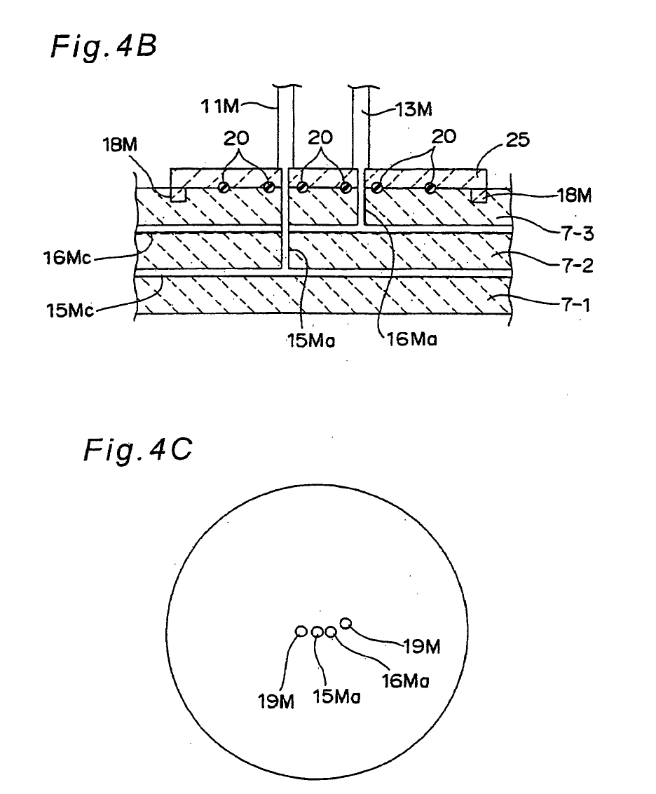

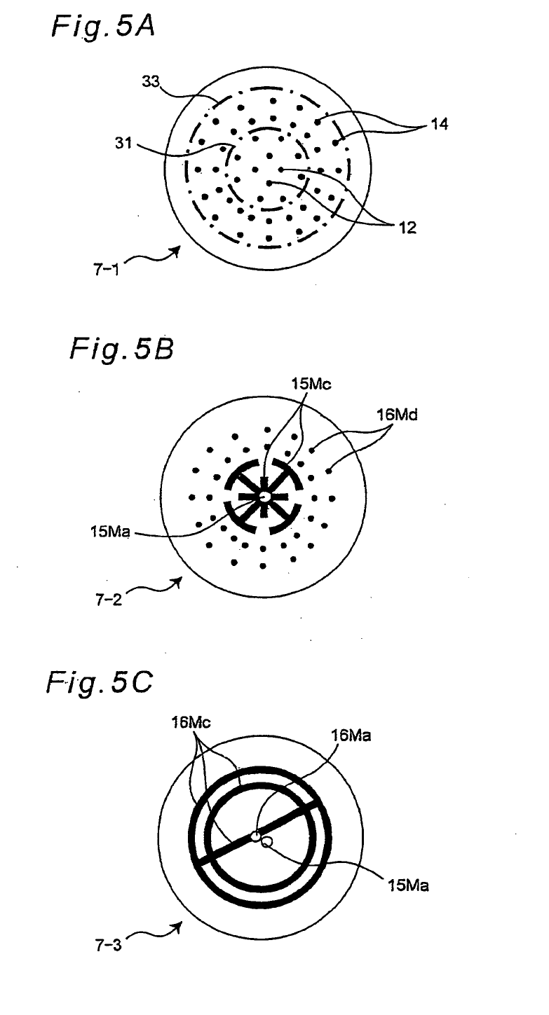

For example, as shown in FIG. 4A to FIG. 5C, as a first modification, lines 11M, 13M of stainless steel may be directly connected to the central part of the outer surface 7b of the top plate 7. That is, the first gas supply line 11M and the second gas supply line 13M are similarly bent at right angles, and their end portions are respectively directly connected to the central part of the outer surface 7b of the top plate 7. More specifically, each lower end of the first gas supply line 11M and the second gas supply line 13M is fixed to a connection member 25, and two positioning projections 18, 18 are formed on a lower surface of the connection member 25. Meanwhile, two positioning holes 19, 19 are formed in the central part of the outer surface 7b of the top plate 7, and when the first gas supply line 11M and the second gas supply line 13M are directly connected to the central part, the two positioning projections 18, 18 of the connection member 25 are engaged with the two positioning holes 19, 19 of the central part of the outer surface 7b of the top plate 7 to perform positioning, so that positioning of the connection member 25, namely, each lower end of the first gas supply line 11M and the second gas supply line 13M, and the top plate 7 can be performed. In addition, sealing is achieved by disposing the O-rings 20 respectively in the circumference of the opening of the connection member 25 and in the circumference of the openings of the upper-side vertical gas flow passage 15Ma and the upper-side vertical gas flow passage 16Ma, each communicating with the lower surface of the connection member 25 and each lower end of the first gas supply line 11M and the second gas supply line 13M and constituting a part of the first gas flow passage 15N and a part of the second gas flow passage 16N respectively.

Regarding the other flow passage, the structure is almost the same as the structure of FIG. 2A.

That is, similarly to FIG. 2A, in the first modification also, the top plate 7 is formed of a three-layer lamination structure, such as the first layer 7-1, the second layer 7-2, and the third layer 7-3 sequentially from the substrate side toward to the opposite side to the substrate 9.

On the third layer 7-3 of the top plate 7, the upper-side vertical gas flow passage 15Ma that communicates with the first gas supply line 11M is formed so as to penetrate through the third layer 7-3, and the upper-side vertical gas flow passage 16Ma that communicates with the second gas supply line 13M is formed so as to penetrate through the third layer 7-3, and an outside lateral gas flow passage 16Mc that extends laterally and communicates with the upper-side vertical gas flow passage 16Ma is formed on the joint surface between the third layer 7-3 and the second layer 7-2.

The upper-side vertical gas flow passage 15Ma that communicates with the upper-side vertical gas flow passage 15Ma of the third layer 7-3 is formed on the second layer 7-2 of the top plate 7 so as to penetrate therethrough, and a plurality of lower-side vertical gas flow passages 16Md that penetrate the second layer 7-2 in the thickness direction, with each upper end communicated with the outside lateral gas flow passage 16Mc of the third layer 7-3 in FIGS. 4A and 4B, is formed on the second layer 7-2 of the top plate 7. Further, on the second layer 7-2 of the top plate 7, an outside lateral gas flow passage 15Mc that laterally extends and communicates with the upper-side vertical gas flow passage 15Ma is formed on the joint surface between the second layer 7-2 and the first layer 7-1.

The outside vertical gas flow passage 16Md that communicates with the outside vertical gas flow passage 16Md of the second layer 7-2 is formed on the first layer 7-1 of the top plate 7 so as to penetrate therethrough, and a plurality of lower-side vertical gas flow passages 15Md that penetrate the first layer 7-1 in the thickness direction, with each upper end communicated with the outside lateral gas flow passage 15Mc as shown in FIG. 4A and FIG. 4B, are formed on the first layer 7-1 of the top plate 7 so as to penetrate therethrough. The opening of the lower end of each lower-side vertical gas flow passage 15Md of the first layer 7-1 serves as the substrate central part gas blowing hole 12, and the opening of the lower end of each lower-side vertical gas flow passage 16Md serves as the substrate peripheral part gas blowing hole 14.

Thus, with the structure in which the top plate 7 is embedded with a communication part of the upper-side vertical gas flow passage 15Ma and the outside lateral gas flow passage 15Mc, and a communication part of the upper-side vertical gas flow passage 16Ma and the outside lateral gas flow passage 16Mc (a branched part of upper-side vertical gas flow passage and the outside lateral gas flow passage), the gas flow passage forming member 17 of FIG. 2A can be eliminated, thus preferably achieving a simple structure. In addition, the connection member 25 and the top plate 7 are directly connected to each other, thus making it possible to reduce the number of the O-rings 20 to be disposed, compared to a case of FIG. 2A, and this is preferable. In addition, with this structure, by applying a force in a contact direction of the O-rings of the connection member 25 from the upper side of the connection member 25 to which the first gas supply line 11M and the second gas supply line 13M are fixed, sealing is performed by the O-rings 20. Thus, a sealing direction by the O-rings 20 and a direction of applying the force to the O-rings 20 from the connection member 25 are identical to each other. Therefore, there is an advantage of mixing the atmosphere into the vacuum vessel 1 and preventing flow out of the source gas to an atmospheric environment.

### (Second Modification)

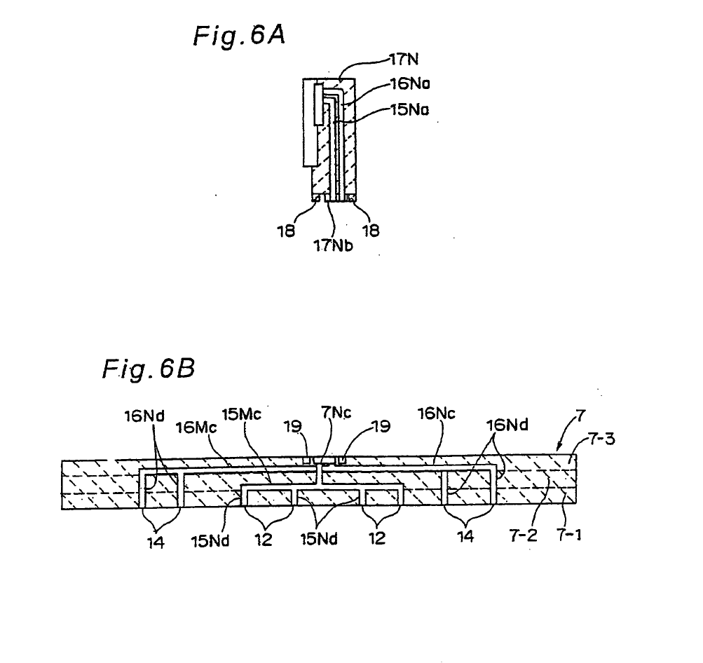

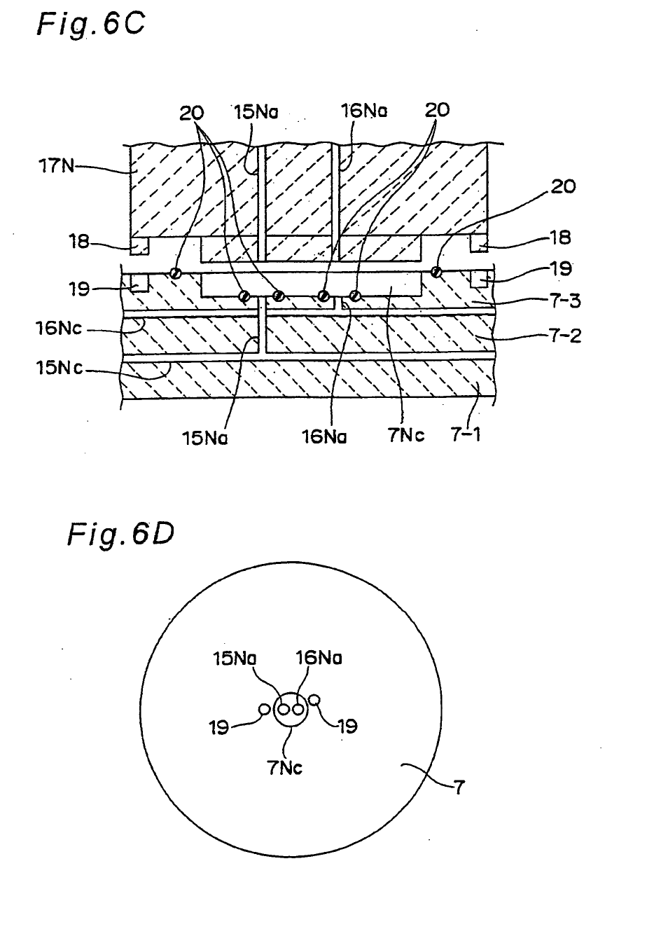

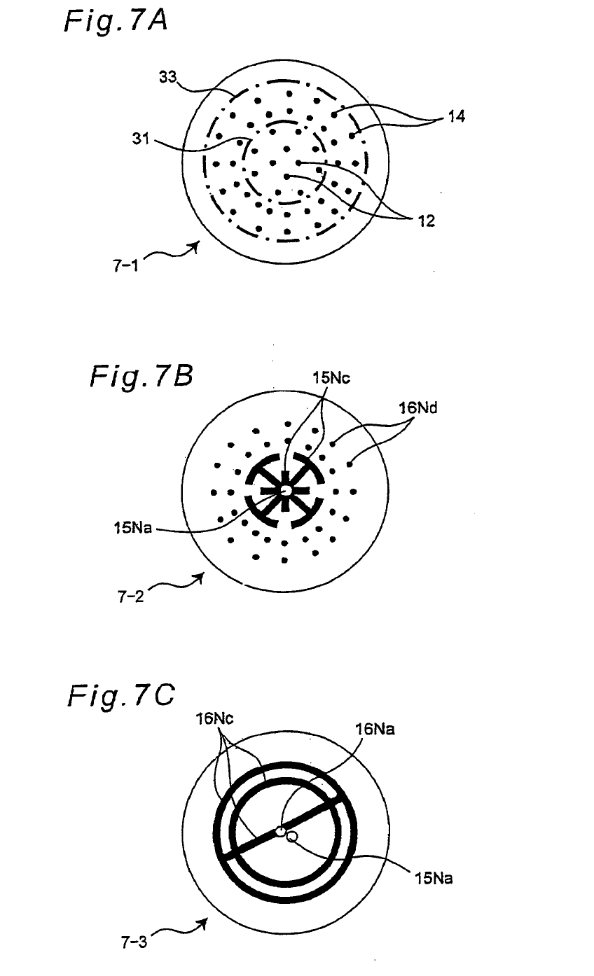

Next, as a second modification, instead of providing in the gas flow passage forming member 17 the branched flow passage to the flow passage in the lateral direction from the flow passage in the vertical direction as shown in FIG. 2A, a simplified structure wherein only the flow passage in the vertical direction is formed in a gas flow passage forming member 17N is shown in FIG. 6A to FIG. 7C.

Specifically, an upper-side vertical gas flow passage 15Na and an upper-side vertical gas flow passage 16Na constituting a part of the first gas flow passage 15 and a part of the second gas flow passage 16 respectively along the longitudinal direction of the gas flow passage forming member 17N are formed in the gas flow passage forming member 17N.

Meanwhile, a recess portion 7Nc is formed in the central part of the outer surface 7b of the top plate 7 without penetrating therethrough, so as to achieve connection by engagement of an engagement part 17Nb of the gas flow passage forming member 17N with the recess portion 7Nc. In addition, the upper-side vertical gas flow passage 15Na and the upper-side vertical gas flow passage 16Na capable of communicating with the upper-side vertical gas flow passage 15Na and the upper-side vertical gas flow passage 16Na of the gas flow passage forming member 17N are provided on the bottom surface of the recess portion 7Nc.

In this second modification also, in the same way as shown in FIG. 2A, the top plate 7 is formed of the three-layer lamination structure, such as the first layer 7-1, the second layer 7-2, and the third layer 7-3 sequentially from the substrate side toward the opposite side to the substrate 9.

The upper-side vertical gas flow passage 15Na and the upper-side vertical gas flow passage 16Na capable of communicating with the upper-side vertical gas flow passage 15Na and the upper-side vertical gas flow passage 16Na of the gas flow passage forming member 17N respectively are formed on the third layer 7-3 of the top plate 7 so as to penetrate therethrough, and the outside lateral gas flow passage 16Nc that extends laterally and communicates with the upper-side vertical gas flow passage 16Na is formed on the joint surface between the third layer 7-3 and the second layer 7-2.

A plurality of lower-side vertical gas flow passages 16Nd that penetrate the second layer 7-2 in the thickness direction, with each upper end communicated with the outside lateral gas flow passage 16Nc of the third layer 7-3 as shown in FIG. 6B and FIG. 6C are formed on the second layer 7-2 of the top plate 7. Further, on the second layer 7-2 of the top plate 7, an outside lateral gas flow passage 15Nc that extends in the lateral direction and communicates with the upper-side vertical gas flow passage 15Na of the third layer 7-3 is formed on the joint surface between the second layer 7-2 and the first layer 7-1.

A plurality of lower-side vertical gas flow passages 15Nd that penetrate the first layer 7-1 in the thickness direction, with each upper end communicated with the outside lateral gas flow passage 15Nc as shown in FIG. 6B and FIG. 6C are formed on the first layer 7-1 of the top plate 7 so as to penetrate therethrough. Further, a plurality of lower-side vertical gas flow passages 16Nd that communicate with the plurality of lower-side vertical gas flow passages 16Nd of the second layer 7-2 are formed on the first layer 7-1 of the top plate 7 so as to penetrate therethrough. The opening of the lower end of each lower-side vertical gas flow passage 15Nd of the first layer 7-1 serves as the substrate central part gas blowing hole 12, and the opening of the lower end of each lower-side vertical gas flow passage 16Nd serves as the substrate peripheral part gas blowing hole 14.

Thus, with a structure wherein the top plate 7 is embedded with the branched part of the flow passage, the structure of the gas flow passage forming member 17N itself can be made simpler than the structure of the gas flow passage forming member 17 of FIG. 2A. In addition, the number of the O-rings 20 can be reduced, and this is preferable.

In addition, with this structure, by adding the force downward in the longitudinal direction of the gas flow passage forming member 17N from the upper side in the longitudinal direction of the gas flow passage forming member 17N, sealing is performed by using the O-rings 20. Accordingly, the sealing direction by the O-rings 20 and the direction of adding the force to the O-rings 20 from the gas flow passage forming member 17N are identical to each other. Therefore there is an advantage of preventing the mixing of the atmosphere into the vacuum vessel 1 and preventing the flow out of the source gas to the atmospheric environment, and this is preferable.

### (Third Modification)

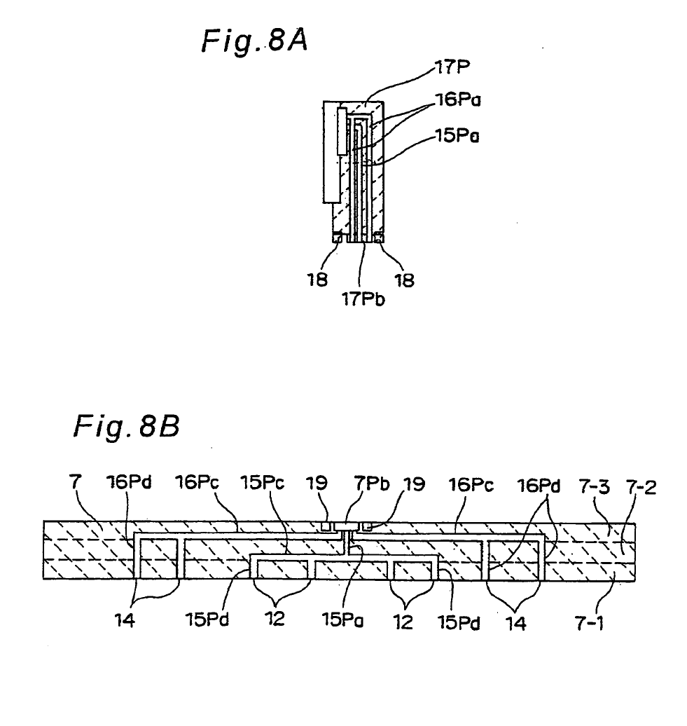

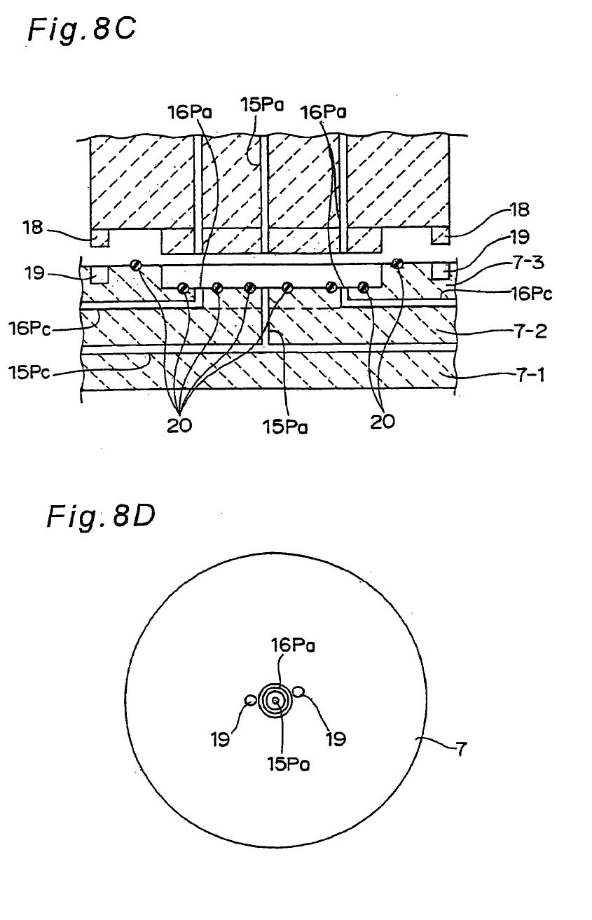

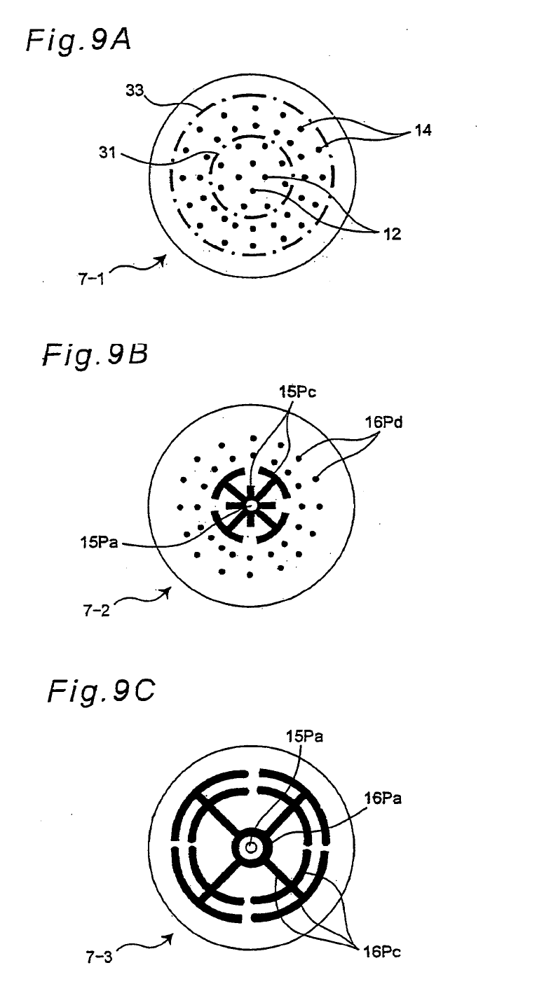

Next, as a third modification, instead of forming in the gas flow passage forming member 17 the vertical gas flow passages 15a and 16a having almost the same diameter as shown in FIG. 2A, one of the flow passages is disposed along the central axis of the gas flow passage forming member 17 and the other flow passage is disposed around the one flow passage so as to be formed into a round cylindrical shape as shown in FIG. 8A to FIG. 9C, and then the two flow passages may be formed concentrically, in other words, completely rotationally symmetric.

Specifically, an upper-side vertical gas flow passage 15Pa constituting a part of the first gas flow passage 15 along the central axis of a gas flow passage forming member 17P is disposed in the gas flow passage forming member 17P, and an upper-side vertical gas flow passage 16Pa constituting a part of the second gas flow passage 16 is formed into a round cylindrical shape around the upper-side vertical gas flow passage 15Pa.

Meanwhile, a recess portion 7Pc is formed in the central part of the outer surface 7b of the top plate 7 without penetrating therethrough, so that connection is achieved by the engagement of an engagement part 17Pb of the gas flow passage forming member 17P with the recess portion 7Pc. In addition, the upper-side vertical gas flow passage 15Pa with the center opened and the upper-side vertical gas flow passage 16Pa with opening in a ring shape, capable of communicating with the upper-side vertical gas flow passage 15Pa and the upper-side vertical gas flow passage 16Pa of the gas flow passage forming member 17P are provided on the bottom surface of the recess portion 7Pc.

In this third modification also, in the same way as shown in FIG. 2A, the top plate 7 is formed of the three-layer lamination structure, such as the first layer 7-1, the second layer 7-2, and the third layer 7-3 sequentially from the substrate side toward the opposite side to the substrate 9.

The upper-side vertical gas flow passage 15Pa with the center opened and the upper-side vertical gas flow passage 16Pa with opening in a ring shape, capable of communicating with the upper-side vertical gas flow passage 15Pa and the upper-side vertical gas flow passage 16Pa of the gas flow passage forming member 17P are formed on the third layer 7-3 of the top plate 7 so as to penetrate therethrough, and an outside lateral gas flow passage 16Pc that laterally extends and communicates with the upper-side vertical gas flow passage 16Pa is formed on the joint surface between the third layer 7-3 and the second layer 7-2.

A plurality of lower-side vertical gas flow passages 16Pd that penetrate the second layer 7-2 in the thickness direction, with each upper end communicated with the outside lateral gas flow passage 16Pc of the third layer 7-3 as shown in FIG. 8B and FIG. 8C are formed on the second layer 7-2 of the top plate 7. Further, on the second layer 7-2 of the top plate 7, an outside lateral gas flow passage 15Pc that laterally extends and communicates with the upper-side vertical gas flow passage 15Pa of the third layer 7-3 is formed on the joint surface between the second layer 7-2 and the first layer 7-1.

A plurality of lower-side vertical gas flow passages 15Pd that penetrate the first layer 7-1 in the thickness direction, with each upper end communicated with the outside lateral gas flow passage 15Pc as shown in FIG. 8B and FIG. 8C are formed on the first layer 7-1 of the top plate 7 so as to penetrate therethrough. Further, a plurality of lower-side vertical gas flow passages 16Pd that communicate with the plurality of lower-side vertical gas flow passages 16Pd of the second layer 7-2 respectively are formed on the first layer 7-1 of the top plate 7 so as to penetrate therethrough. The opening of the lower end of each lower-side vertical gas flow passage 15Pd of the first layer 7-1 serves as the substrate central part gas blowing hole 12, and the opening of the lower end of each lower-side vertical gas flow passage 16Pd serves as the substrate peripheral part gas blowing hole 14.

Thus, the gas flow passage is disposed rotationally symmetric around the center of the top plate 7, and therefore further improvement in the uniformity can be realized.

### SECOND EMBODIMENT

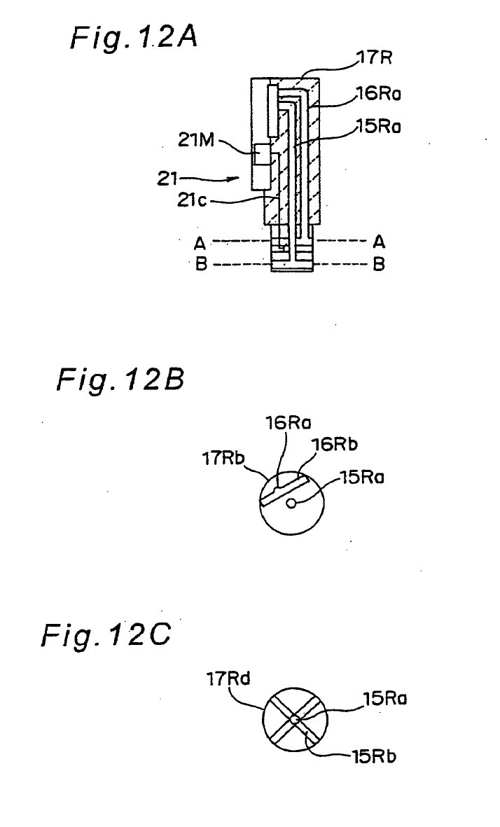

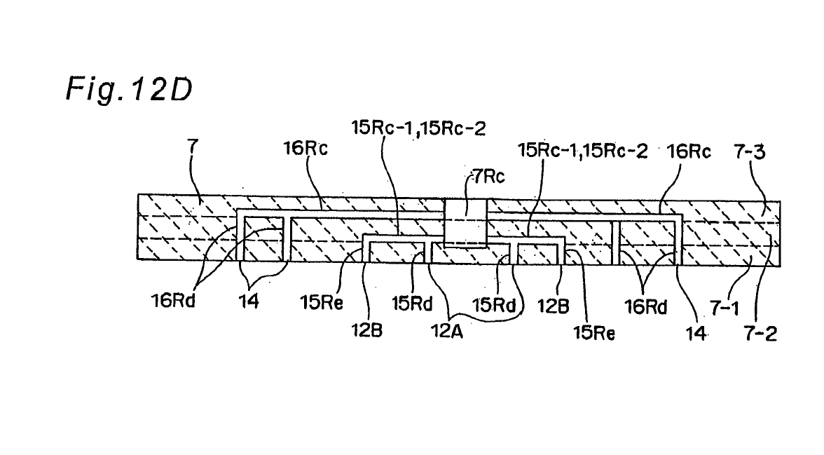

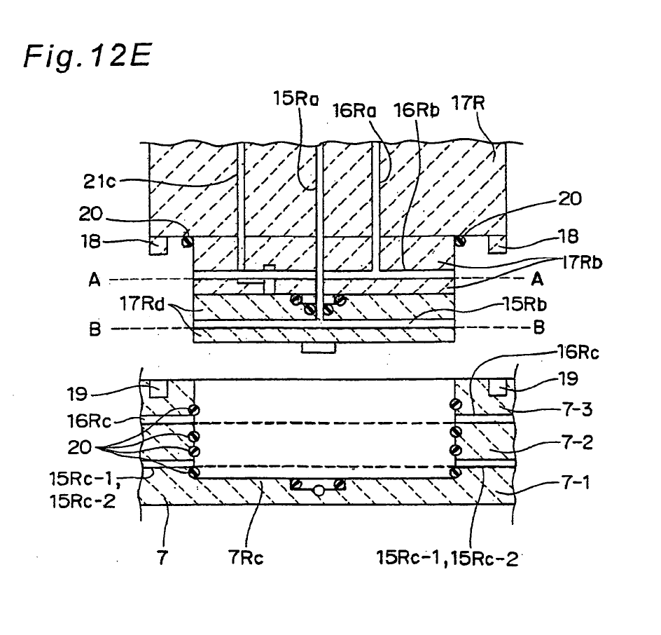

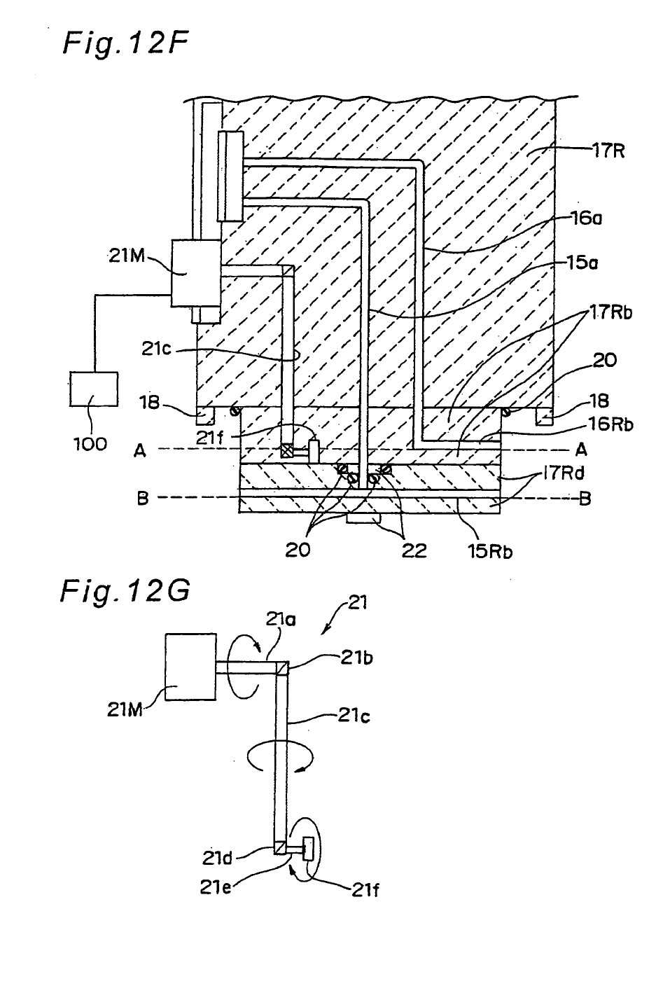

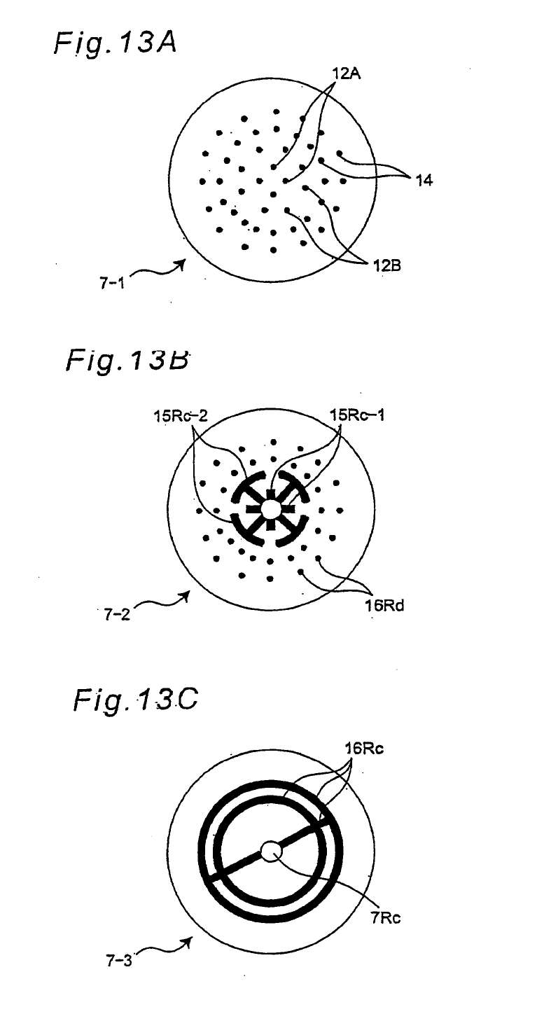

Next, as shown in FIG. 12A to FIG. 15E, as a second embodiment of the present invention, explanation is given to the structure that in the apparatus structure of the first embodiment, a rotation mechanism 21 is provided in a tip end of the gas flow passage forming member 17 and by changing a rotation position, a part of the flow passage can be changed. Note that the same reference numerals are assigned to the same parts as the apparatus structure of the first embodiment and the explanation therefore is omitted.

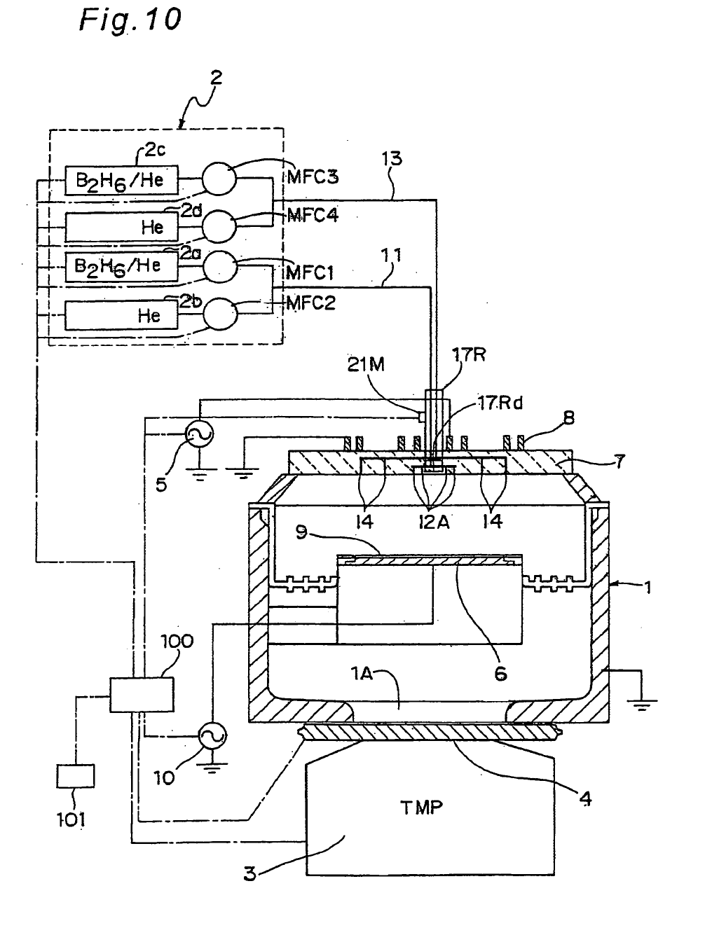

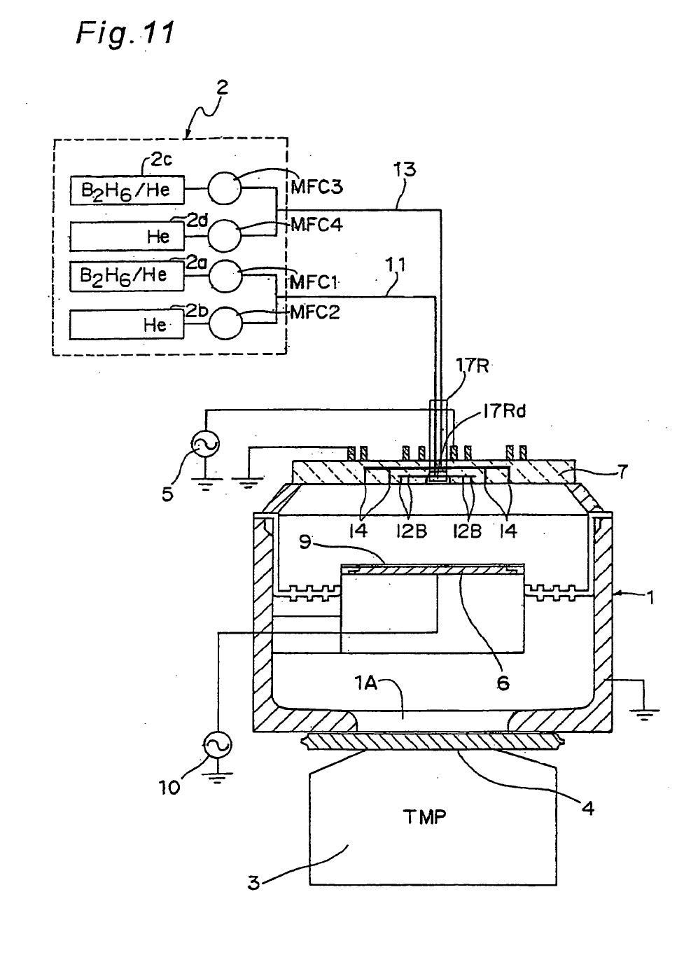

FIG. 10 is a partially sectional view of a plasma doping apparatus used in the second embodiment of the present invention, showing a case that the rotational angle of a disc part 17Rd rotationally disposed on the tip end of the engagement part 17Rb of the gas flow passage forming member 17 is set at a rotational position of 0 degree. FIG. 11 is also a similar figure (the control device 100, etc. is omitted.), showing the rotational angle of the disc part 17Rd rotationally disposed on the tip end of the gas flow passage forming member 17, so as to be rotated by 45° from the position of 0° to the position of 45° and is set at the rotational position of 45°. FIG. 10 and FIG. 11 show a case that the gas blowing holes for blowing the gas actually supplied to the inside of the vacuum vessel 1 from the first gas flow passage 15, can be selected out of a first substrate central part gas blowing holes 12A and a second substrate central part gas blowing holes 12B disposed rotationally symmetric around the central part of the substrate 9. In FIG. 10, the gas is supplied only to the vicinity of the center of the central part of the substrate 9 from the first substrate central part gas blowing holes 12A, corresponding to the position of the rotational angle of the disc part 17Rd of the tip end of the gas flow passage forming member 17, which is set at the rotational position of 0°. Meanwhile, in FIG. 11, the gas is supplied, rather than the vicinity of the center of the central part of the substrate 9 shown in FIG. 10, from the outside thereof, from the second substrate central part gas blowing holes 12B, corresponding to the position of the rotational position of the disc part 17Rd of the tip end of the gas flow passage forming member 17, which is set at the rotational position of 45°.

Explanation will be given hereunder to the mechanism to allow the aforementioned structure to be realized.

The gas flow passage through the first gas supply line 11, the second gas supply line 13, and the gas flow passage forming member 17R has two systems in the same way as the first embodiment.

Meanwhile, unlike the first embodiment, the gas flow passage of the top plate 7 has three systems. That is, depending on the rotational position of the tip end of the gas flow passage forming member 17R, the gas flow passage of one system (the gas flow passage on the side of the first gas flow passage 15) in the gas flow passages of two systems of the gas flow passage forming member 17R, and the gas flow passages of two systems on the side of the first gas flow passage 15 in the gas flow passages of three systems of the top plate 7 can be selectively switched and connected to each other.

The rotation mechanism 21 is provided in the gas flow passage forming member 17R, so that the disc part 17Rd having a communication switching gas flow passage, is rotatably disposed on the lower end of the engagement part 17b of the gas flow passage forming member 17R, thus capable of switching between the switching gas flow passage and the flow passage of the top plate 7 by a rotational angle (rotational position) of the disc part.

On the lower end of the engagement part 17b of the gas flow passage forming member 17R, the disc part 17Rd is rotatably supported to the engagement part 17b by the rotation shaft 22.

As shown in FIG. 12A and FIG. 12G, the rotation mechanism 21, with a motor 21M disposed on the side part of the gas flow passage forming member 17R and serving as an example of a rotation driving device subjected to driving control by the control device 100, including a lateral first rotation shaft 21a connected to a rotation shaft of the motor 21M; a first rotation axis conversion member 21b connected to the first rotation shaft 21a, for vertically converting a transfer direction of a rotating force of the lateral first rotation shaft 21a; a vertical second rotation shaft 21c connected to the first rotation axis conversion member 21b; a second rotation axis conversion member 21d for laterally converting the transfer direction of the rotating force of the vertical second rotation shaft 21c; a lateral third rotation shaft 21e connected to the second rotation axis conversion member 21d; and a rotation roller 21f fixed to the third rotation shaft 21e, press-contacted to the surface of the disc part 17Rd, to rotate the disc part 17Rd.

Therefore, the disc part 17Rd is rotated by the rotation roller 21f, by a forward/backward rotation or one directional rotation of the motor 21M, under a control of the control device 100.

FIG. 12A to FIG. 12E are partially sectional views of the gas flow passage forming member 17R and the top plate 7 for connecting the gas flow passage and the top plate 7.

The gas flow passages 15 and 16 of two systems are connected to the top plate 7 via the gas flow passage forming member 17R. The gas flow passage forming member 17R has two gas flow passages, such as an upper-side vertical gas flow passage 15Ra and an upper-side vertical gas flow passage 16Ra.

As shown in FIG. 12B which is the sectional view taken along the line A-A of FIG. 12A, the engagement part 17Rb of the lower end of the gas flow passage forming member 17R is formed, in such a manner that the upper-side vertical gas flow passage 15Ra is formed so as to penetrate a center position of the engagement part 17Rb, the upper-side vertical gas flow passage 16Ra is formed so as to penetrate the position deviated from the center independently of the upper-side vertical gas flow passage 15Ra, and a lateral gas flow passage 16Rb that communicates with the upper-side vertical gas flow passage 16Ra is formed. This lateral gas flow passage 16Rb is disposed so as to deviate from the center as shown in FIG. 12B, so as not to be communicated with the upper-side vertical gas flow passage 15Ra disposed in the center.

The disc part 17Rd is rotatably disposed on the lower end of the engagement part 17Rb. At a center position of the disc part 17Rd, the upper-side vertical gas flow passage 15Ra that communicates with the upper-side vertical gas flow passage 15Ra penetrating the engagement part 17Rb is formed, and a cross-shaped lateral gas flow passage 15Rb (an example of the communication-switching gas flow passage) that communicates with the lower end of the upper-side vertical gas flow passage 15Ra is formed.

A recess portion 7Rc that can be engaged with the engagement part 17Rb and the disc part 17Rd of the gas flow passage forming member 17R is formed in the center part of the outer surface 7b of the top plate 7.

In this second embodiment also, in the same way as shown in FIG. 2A, the top plate 7 is formed of the three-layer lamination structure, such as the first layer 7-1, the second layer 7-2, the third layer 7-3 from the substrate side toward the opposite side to the substrate 9.

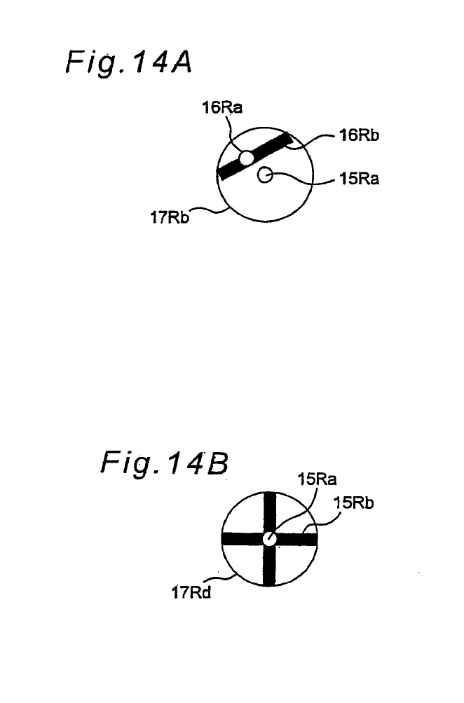

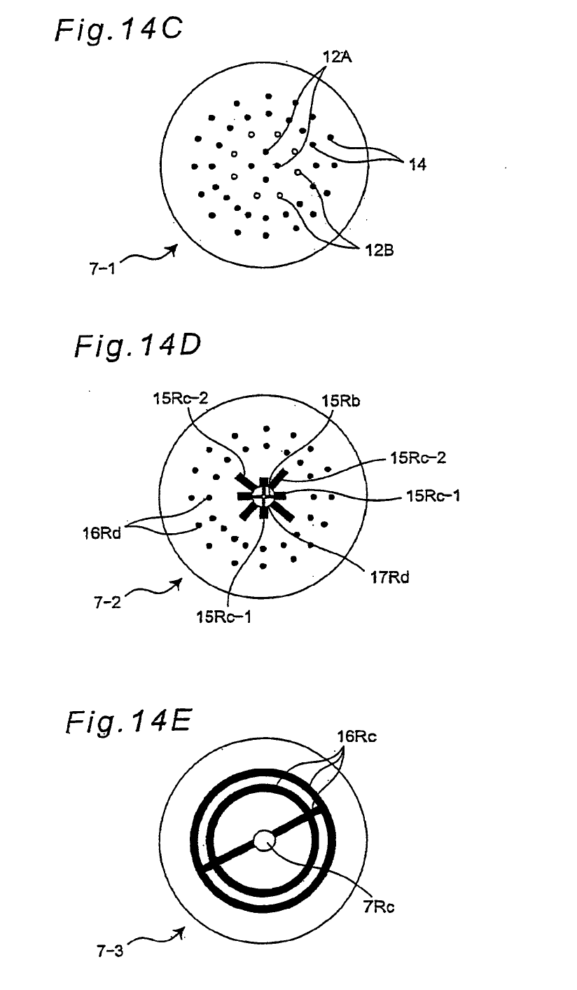

As shown in FIG. 14E, a part of the recess portion 7Rc is formed on the third layer 7-3 of the top plate 7 so as to penetrate therethrough, and an outside lateral gas flow passage 16Rc capable of communicating with the lateral gas flow passage 16Rb of the engagement part 17Rb of the gas flow passage forming member 17R engaged with the recess portion 7Rc is formed on the joint surface between the third layer 7-3 and the second layer 7-2.

As shown in FIG. 14D, a part of the recess portion 7Rc is formed on the second layer 7-2 of the top plate 7 so as to penetrate therethrough, and a plurality of lower-side vertical gas flow passages 16Rd that penetrate the second layer 7-2 in the thickness direction, with each upper end communicated with the outside lateral gas flow passage 16Rc of the third layer 7-3 as shown in FIG. 12D are formed on the second layer 7-2 of the top plate 7. Further, on the second layer 7-2 of the top plate 7, two kinds of outside lateral gas flow passages 15Rc are formed on the joint surface between the second layer 7-2 and the first layer 7-1, such as a first outside lateral gas flow passage 15Rc-1 and a second outside lateral gas flow passage 15Rc-2 that communicate with the cross-shaped upper-side lateral gas flow passage 15Rb of the disc part 17Rd on the lower end of the engagement part 17Rb of the gas flow passage forming member 17R engaged with the recess portion 7Rc. The first outside lateral gas flow passage 15Rc-1 is a cross-shaped flow passage that vertically and laterally extends as shown in FIG. 14D. However, this flow passage is defined as being set at the rotational position with the rotational angle of 0°. The second outside lateral gas flow passage 15Rc-2 is an obliquely extending cross-shaped flow passage that is rotated by 45° around the rotating axis from the outside lateral gas flow passage 15Rc-1 in FIG. 14D, and defined as being set at a rotation position with the rotational angle of 45°. Therefore, when the disc part 17Rd is positioned at the rotation position with the rotational angle of 0°, the cross-shaped upper-side lateral gas flow passage 15Rb of the disc part 17Rd is communicated with only the first outside lateral gas flow passage 15Rc-1. When the disc part 17Rd is positioned at the rotation position with the rotational angle of 45°, the cross-shaped upper-side lateral gas flow passage 15Rb of the disc part 17Rd is communicated with only the second outside lateral gas flow passage 15Rc-2.

As shown in FIG. 14C, a plurality of first lower-side vertical gas flow passages 15Rd that penetrate the first layer 7-1 in the thickness direction, with each upper end communicated with the first outside lateral gas flow passage 15Rc-1 as shown in FIG. 12D are formed on the first layer 7-1 of the top plate 7 so as to penetrate therethrough, and a plurality of second lower-side vertical gas flow passages 15Re that penetrate the first layer 7-1 in the thickness direction, with each upper end communicated with the second outside lateral gas flow passage 15Rc-2 as shown in FIG. 12D are formed on the first layer 7-1 of the top plate 7 so as to penetrate therethrough. The opening of the lower end of each first lower-side vertical gas flow passage 15Rd of the first layer 7-1 serves as the first substrate central part gas blowing hole 12A disposed close to the center of the substrate central part. The opening of the lower end of each second lower-side vertical gas flow passage 15Re of the first layer 7-1 serves as the second substrate central part gas blowing hole 12B disposed close to the periphery of the substrate central part. Further, a plurality of lower-side vertical gas flow passages 16Rd that communicate with the plurality of lower-side vertical gas flow passages 16Rd of the second layer 7-2 are formed on the first layer 7-1 of the top plate 7 so as to penetrate therethrough. The opening of the lower end of each lower-side vertical gas flow passage 16Rd serves as the substrate peripheral part gas blowing hole 14.

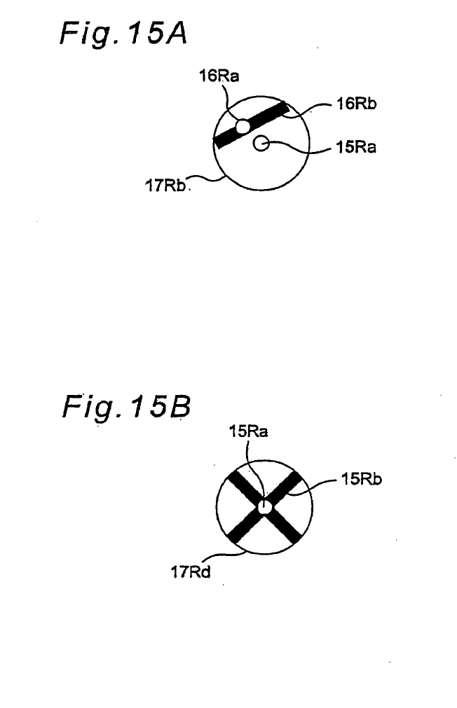

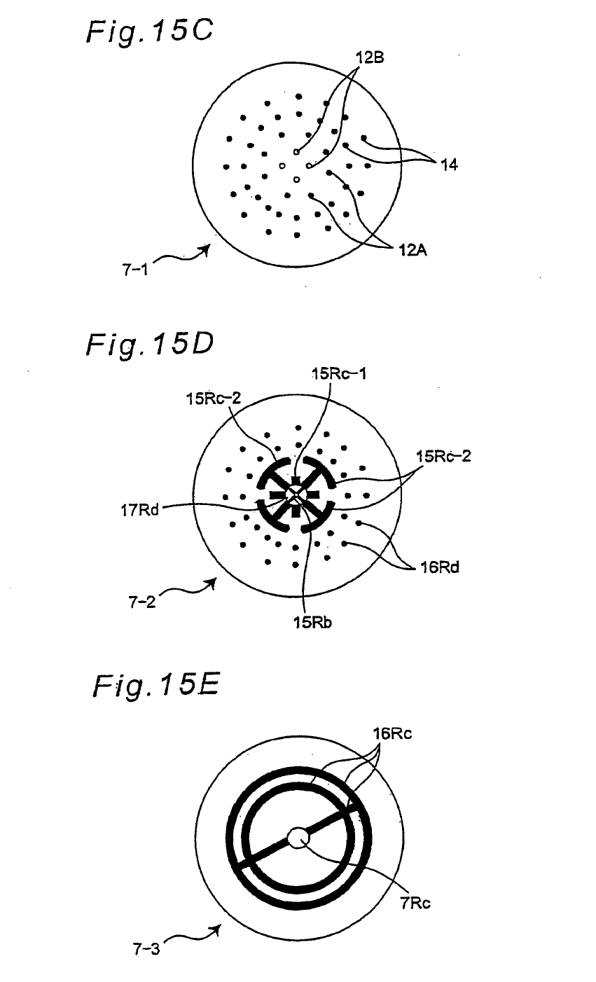

As a result of such a structure, as shown in FIG. 14A to FIG. 14E, by a drive of the rotation mechanism 21, when the rotational angle of the disc part 17Rd of the tip end of the gas flow passage forming member 17R is positioned at a rotational position of 0°, the gas is blown toward the substrate 9 from a plurality of the first substrate central part gas blowing holes 12A disposed close to the center of the central part of the substrate 9 as shown by black circles on the first layer 7-1 in FIG. 14C. In addition, as shown in FIG. 15A to FIG. 15E, by a drive of the rotation mechanism 21, when the rotational angle of the disc part 17Rd of the tip end of the gas flow passage forming member 17R is positioned at the rotational position of 45°, the gas is blown toward the substrate 9 from the plurality of second substrate central part gas blowing holes 12B disposed close to the periphery of the central part of the substrate 9 as shown by black circles on the first layer 7-1 in FIG. 15C. Irrespective of the rotational angle of the disc part 17Rd, the gas is constantly blown toward the substrate 9 from the substrate peripheral part gas blowing holes 14. Note that in FIG. 14C and FIG. 15C, white circles mean the gas blowing holes not blowing the gas.

With such a structure, when distribution of the dose amount due to a factor other than gas blow is low in the vicinity of the center of the substrate central part, in other words, when the distribution is high in the vicinity of the periphery of the substrate central part, the gas blow amount in the vicinity of the center of the substrate central part can be made larger than the gas blow amount in the vicinity of the periphery of the substrate central part, by switching the rotational angle of the disc part 17Rd to the rotational position of 0°, thus making it easy to uniformly adjust the intro-substrate surface dose amount. Meanwhile, reversely, when the distribution of the dose amount due to the factor other than gas blow is high in the vicinity of the center of the substrate central part, in other words, when the distribution is low in the vicinity of the periphery of the substrate central part, the gas blow amount in the vicinity of the periphery of the substrate central part (an intermediate part between the substrate central part and the substrate peripheral part) can be made larger than the gas blow amount in the vicinity of the center of the substrate central part by switching the rotational angle of the disc part 17Rd of the tip end of the gas flow passage forming member 17R to the rotational position of 45°, thus making it easy to uniformly adjust the intra-substrate surface dose amount.

As described above, according to the plasma doping apparatus of the second embodiment, it is characterized in that a plurality of vertical gas flow passages 15Ra and 16Ra are provided in the central part of the top plate 7 by the rotation mechanism 21, the disc part 17Rd, and the recess portion 7Rc, etc, and a positioning mechanism of a plurality of connection holes for communicating and connecting the vertical gas flow passages 15Ra and 16Ra and the lateral gas flow passages 15Rc-1, 15Rc-2, and 16Rc of the inside of the top plate 7 with each other is constituted, and the plurality of connection holes are formed between the vacuum vessel inner surface 7a and the outer surface 7b of the top plate 7. That is, on apparatus that has a space for providing the gas flow passage on the upper side of the central part of the top plate 7, by forming a mechanism for positioning the plurality of connection holes to connect the plurality of gas flow passages vertically provided in the central part of the top plate 7 and the plurality of gas flow passages provided inside of the top plate 7, the apparatus and the method are realized, whereby the flow of the gas containing impurities according to plasma doping in the embodiments of the present invention, such as the flow of the gas that starts from the upper side in the vertical direction, downward, directed laterally, and then downward is possible.

With such a structure, although in the conventional apparatus, it is difficult to excellently maintain the uniformity of the sheet resistance based on a plurality of plasma doping conditions, by changing a combination pattern of the connection of the gas flow passage forming member 17R and the gas flow passage of the top plate 7 in accordance with change of plasma doping condition, it is possible to select the positions of the gas blowing holes 12A and 12B from which the gas is blown with no opening of the vacuum vessel 1 and maintaining the vacuum state, corresponding to the plasma doping conditions. Accordingly, impurity implantation can be executed by the plasma doping with more excellent uniformity based on the plurality of plasma doping conditions, and the semiconductor device, into which the impurities are implanted, can be manufactured.

Note that it is more preferable to form each connection hole in a space of not larger than the height of the coil 8 and not higher than the lower surface of the top plate 7. This is because it is easy to manufacture the top plate 7 made of quartz, for example, having a plurality of gas flow passages inside of the top plate 7. When the connection hole is formed at a place higher than the height of the coil 8, a convex portion must be formed on the top plate 7, thus involving an issue that the convex portion is easily broken in a manufacturing process. When the connection hole is formed at a place lower than the lower surface of the top plate 7, a shape of plasma is affected thereby, thus involving an issue of producing non-uniform plasma.

### THIRD EMBODIMENT

Next, explanation will be given to a method of uniformly correcting the distribution of the sheet resistance which is non-uniform in the first setting, by using the plasma doping apparatus according to a third embodiment of the present invention. In these methods, the plasma doping is executed by a dummy substrate first, and a feedback of a result thus obtained is performed, thus adjusting a gas supply for improving the uniformity.

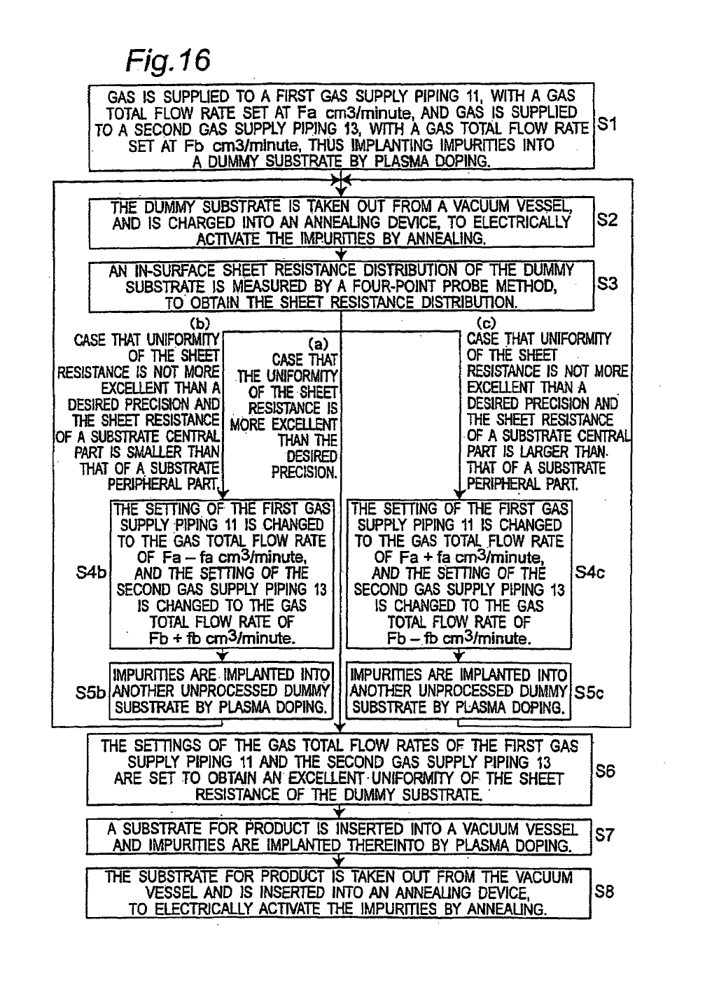

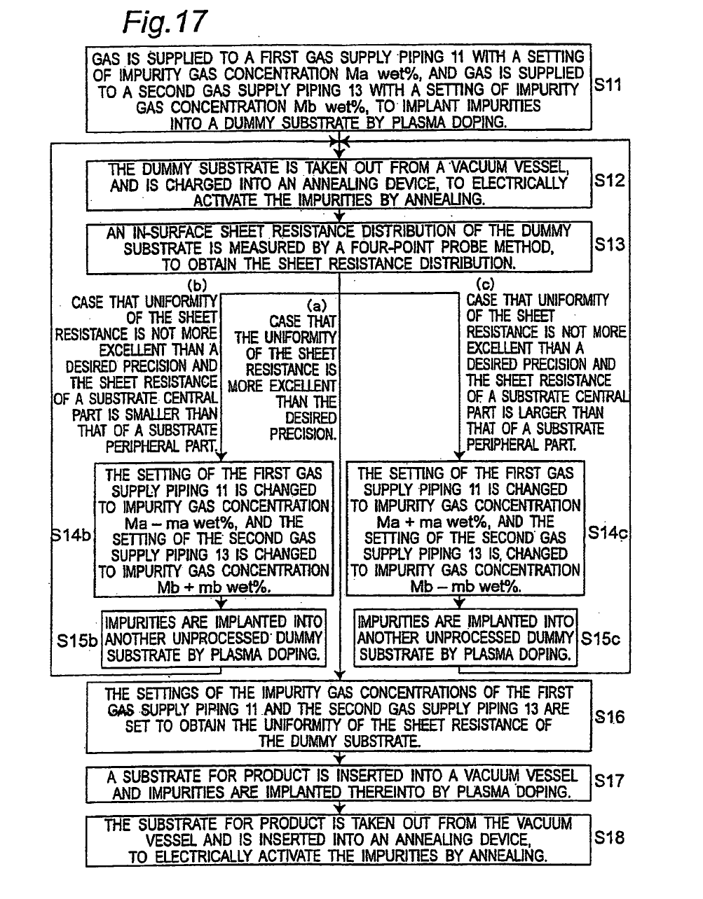

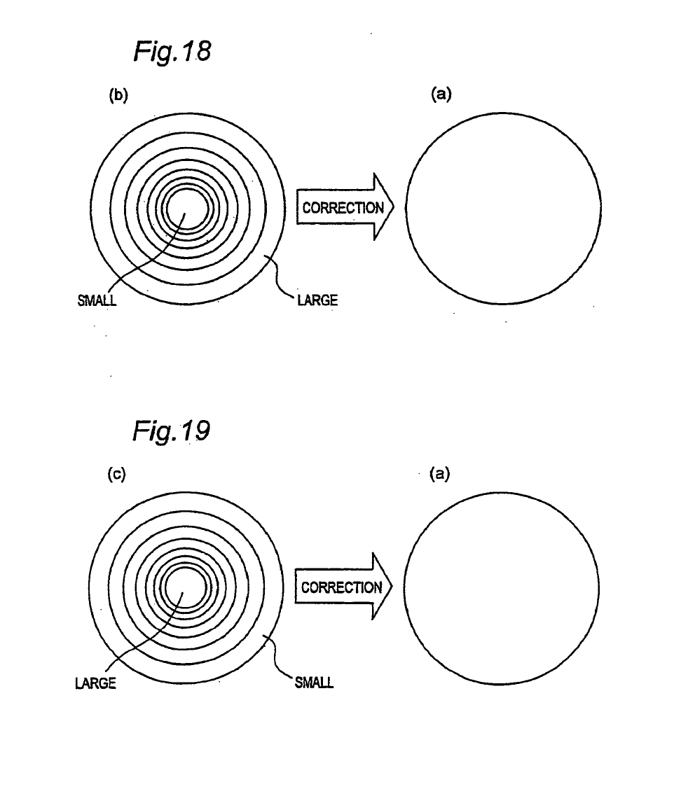

Specifically, by executing the method in accordance with the flow of FIG. 16 or FIG. 17, the sheet resistance distribution which is non-uniform in the first setting can be uniformly corrected as shown in FIG. 18 or FIG. 19.

FIG. 16 shows an example of a method of correcting the uniformity of the sheet resistance distribution by adjusting a gas total flow rate as the third embodiment of the present invention. The following operations are mainly performed under a control of the control device 100, and as necessary, the information is stored in a storage section 101 and the information previously stored in the storage section 101 is read.

(Step S1)

First, under the control of the control device 100, operations of the gas supply device 2 and the first to fourth mass flow controllers MFC1 to MFC4 are controlled, and the gas is supplied to the first gas supply line 11, with the gas total flow rate set at Fa cm³/min (standard state), the gas is supplied to the second gas supply line 13, with the gas total flow rate set at Fb cm³/min (standard state), and the impurities are implanted into the dummy substrate by plasma doping.

For example, Fa is set at 50 cm³/min (standard state), and Fb is also set at 50 cm³/min (standard state). At this time, the gas total flow rate supplied from the first gas supply line 11 and the second gas supply line 13 is set at 100 cm³/min (standard state). In step S1, Fa and Fb is preferably set at the same gas flow rate, because correction thereafter can be easily performed.

(Step S2)

Subsequently, under the control of the control device 100, the dummy substrate is taken out from the vacuum vessel 1 by a known method not shown, inserted into an annealing device not shown, and the impurities of the dummy substrate are electrically activated by annealing.

(Step S3)

Subsequently, the in-surface sheet resistance distribution of the dummy substrate is measured by a four-point probe method, etc, to obtain the distribution of the sheet resistance. The information regarding the distribution of this sheet resistance is stored in the storage section 101. Based on the information regarding the sheet resistance distribution stored in the storage section 101, any one of the cases as described below is determined by a control unit (such as an operation unit) of the control device 100. Specifically, for example, a threshold value corresponding to a desired precision is previously stored in the storage section 101, and a typical value out of the sheet resistance distribution and the threshold value are compared by the operation unit, and any one of the following three cases may be determined.

Processing of the step S3 and thereafter is divided into the following three cases and advances:

(a) Case that the measured uniformity of the sheet resistance distribution is more excellent than the desired precision (see (a) of FIG. 18 and (a) of FIG. 19),

(b) Case that the measured uniformity of the sheet resistance distribution is not more excellent than the desired precision, and the sheet resistance of the substrate central part is smaller than that of the substrate peripheral part (see (b) of FIG. 18),

(c) Case that the measured uniformity of the sheet resistance is not more excellent than the desired precision, and the sheet resistance of the substrate central part is larger than that of the substrate peripheral part (see (c) of FIG. 19).

First, in the case (a), when the uniformity of the sheet resistance distribution is more excellent than the desired precision, the processing is advanced to step S6 under the control of the control device 100.

In addition, in the case (b), when the uniformity of the sheet resistance distribution is not more excellent than the desired precision, and when the sheet resistance of the substrate central part is smaller than that of the substrate peripheral part, the processing is advanced to step S4b under the control of the control device 100.

In addition, in the case (c), when the uniformity of the sheet resistance distribution is not more excellent than the desired precision, and the sheet resistance of the substrate central part is larger than that of the substrate peripheral part, the processing is advanced to step S4c under the control of the control device 100.

(Step S4b)

Under the control of the control device 100, the operations of the gas supply device 2 and the first to fourth mass flow controllers MFC1 to MFC4 are controlled, and setting of the gas total flow rate Fa−fa cm³/min (standard state) of the first gas supply line 11, and setting of the gas total flow rate Fb+fb cm³/min of the second gas supply line 13 are changed and then the processing is advanced to step S5b.

For example, Fa−fa is set at 49 cm³/min (standard state), and Fb+fb is set at 51 cm³/min (standard state). Thus, the total flow rate of the gas supplied from the first gas supply line 11 and the second gas supply line 13 are set at 100 cm³/min (standard state), and without changing this total ratio, only the ratio of the gas flow rates supplied from the first gas supply line 11 and the second gas supply line 13 is changed. With this structure, only the uniformity of the sheet resistance can be controlled without changing other performance, and this is more preferable. In addition, the uniformity of the sheet resistance can be strictly controlled, by setting fa and fb at 1/100 times to 10/100 times of the total flow rate of the gas supplied from the first gas supply line 11 and the second gas supply line 13.

(Step S5b)

Under the control of the control device 100, after implanting the impurities into another unprocessed dummy substrate by plasma doping, the processing is returned to step S2.

(Step S4c)

Under the control of the control device 100, the operations of the gas supply device 2 and the first to fourth mass flow controllers MFC1 to MFC4 are controlled, and after the setting of the first gas supply line 11 is changed to the gas total flow rate Fa+fa cm³/min (standard state), and the setting of the second gas supply line 13 is changed to Fb−fb cm³/min (standard state), the processing is advanced to step S5c.

(Step S5c)

Under the control of the control device 100, the impurities are implanted into another unprocessed dummy substrate by plasma doping, and then the processing is returned to step S2.

(Step S6)

As the setting of the gas total flow rate of the first gas supply line 11 and the second gas supply line 13, the setting of obtaining an excellent uniformity of the sheet resistance of the dummy substrate is used. That is, the information regarding a set value of the gas total flow rate of the first gas supply line 11 and the second gas supply line 13 is stored in the storage section 101 as the information regarding the set value achieving an excellent uniformity of the sheet resistance distribution of the dummy substrate.

(Step S7)

Subsequently, under the control of the control device 100, the substrate 9 for product is inserted into the vacuum vessel 1, and the impurities are implanted by plasma doping.

(Step S8)

Subsequently, under the control of the control device 100, the substrate 9 for product is taken out from the vacuum vessel 1 and is inserted into the annealing device, to electrically activate the impurities by annealing.

By these steps, it is possible to execute the method of correcting the uniformity of the sheet resistance distribution by adjusting the gas total flow rate. As a result, as shown in (b) of FIG. 18, the case that the uniformity of the sheet resistance distribution is not more excellent than the desired precision and the sheet resistance of the substrate central part is smaller than that of the substrate peripheral part, can be corrected to the case that the uniformity of the sheet resistance distribution is more excellent than the desired precision as shown in (a) of FIG. 18. In addition, as shown in (c) of FIG. 19, the case that the uniformity of the sheet resistance distribution is not more excellent than the desired precision and the sheet resistance of the substrate central part is larger than that of the substrate peripheral part, can be corrected to the case that the uniformity of the sheet resistance distribution is more excellent than the desired precision as shown in (a) of FIG. 19.

FIG. 17 shows a method of correcting the uniformity of the sheet resistance distribution by adjusting gas concentration, as a modification of the third embodiment of the present invention.

(Step S11)

First, under the control of the control device 100, the operations of the gas supply device 2 and the first to fourth mass flow controllers MFC1 to MFC4 are controlled, and the gas is supplied to the first gas supply line 11, with the setting of impurity gas concentration Ma wet %, and the gas is supplied to the second gas supply line 13, with the impurity gas concentration Mb wet %, and the impurities are implanted into the dummy substrate by plasma doping.

For example, Ma is set at 0.5 wet %, and Mb is set at 0.5 wet %. In step S11, Ma and Mb are set at the same impurity gas concentration, thus making it easy to perform correction thereafter, and this is preferable.

(Step S12)

Subsequently, under the control of the control device 100, the dummy substrate is taken out from the vacuum vessel 1 by a known method not shown, and the dummy substrate is inserted into the annealing device not shown, to electrically activate the impurities of the dummy substrate by annealing.

(Step S13)

Subsequently, the in-surface sheet resistance distribution of the dummy substrate is measured by the four-point probe method, etc, to obtain the sheet resistance distribution. The information of the sheet resistance distribution is stored in the storage section 101. Based on the information regarding the sheet resistance distribution stored in the storage section 101, any one of the following cases is determined by the control unit (such as the operation unit) of the control device 100. Specifically, for example, a threshold value corresponding to the desired precision is previously stored in the storage section 101, and a typical value out of the sheet resistance distribution and the threshold value are compared by the operation unit, and any one of the following three cases may be determined.

The processing after step S13 is divided into the following three cases and advances:

(a) Case that the measured uniformity of the sheet resistance distribution is more excellent than the desired precision (see (a) of FIG. 18 and (a) of FIG. 19),

(b) Case that the measured uniformity of the sheet resistance distribution is not more excellent than the desired precision, and the sheet resistance of the substrate central part is smaller than that of the substrate peripheral part (see (b) of FIG. 18), and

(c) Case that the measured uniformity of the sheet resistance distribution is not more excellent than the desired precision, and the sheet resistance of the substrate central part is larger than that of the substrate peripheral part (see (c) of FIG. 19).

First, in the case (a), when the uniformity of the sheet resistance distribution is more excellent than the desired precision, under the control of the control device 100, the processing is advanced to step S16.

In addition, in the case (b), when the uniformity of the sheet resistance distribution is not more excellent than the desired precision, and the sheet resistance of the substrate central part is smaller than that of the substrate peripheral part, under the control of the control device 100, the processing is advanced to step S14b.

In addition, in the case (c), when the uniformity of the sheet resistance distribution is not more excellent than the desired precision, and when the sheet resistance of the substrate central part is larger than that of the substrate peripheral part, under the control of the control device 100, the processing is advanced to step S14c.

(Step S14b)

Under the control of the control device 100, the operations of the gas supply device 2 and the first to fourth mass flow controllers MFC1 to MFC4 are controlled, and the setting of the first gas supply line 11 is changed to the impurity gas concentration of Ma−ma wet %, and the setting of the second gas supply line 13 is changed to the impurity gas concentration of Mb+mb wet %, and the processing is advanced to step S15b.

(Step S15b)

Under the control of the control device 100, the impurities are implanted into another unprocessed dummy substrate by plasma doping, and thereafter the processing is returned to step S12.

(Step S14c)

Under the control of the control device 100, the operations of the gas supply device 2 and the first to fourth mass flow controllers MFC1 to MFC4 are controlled, and the setting of the first gas supply line 11 is changed to impurity gas concentration of Ma+ma wet %, and the setting of the second gas supply line 13 is changed to the impurity gas concentration of Mb−mb wet %, and thereafter the processing is advanced to step S15c.

For example, Ma+ma is set at 0.52 wet %, and Mb−mb is set at 0.48 wet %. The uniformity of the sheet resistance can be strictly controlled by setting the impurity gas concentration at 1/100 times to 10/100 times of Ma and Mb respectively.

(Step S15c)

Under the control of the control device 100, the impurities are implanted into another unprocessed dummy substrate by plasma doping, and thereafter the processing is returned to step S12.

(Step S16)

At the setting of the impurity gas concentrations of the first gas supply line 11 and the second gas supply line 13, the setting for obtaining the excellent uniformity of the sheet resistance distribution of the dummy substrate is used. That is, the information regarding the set values of the impurity gas concentrations of the first gas supply line 11 and the second gas supply line 13 is stored in the storage section 101 as the information of the set values for obtaining the excellent uniformity of the sheet resistance distribution of the dummy substrate.

(Step S17)

Subsequently, under the control of the control device 100, the substrate 9 for product is inserted into the vacuum vessel 1, and the impurities are implanted by plasma doping.

(Step S18)

Subsequently, under the control of the control device 100, the substrate 9 for product is taken out from the vacuum vessel 1 and is inserted into the annealing device, to electrically activate the impurities by annealing.

By these steps, the method of correcting the uniformity of the sheet resistance distribution by adjusting the gas concentrations can be executed. As a result, as shown in (b) of FIG. 18, the case that the uniformity of the sheet resistance distribution is not more excellent than the desired precision and the sheet resistance of the substrate central part is smaller than that of the substrate peripheral part, is corrected to the case that the uniformity of the sheet resistance distribution is more excellent than the desired precision as shown in (a) of FIG. 18. In addition, as shown in (c) of FIG. 19, the case that the uniformity of the sheet resistance distribution is not more excellent than the desired precision and the sheet resistance of the substrate central part is larger than that of the substrate peripheral part, can be corrected to the case that the uniformity of the sheet resistance distribution is more excellent than the desired precision.

In this embodiment, the top plate 7 is constituted by laminating three layers. However, the top plate 7 may be constituted by laminating two layers.

Note that by properly combining arbitrary embodiments out of the aforementioned various embodiments, the advantage of each embodiment can be exhibited.

The apparatus and the method for plasma doping, and the manufacturing method of the semiconductor device according to the present invention are useful for uniformly implanting the impurities into a substrate with large diameter of 300 mm or more, and further is useful for manufacturing the semiconductor device by uniformly implanting the impurities into the substrate with large diameter.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A plasma doping apparatus comprising:
a vacuum vessel having a top plate;
an electrode disposed in the vacuum vessel and in opposition to an inner surface of the top plate, for placing a substrate thereon;
a high frequency power supply for applying a high frequency power to the electrode;
an exhaust device for exhausting an inside of the vacuum vessel; and
first and second gas supply devices for supplying gas into the vacuum vessel; and
a single gas-nozzle member having first and second upper-side vertical gas flow passages perpendicular to a surface of the electrode,
the top plate having first gas blow holes and second gas blow holes on the inner surface of the top plate,
the first gas supply device is connected to the first gas blow holes through the first upper-side vertical gas flow passage and the second gas supply device is connected to the second gas blow holes through the second upper-side vertical gas flow passage.

2. The plasma doping apparatus according to claim 1,
wherein the top plate comprises a recess portion at a central part of an outer surface of the top plate on an opposite side to the electrode, the single gas-nozzle member is fitted into the recess portion of the top plate,
the top plate has first and second gas flow passages comprising first and second lateral gas flow passages branched independently respectively in a lateral direction intersecting with the longitudinal direction of the single gas-nozzle member and communicated with the first and second upper-side vertical gas flow passages, and first and second lower-side vertical gas flow passages extending downward along the longitudinal direction from the first and second lateral gas flow passages and communicated with the first and second gas blow holes.

3. The plasma doping apparatus according to claim 1, further comprising:
first and second gas supply lines, with respective one ends communicated with the first and second gas supply devices, and respective other ends vertically connected with the first and second upper-side vertical gas flow passages, thereby forming flows along the vertical direction by the gas supplied from the first and second gas supply devices;
wherein the top plate is constituted by laminating a plurality of plate-like members, and
the first and second gas supply lines and the first and second gas flow passages are separately and independently provided to the first gas supply device and the second gas supply device.

4. The plasma doping apparatus according to claim 1, wherein the single gas-nozzle member is a separate element from the top plate.

5. The plasma doping apparatus according to claim 1, wherein a length of each of the first and second upper-side vertical gas flow passages is not less than a value of ten times as longer as an inner diameter of each of the first and second upper-side vertical gas flow passages.

6. The plasma doping apparatus according to claim 2, further comprising:
first and second gas supply lines, with respective one ends communicated with the first and second gas supply devices, and respective other ends vertically connected with the first and second upper-side vertical gas flow passages, thereby forming flows along the vertical direction by the gas supplied from the first and second gas supply devices;
wherein the first and second lower-side vertical gas flow passages and the first and second lateral gas flow passages in the top plate are:
the first lower-side vertical gas flow passage that communicates with the first gas blow holes;
the first lateral gas flow passage that communicates with the first lower-side vertical gas flow passage;
the second lower-side vertical gas flow passage that communicates with the second gas blow holes and independent of the first lower-side vertical gas flow passage; and
the second lateral gas flow passage that communicates with the second lower-side vertical gas flow passage and independent of the first lateral gas flow passage; and
the single gas-nozzle member comprises a disc part having a communication-switching gas flow passage rotatable with respect to the single gas-nozzle member, capable of communicating with one of the first and second upper-side vertical gas flow passages and capable of selectively communicating with the first lateral gas flow passage and the second lateral gas flow passage in accordance with rotational positions,
wherein by changing the rotational position of the disc part of the single gas-nozzle member, either one of the first lateral gas flow passage and the second lateral gas flow passage, and the communication-switching gas flow passage are selectively communicated to each other, so that the gas is blown from gas blow holes that communicates with the lateral gas flow passage that is selectively communicated, through one of the first lateral gas flow passage and the second lateral gas flow passage that is selectively communicated, via the gas supply line and the upper-side vertical gas flow passage and the communication-switching gas flow passage from the gas supply device.

7. The plasma doping apparatus according to claim 1, wherein each of the first and second gas supply device is a device for supplying gas containing B₂H₆.

8. The plasma doping apparatus according to claim 1, wherein each of the first and second gas supply device is a device for supplying gas containing impurities and diluted with rare gas or hydrogen, with a concentration of the gas containing the impurities set at not less than 0.05 wet % and not more than 5.0 wet %.

9. The plasma doping apparatus according to claim 1, wherein each of the first and second gas supply device is a device for supplying gas containing impurities and diluted with rare gas or hydrogen, with a concentration of the gas containing the impurities set at not less than 0.2 wet % and not more than 2.0 wet %.

10. The plasma doping apparatus according to claim 1, wherein a bias voltage of the high frequency power applied from the high frequency power supply is not less than 30 V and not more than 600 V.

11. The plasma doping apparatus according to claim 1, wherein the exhaust device is communicated with an exhaust opening disposed on a bottom surface of the vacuum vessel on an opposite side of the electrode to the top plate, regarding the electrode.

12. A plasma doping method of performing plasma doping by using a plasma doping apparatus comprising:
a vacuum vessel having a top plate;
an electrode disposed in the vacuum vessel and in opposition to an inner surface of the top plate, for placing a substrate thereon;
a high frequency power supply for applying high frequency power to the electrode;
an exhaust device for exhausting an inside of the vacuum vessel;
first and second gas supply devices for supplying gas into the vacuum vessel;
a single gas-nozzle member having first and second upper-side vertical gas flow passages perpendicular to a surface of the electrode; and
first gas blow holes and second gas blow holes disposed on the inner surface of the top plate, the first gas supply device being connected to the first gas blow holes through the first upper-side vertical gas flow passage and the second gas supply device being connected to the second gas blow holes through the second upper-side vertical gas flow passage,
the plasma doping method comprising:
supplying the gas from the first and second gas supply devices into the first and second upper-side gas flow passages, while forming flows in a vertical direction through the first and second upper-side gas flow passages; and
flowing the gas in the first and second upper-side gas flow passages, sequentially into the first and second gas blow holes, and supplying the gas into the vacuum vessel by blowing out the gas from the first and second gas blow holes; and
implanting impurities into a source/drain extension region of the substrate at a time of the plasma doping by using gas containing the impurities and diluted with rare gas or hydrogen is used as the gas, with a concentration of the gas containing the impurities set at not less than 0.05 wet % and not more than 5.0 wet %, and bias voltage of the high frequency power applied by the high frequency power supply set at not less than 30 V and not more than 600 V.

13. The plasma doping method according to claim 12, comprising:
performing the plasma doping to a first dummy substrate to implant the impurities into the first dummy substrate;
activating the impurities of the first dummy substrate by annealing;
comparing with a threshold value, information regarding a uniformity of a distribution obtained by measuring an in-surface sheet resistance distribution of the first dummy substrate, and then determining the uniformity of the in-surface sheet resistance distribution of the first dummy substrate;
when a sheet resistance of a central part of the first dummy substrate is determined to be excellent, replacing the first dummy substrate with the substrate and performing the plasma doping to the substrate to implant the impurities into the substrate;
when the sheet resistance of the central part of the first dummy substrate is determined not to be excellent and determined to be smaller than that of a peripheral part of the first dummy substrate, replacing the first dummy substrate with a second dummy substrate, blowing the gas from the gas blow holes in opposition to a central part of the second dummy substrate in a state of stopping blow of the gas from the gas blow holes in opposition to a peripheral part of the second dummy substrate, and performing the plasma doping to the second dummy substrate to implant the impurities into the second dummy substrate; and
when the sheet resistance of the central part of the first dummy substrate is determined not to be excellent and determined to be greater than that of the peripheral part of the first dummy substrate, replacing the first dummy substrate with a second dummy substrate, blowing the gas from the gas blow holes in opposition to the peripheral part of the second dummy substrate in a state of stopping the blow of the gas from the gas blow holes in opposition to the central part of the second dummy substrate, and performing the plasma doping to the second dummy substrate to implant the impurities into the second dummy substrate;
after performing the plasma doping to the second dummy substrate, comparing with a threshold value, information regarding a uniformity of a distribution obtained by measuring an in-surface sheet resistance distribution of the second dummy substrate, and determining the uniformity of the in-surface sheet resistance distribution of the second dummy substrate, and adjusting gas blow amounts from the gas blow holes to correct a uniformity of an in-surface sheet resistance distribution of the substrate, replacing the second dummy substrate with the substrate, and performing the plasma doping to the substrate to implant the impurities into the substrate.

14. The plasma doping method according to claim 12, comprising:
performing the plasma doping to a first dummy substrate to implant the impurities into the first dummy substrate;
activating the impurities of the first dummy substrate by annealing;
comparing with a threshold value, information regarding a uniformity of a distribution obtained by measuring an in-surface sheet resistance distribution of the first dummy substrate, and then determining the uniformity of the in-surface sheet resistance distribution of the first dummy substrate; and
when a sheet resistance of a central part of the first dummy substrate is determined to be excellent, replacing the first dummy substrate with the substrate and then performing the plasma doping to the substrate to implant the impurities into the substrate;
when the sheet resistance of the central part of the first dummy substrate is determined not to be excellent and determined to be smaller than that of a peripheral part of the first dummy substrate, decreasing a concentration of the impurities of the gas blown from the gas blow holes in opposition to a peripheral part of the second dummy substrate, and increasing a concentration of the impurities of the gas blown from the gas blow holes in opposition to a central part of the second dummy substrate, and then performing the plasma doping to the second dummy substrate to implant the impurities into the second dummy substrate; and
when the sheet resistance of the central part of the first dummy substrate is determined not to be excellent and determined to be greater than that of the peripheral part of the first dummy substrate, replacing the first dummy substrate with a second dummy substrate, decreasing a concentration of the impurities of the gas blown from the gas blow holes in opposition to a central part of the second dummy substrate, increasing a concentration of the impurities of the gas blown from the gas blow holes in opposition to the gas blow holes in opposition to a peripheral part of the second dummy substrate, and the performing the plasma doping to the second dummy substrate to implant the impurities into the second dummy substrate;
after performing the plasma doping to the second dummy substrate, comparing with the threshold value, information regarding a uniformity of a distribution obtained by measuring an in-surface sheet resistance distribution of the second dummy substrate, determining the uniformity of the in-surface sheet resistance distribution of the second dummy substrate, and adjusting concentrations of the impurities of the gas from the gas blow holes to correct a uniformity of an in-surface sheet resistance distribution of the substrate, replacing the second dummy substrate with the substrate, and performing the plasma doping to the substrate to implant the impurities into the substrate.

15. The plasma doping method according to claim 12, wherein the concentration of the impurities of the gas is not less than 0.2 wet % and not more than 2.0 wet %.

16. The plasma doping method according to claim 12, wherein thereby the gas is supplied in independent two lines of a first gas supply device and a second gas supply device which the gas supply device comprises, and to which the gas supply lines and the gas flow passages are separately and independently provided respectively.

17. A manufacturing method of a semiconductor device for manufacturing a semiconductor device, by performing plasma doping using a plasma doping apparatus comprising:
a vacuum vessel having a top plate;
an electrode disposed in the vacuum vessel and in opposition to an inner surface of the top plate, for placing a substrate thereon;
a high frequency power supply for applying high frequency power to the electrode;
an exhaust device for exhausting an inside of the vacuum vessel;
first and second gas supply devices for supplying gas into the vacuum vessel;
a single gas-nozzle member having first and second upper-side vertical gas flow passages perpendicular to a surface of the electrode; and
first gas blow holes and second gas blow holes disposed on the inner surface of the top plate, the first gas supply device being connected to the first gas blow holes through the first upper-side vertical gas flow passage and the second gas supply device being connected to the second gas blow holes through the second upper-side vertical gas flow passage,
the method comprising:
supplying the gas from the first and second gas supply devices into the first and second upper-side gas flow passages while forming flows in a vertical direction through the first and second upper-side gas flow passages;
flowing the gas in the gas flow passages of the top plate, sequentially through the first and second upper-side vertical gas flow passages into the gas blow holes, and supplying the gas into the vacuum vessel by blowing the gas from the first and second gas blow holes; and
implanting impurities into a source/drain extension region of the substrate at a time of the plasma doping by using gas containing the impurities and diluted with rare gas or hydrogen which is used as the gas, with a concentration of the impurities of the gas set at not less than 0.05 wet % and not more than 5.0 wet %, and bias voltage of the high frequency power applied by the high frequency power supply set at not less than 30 V and not more than 600V.
